(19) United States
(12) Patent Application Publication
(10) Pub. No.: US 2024/0196737 A1
(43) Pub. Date: Jun. 13, 2024

(54) LIGHT EMITTING ELEMENT AND FUSED POLYCYCLIC COMPOUND FOR THE SAME

(71) Applicant: Samsung Display Co., Ltd., Yongin-si (KR)

(72) Inventors: TAEIL KIM, Yongin-si (KR); MINJUNG JUNG, Yongin-si (KR); JUNHA PARK, Yongin-si (KR); MUN-KI SIM, Yongin-si (KR); MinJae SUNG, Yongin-si (KR)

(73) Assignee: Samsung Display Co., Ltd., Yongin-si (KR)

(21) Appl. No.: 18/366,840

(22) Filed: Aug. 8, 2023

(30) Foreign Application Priority Data
Oct. 24, 2022 (KR) 10-2022-0137584

(51) Int. Cl. H10K 85/60; C09K 11/02; C09K 11/06; H10K 85/30; H10K 85/40

(52) U.S. Cl. CPC H10K 85/633; C09K 11/02; C09K 11/06; H10K 85/346; H10K 85/40; H10K 85/654; H10K 85/6572; H10K 85/6574; H10K 85/658; C07B 2200/05; H10K 2101/30

(57) ABSTRACT

Embodiments provide a fused polycyclic compound and a light emitting device including the fused polycyclic compound. The light emitting element includes a first electrode, a second electrode disposed on the first electrode, and an emission layer disposed between the first electrode and the second electrode. The emission layer includes a fused polycyclic compound, and at least one of a second compound, a third compound, and a fourth compound. The first compound is represented by Formula 1, the second compound is represented by Formula HT-1, the third compound is represented by Formula ET-1, and the fourth compound is represented by Formula M-b, which are each explained in the specification.

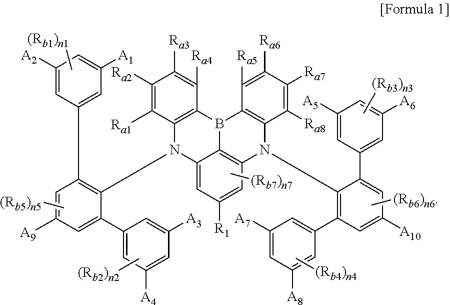

### CROSS-REFERENCE TO RELATED APPLICATION(S)

This application claims priority to and benefits of Korean Patent Application No. 10-2022-0137584 under 35 U.S.C. § 119, filed on Oct. 24, 2022, in the Korean Intellectual Property Office, the entire contents of which are incorporated herein by reference.

### BACKGROUND

### 1. Technical Field

The disclosure relates to a light emitting element and a fused polycyclic compound used therein.

### 2. Description of the Relation Art

Active development continues for an organic electroluminescence display device as an image display device. The organic electroluminescence display device includes a so-called self-luminescent light emitting element in which holes and electrons respectively injected from a first electrode and a second electrode combine in an emission layer, so that a luminescent material of the emission layer emits light to implement display.

In the application of a light emitting element to a display device, there is a demand for a light emitting element having improved light efficiency and improved service life, and continuous development is required on materials for a light emitting element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which light efficiency and a service life are improved.

The disclosure also provides a fused polycyclic compound which is a material for a light emitting element to improve light efficiency and service life.

An embodiment provides a light emitting element which may include a first electrode, a second electrode disposed on the first electrode, and an emission layer disposed between the first electrode and the second electrode, wherein the emission layer may include a first compound represented by Formula 1, and at least one of a second compound represented by Formula HT-1, a third compound represented by Formula ET-1, or a fourth compound represented by Formula M-b:

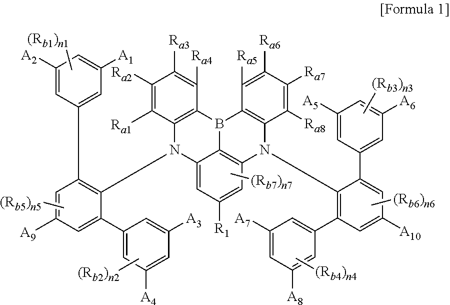

In Formula 1, at least one of Rₐ₁ to Rₐ₈ may each independently be a group represented by Formula 2; the remainder of Rₐ₁ to Rₐ₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms;
at least one of A₁ to A₈ may each independently be a first substituent; the remainder of A₁ to A₈ may each independently be a hydrogen atom or a deuterium atom; the first substituent may be a substituted or unsubstituted germanium group, a substituted or unsubstituted silyl group, a substituted or unsubstituted alkyl group having 1 to 60 carbon atoms, or a substituted or unsubstituted aryl group having 6 to 60 ring-forming carbon atoms,
A₉ and A₁₀ may each independently be a hydrogen atom, a deuterium atom, a substituted or unsubstituted alkyl group having 1 to 60 carbon atoms, or a substituted or unsubstituted aryl group having 6 to 60 ring-forming carbon atoms;
R₁ may be a hydrogen atom, a deuterium atom, a halogen atom, a cyano group, a nitro group, a hydroxyl group, a substituted or unsubstituted silyl group, a substituted or unsubstituted amine group, a substituted or unsubstituted alkoxy group, a substituted or unsubstituted alkylthio group, a substituted or unsubstituted alkyl group having 1 to 60 carbon atoms, a substituted or unsubstituted aryl group having 6 to 60 ring-forming carbon atoms, a substituted or unsubstituted heterocyclic group having 2 to 60 ring-forming carbon atoms, or may be bonded to an adjacent group to form a ring,
n1 to n4 may each independently be an integer from 0 to 3; n5 to n7 may each independently be an integer from 0 to 2; and R_{b1} to R_{b7} may each independently be a hydrogen atom or a deuterium atom;

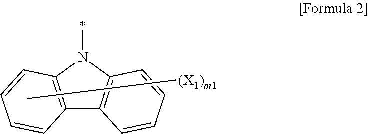

In Formula 2, m1 may be an integer from 0 to 8; and X₁ may be a hydrogen atom, a deuterium atom, a cyano group, or a substituted or unsubstituted alkyl group having 1 to 60 carbon atoms;

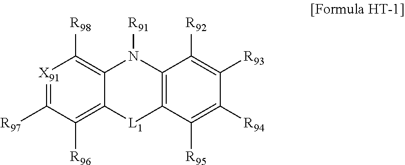

In Formula HT-1, L₁ may be a direct linkage, C(R₉₉)(R₁₀₀), or Si(R₁₀₁)(R₁₀₂); X₉₁ may be N or C(R₁₀₃); and

R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring;

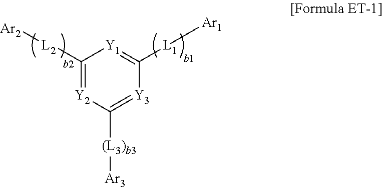

In Formula ET-1, at least one among Y₁ to Y₃ may each be N; the remainder of Y₁ to Y₃ may each independently be C(Rₐ);
Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms;
b1 to b3 may each independently be an integer from 0 to 10; L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms; and
Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and

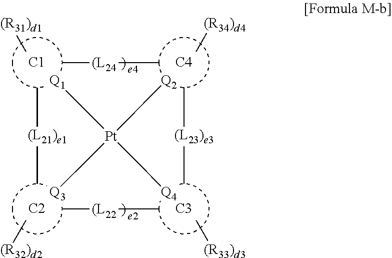

In Formula M-b, Q₁ to Q₄ may each independently be C or N,
C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms,
e1 to e4 may each independently be 0 or 1,
L₂₁ to L₂₄ may each independently be a direct linkage,

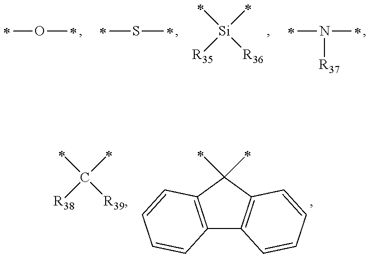

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 may each independently be an integer from 0 to 4, and
R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the first compound may be represented by Formula 1-A1 or Formula 1-A2:

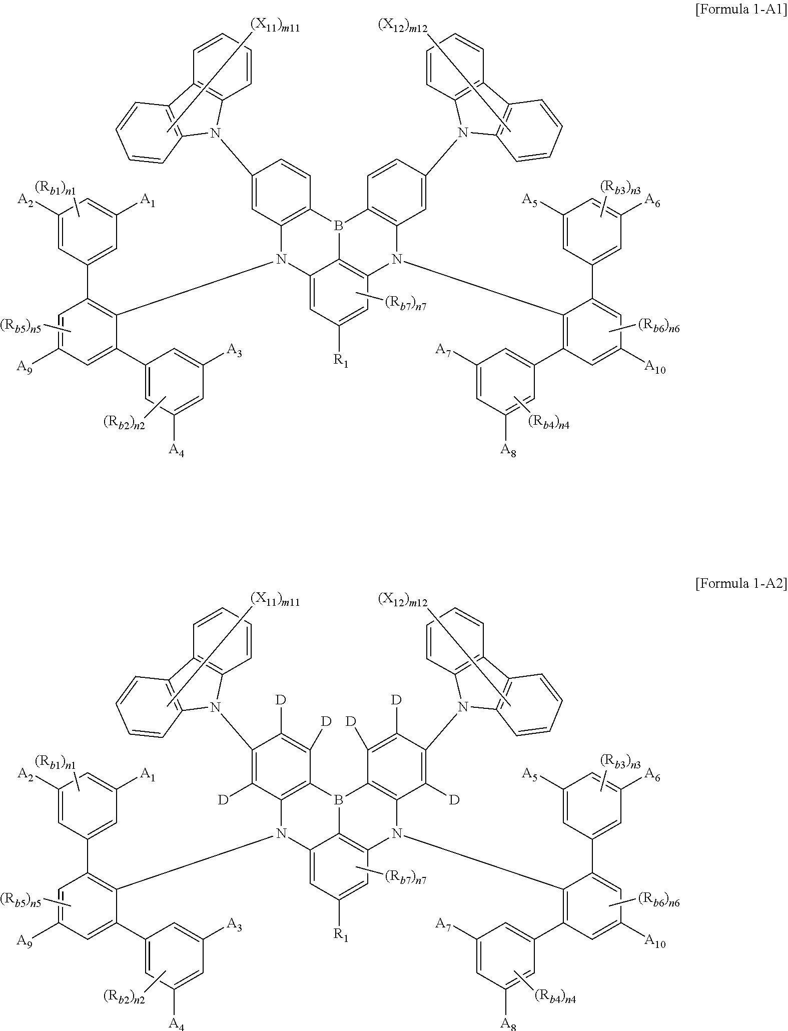

In Formula 1-A1 and Formula 1-A2, m11 and m12 may each independently be an integer from 0 to 8; X₁₁ and X₁₂ may each independently be a hydrogen atom, a deuterium atom, a cyano group, or a substituted or unsubstituted alkyl group having 1 to 60; and A₁ to A₁₀, R₁, n1 to n7, and R_{b1} to R_{b7} are the same as defined in Formula 1.

In an embodiment, the first compound may be represented by Formula 1-B:

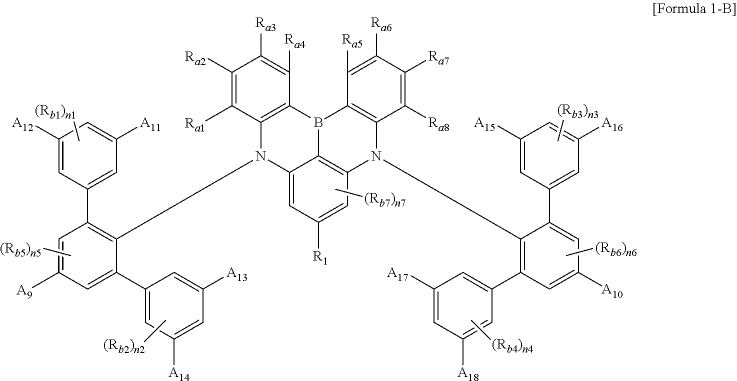

In Formula 1-B, A₁₄ and A₁₈ may each independently be a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms,
A₁₁ to A₁₃ and A₁₈ to A₁₇ may each independently be a hydrogen atom, a deuterium atom, a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and Rₐ₁ to Rₐ₈, A₉, A₁₀, R₁, n1 to n7, and R_{b1} to R_{b7} are the same as defined in Formula 1.

In an embodiment, the first compound may be represented by one of Formula 1-B1 to Formula 1-B3:

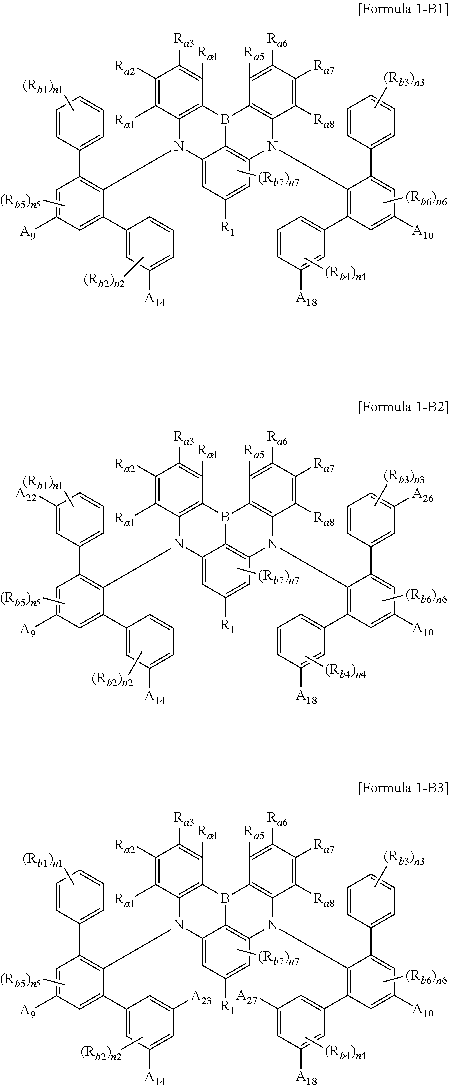

In Formula 1-B2 and Formula 1-B3,
A₂₂, A₂₃, A₂₆, and A₂₇ may each independently be a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and
in Formula 1-B1 to Formula 1-B3,
Rₐ₁ to Rₐ₈, A₉, A₁₀, A₁₄, A₁₈, R₁, n1 to n7, and R_{b1} to R_{b7} are the same as defined in Formula 1-B.

In an embodiment, the first substituent may be a substituted or unsubstituted trimethylgermanium group, a substituted or unsubstituted trimethylsilyl group, a substituted or unsubstituted ethyl group, a substituted or unsubstituted isopropyl group, a substituted or unsubstituted propyl group, a substituted or unsubstituted t-butyl group, a substituted or unsubstituted cyclohexyl group, or a substituted or unsubstituted phenyl group.

In an embodiment, the first substituent may be represented by one of Formula F-1 to Formula F-11:

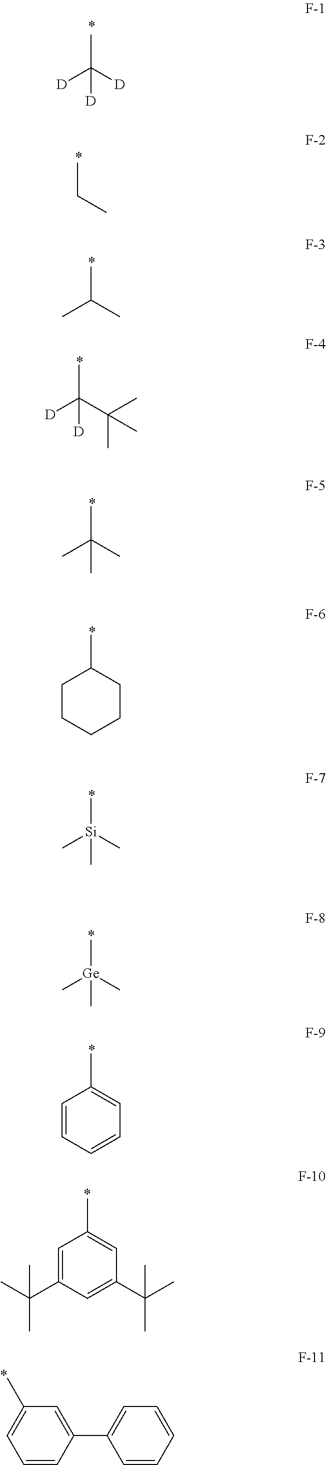

In Formula F-1 and Formula F-4, D is a deuterium atom.

In an embodiment, the first compound may be represented by Formula 1-C1 or Formula 1-C2:

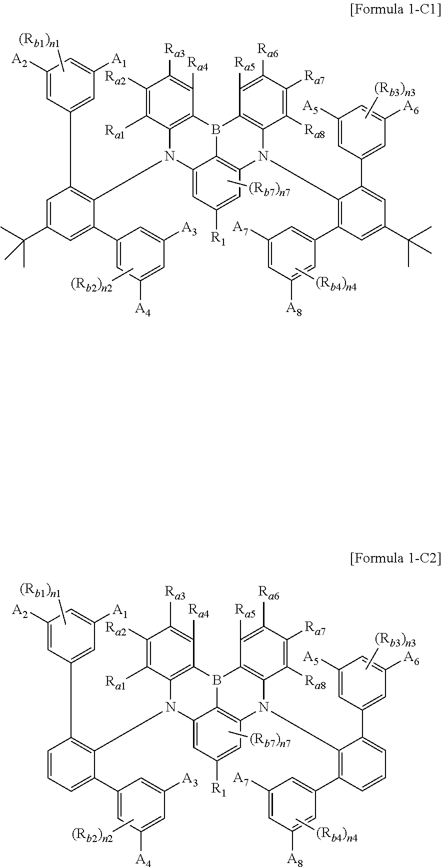

In Formula 1-C1 and Formula 1-C2, Rₐ₁ to Rₐ₈, A₁ to A₈, R₁, n1 to n4, n7, R_{b1} to R_{b4}, and R_{b7} are the same as defined in Formula 1.

In an embodiment, the group represented by Formula 2 may be a group represented by Formula 2-1:

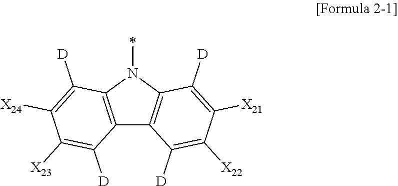

In Formula 2-1, X₂₁ to X₂₄ may each independently be a deuterium atom, a cyano group, a substituted or unsubstituted methyl group, or a substituted or unsubstituted t-butyl group; and D is a deuterium atom.

In an embodiment, in Formula 1, R₁ may be represented by one of Formula R1-1 to Formula R1-13:

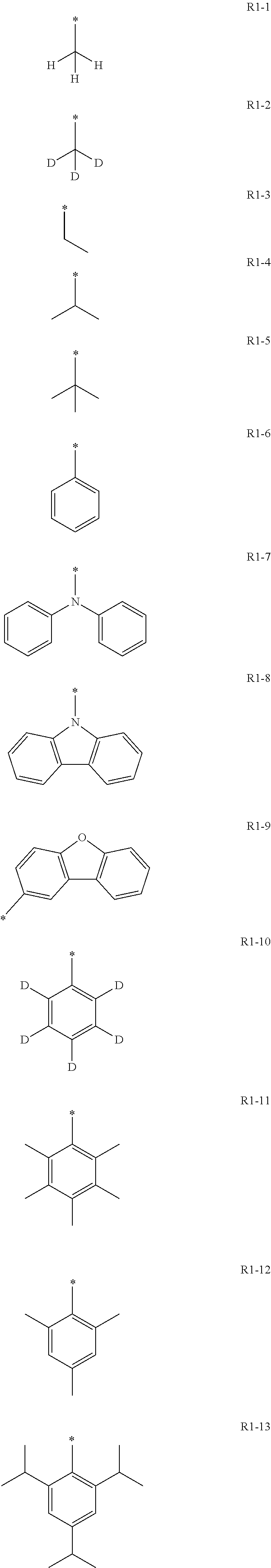

In Formula R1-2 and Formula R1-10, D is a deuterium atom.

In an embodiment, the emission layer may include a host and a dopant; and the dopant may include the first compound.

In an embodiment, the emission layer may include the first compound, the second compound, the third compound, and the fourth compound.

In an embodiment, the first compound may include at least one compound selected from Compound Group 1, which is explained below.

Embodiments provide a fused polycyclic compound which may be represented by Formula 1, which is described herein.

In an embodiment, Formula 1 may be represented by Formula 1-A1 or Formula 1-A2, which are explained herein.

In an embodiment, Formula 1 may be represented by Formula 1-B, which is explained herein.

In an embodiment, Formula 1-B may be represented by one of Formula 1-B1 to Formula 1-B3, which are explained herein.

In an embodiment, the first substituent may be a substituted or unsubstituted trimethylgermanium group, a substituted or unsubstituted trimethylsilyl group, a substituted or unsubstituted ethyl group, a substituted or unsubstituted isopropyl group, a substituted or unsubstituted propyl group, a substituted or unsubstituted t-butyl group, a substituted or unsubstituted cyclohexyl group, or a substituted or unsubstituted phenyl group.

In an embodiment, the first substituent may be represented by one of Formula F-1 to Formula F-11, which are explained herein.

In an embodiment, Formula 1 may be represented by Formula 1-C1 or Formula 1-C2, which are explained herein.

In an embodiment, the group represented by Formula 2 may be a group represented by Formula 2-1, which is explained herein.

In an embodiment, in Formula 1, R₁ may be represented by one of Formula R1-1 to Formula R1-13, which are explained herein.

In an embodiment, the fused polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings in which:

FIG. 1 is a schematic plan view of a display device according to an embodiment;

FIG. 2 is a schematic cross-sectional view of a part taken along line I-I′ of FIG. 1;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment; and

FIG. 11 is a schematic perspective view of an interior of a vehicle in which display devices are disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

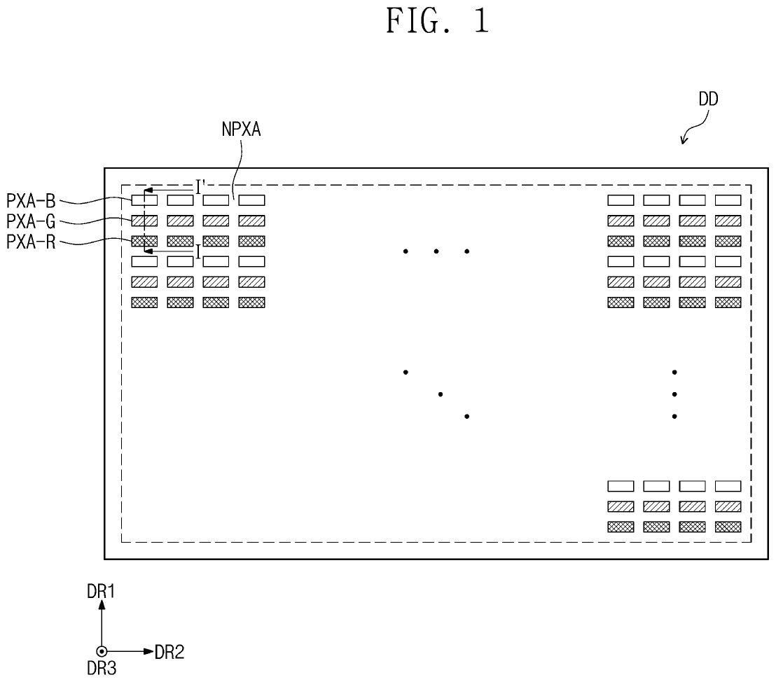

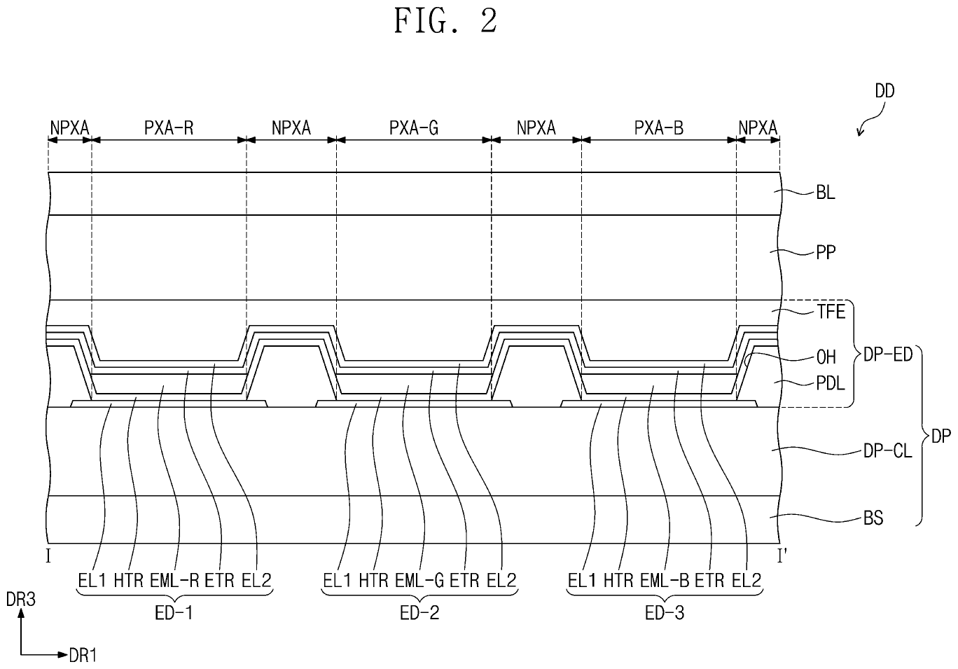

Hereinafter, embodiments will be described with reference to the accompanying drawings. FIG. 1 is a schematic plan view illustrating an embodiment of a display device DD. FIG. 2 is a schematic cross-sectional view of the display device DD according to an embodiment. FIG. 2 is a schematic cross-sectional view corresponding to line I-I′ of FIG. 1.

The display device DD may include a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP to control light reflected at the display panel DP from an external light. The optical layer PP may include, for example, a polarization layer or a color filter layer. Although not shown in the drawings, in an embodiment the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

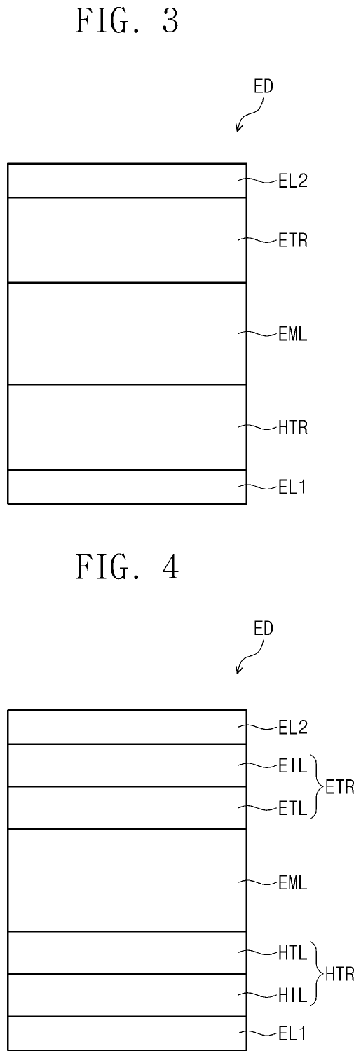

The light emitting elements ED-1, ED-2, and ED-3 may each have a structure of a light emitting element ED of an embodiment, according to any of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto. Although not illustrated in FIG. 2, the hole transport region HTR and the electron transport region ETR in an embodiment may each be provided by being patterned inside the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 t may each be provided by being patterned in an inkjet printing method.

An encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or multiple layers. The encapsulation layer TFE may include at least one insulation layer. In an embodiment, the encapsulation layer TFE may include at least one inorganic film (hereinafter, an encapsulation-inorganic film). In an embodiment, the encapsulation layer TFE may also include at least one organic film (hereinafter, an encapsulation-organic film) and at least one encapsulation-inorganic film.

The encapsulation-inorganic film may protect the display element layer DP-ED from moisture and/or oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region which emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining film PDL. The non-light emitting areas NPXA may be areas between the adjacent light emitting areas PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light are illustrated. For example, the display device DD may include a red light emitting region PXA-R, a green light emitting region PXA-G, and a blue light emitting region PXA-B that are separated from each other.

In the display device DD according to an embodiment, the light emitting elements ED-1, ED-2 and ED-3 may emit light having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit a light in a wavelength range that is different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be alternately arranged in this order along a first directional axis DR1.

FIGS. 1 and 2 illustrate that the light emitting regions PXA-R, PXA-G, and PXA-B as each having a similar area, but the embodiments are not limited thereto. Thus, the light emitting regions PXA-R, PXA-G, and PXA-B may have different areas from each other according to a wavelength range of the emitted light. For example, the areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the display quality characteristics that are required for the display device DD. For example, the light emitting regions PXA-R, PXA-G, and PXA-B may be arranged in a pentile configuration (such as a PENTILE™ configuration) or in a diamond configuration (such as a Diamond Pixel™ configuration).

The areas of the light emitting regions PXA-R, PXA-G, and PXA-B may be different in size from each other. For example, in an embodiment, an area of a green light emitting region PXA-G may be smaller than an area of a blue light emitting region PXA-B, but the embodiments are not limited thereto.

Hereinafter, FIGS. 3 to 6 are each a schematic cross-sectional view ofa light emitting element according to an embodiment. The light emitting elements ED according to embodiments may each include a first electrode EL1, a hole transport region HTR, an emission layer EML, an electron transport region ETR, and a second electrode EL2 that are stacked.

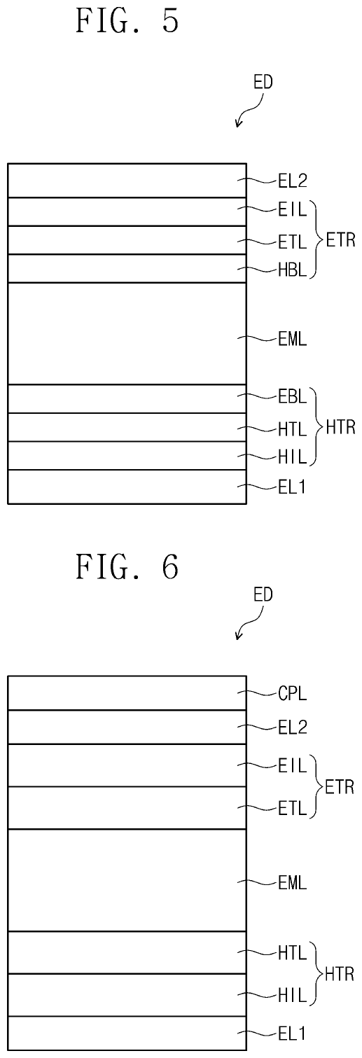

In comparison to FIG. 3, FIG. 4 illustrates a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 illustrates a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 illustrates a schematic cross-sectional view of a light emitting element ED according to an embodiment that includes a capping layer CPL disposed on a second electrode EL2.

In the light emitting element ED according to an embodiment, the emission layer EML may include the first compound and at least one of the second to fourth compounds. The first compound may include, as a central structure, a pentacyclic fused ring containing nitrogen atoms and a boron atom as ring-forming atoms. A carbazole group and an ortho-terphenyl group may be bonded to the pentacyclic fused ring. In an embodiment, the light emitting element ED that includes the first compound may exhibit high efficiency and long service life characteristics. In the specification, the first compound may be the same as the fused polycyclic compound according to an embodiment.

The second compound may include, as a central structure, a tricyclic fused ring containing a nitrogen atom as a ring-forming atom. The third compound may include, as a central structure, a monocyclic hexagonal ring group containing at least one nitrogen atom as a ring-forming atom. The fourth compound may include a structure in which a ligand is bonded to the central metal.

In the specification, the term “substituted or unsubstituted” may describe a group that is unsubstituted or substituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may be itself substituted or unsubstituted. For example, a biphenyl group may be interpreted as an aryl group, or it may be interpreted as a phenyl group substituted with a phenyl group.

In the specification, the phrase “bonded to an adjacent group to form a ring” may describe a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 60, 1 to 50, 1 to 30, 1 to 20, 1 to 10, or 1 to 6. Examples of an alkyl group may include a methyl group, an ethyl group, an n-propyl group, an isopropyl group, a 2,2-dimethylpropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not limited, but may be 2 to 60, 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group including at least one carbon-carbon triple bond in the middle or at a terminus of an alkyl group having 2 or more carbon atoms. An alkynyl group may be linear or branched. The number of carbon atoms in an alkynyl group is not limited, but may be 2 to 60, 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 60, 5 to 30, or 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group are as follows. However, embodiments are not limited thereto.

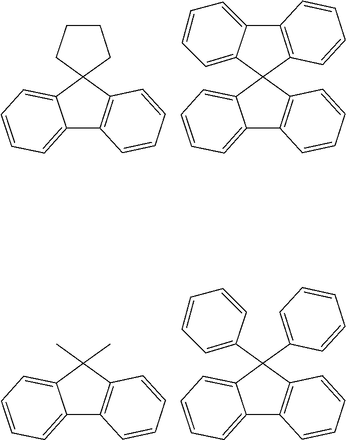

In the specification, a heterocyclic group may be any functional group or substituent derived from a ring that includes at least one of B, O, N, P, Si, or S as a heteroatom. A heterocyclic group may be an aliphatic heterocyclic group or an aromatic heterocyclic group. An aromatic heterocyclic group may be a heteroaryl group. An aliphatic heterocyclic group and an aromatic heterocyclic group may each independently be monocyclic or polycyclic.

In the specification, a heterocyclic group may contain at least one of B, O, N, P, Si, or S as a heteroatom. If a heterocyclic group contains two or more heteroatoms, the two or more heteroatoms may be the same as or different from each other. A heterocyclic group may be monocyclic or polycyclic and a heterocyclic group may be a heteroaryl group. The number of ring-forming carbon atoms in a heterocyclic group may be 2 to 60, 2 to 30, 2 to 20, or 2 to 10.

In the specification, an aliphatic heterocyclic group may include at least one of B, O, N, P, Si, or S as a heteroatom. The number of ring-forming carbon atoms in an aliphatic heterocyclic group may be 2 to 60, 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiments are not limited thereto.

In the specification, a heteroaryl group may include at least one of B, O, N, P, Si, or S as a heteroatom. When a heteroaryl group contains two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a germanium group may be a germanium atom that is bonded to an alkyl group or an aryl group as defined above. A germanium group may be an alkyl germanium group or an aryl germanium group. Examples of a germanium group may include a trimethylgermanium group, a triethylgermanium group, a t-butyldimethylgermanium group, an ethyldimethylgermanium group, a propyldimethylgermanium group, a triphenylgermanium group, a diphenylgermanium group, a phenylgermanium group, etc., but embodiments are not limited thereto.

In the specification, a silyl group may be a silicon atom that is bonded to an alkyl group or an aryl group as defined above. A silyl group may be an alkylsilyl group or an arylsilyl group. Examples of a silyl group may include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not limited, but may be 1 to 40, 1 to 30, or 1 to 20. For example, a carbonyl group may have one of following structures, but the embodiments are not limited thereto.

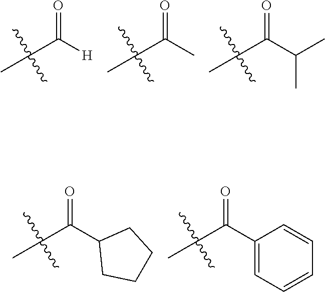

In the specification, the number of carbon atoms in a sulfinyl group or a sulfonyl group is not limited, but may be 1 to 60 or 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not limited, but may be, for example, 1 to 60, 1 to 30, 1 to 20, or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boryl group may be a boron atom that is bonded to an alkyl group or an aryl group as defined above. A boron group may be an alkyl boron group or an aryl boron group. Examples of a boron group may include a dimethylboron group, a diethylboron group, a t-butylmethylboron group, a diphenylboron group, a phenylboron group, etc., but embodiments are not limited thereto.

In the specification, the number of carbon atoms in an amine group is not limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group in an alkylthio group, an alkylsulfinyl group, an alkylsulfonyl group, an alkoxy group, an alkyl boron group, an alkyl germanium group, an alkyl silyl group, or an alkyl amine group may be the same as an example of the alkyl group described above.

In the specification, an aryl group in an aryloxy group, an arylthio group, an arylsulfinyl group, an arylsulfonyl group, an arylamine group, an aryl boron group, an aryl germanium group, or an aryl silyl group may be the same as an example of the aryl group described above.

In the specification, a direct linkage may be a single bond.

In the specification, the symbols [symbol] and [symbol] each represent a bonding site to a neighboring atom.

The light emitting element ED according to an embodiment may include a fused polycyclic compound. The fused polycyclic compound may be represented by Formula 1:

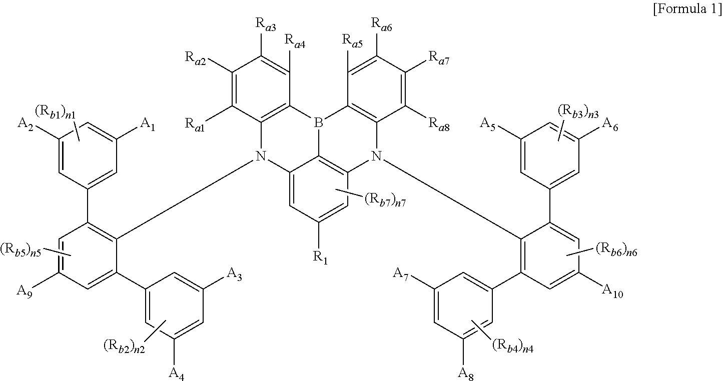

In Formula 1, at least one of Rₐ₁ to Rₐ₈ may each independently be a group represented by Formula 2, and the remainder of Rₐ₁ to Rₐ₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms. For example, when any one of Rₐ₁ to Rₐ₈ is a heteroaryl group, the heteroaryl group may contain at least one of N, O, or S as a ring-forming atom. In an embodiment, the remainder of Rₐ₁ to Rₐ₈, which are not represented by Formula 2, may each independently be a hydrogen atom or a deuterium atom.

Formula 2 represents a substituted or unsubstituted carbazole group, and the nitrogen atom of the carbazole group in Formula 2 may be a position which is bonded to Formula 1. When at least two of Rₐ₁ to Rₐ₈ are represented by Formula 2, multiple groups represented by Formula 2 may be the same as each other or at least one group thereof may be different from the others.

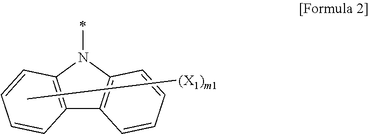

In Formula 2, m1 may be an integer from 0 to 8. When m1 is 2 or greater, multiple X₁ groups may be the same as each other or at least one X₁ group may be different from the others. In Formula 2, X₁ may be a hydrogen atom, a deuterium atom, a cyano group, or a substituted or unsubstituted alkyl group having 1 to 60 carbon atoms. For example, m1 may be 2 or greater, at least one X₁ group may be a deuterium atom, and the remainder of the X₁ groups may each independently be a cyano group, a substituted or unsubstituted methyl group, or a substituted or unsubstituted t-butyl group.

In an embodiment, the group represented by Formula 2 may be a group represented by Formula 2-1. Formula 2-1 represents a case where in Formula 2, m1 is 8, and at least four X₁ groups are deuterium atoms.

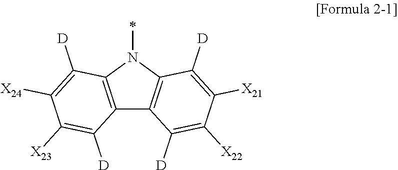

In Formula 2-1, D is a deuterium atom. In Formula 2-1, X₂₁ to X₂₄ may each independently be a deuterium atom, a cyano group, a substituted or unsubstituted methyl group, or a substituted or unsubstituted t-butyl group. For example, X₂₁ and X₂₄ may be the same, and X₂₂ and X₂₃ may be the same. In an embodiment, a group represented by Formula 2-1 may be a group represented by one of Formula 2-1a to Formula 2-1e. Formula 2-1a to Formula 2-1e represent cases where X₂₁ to X₂₄ are further defined in Formula 2-1.

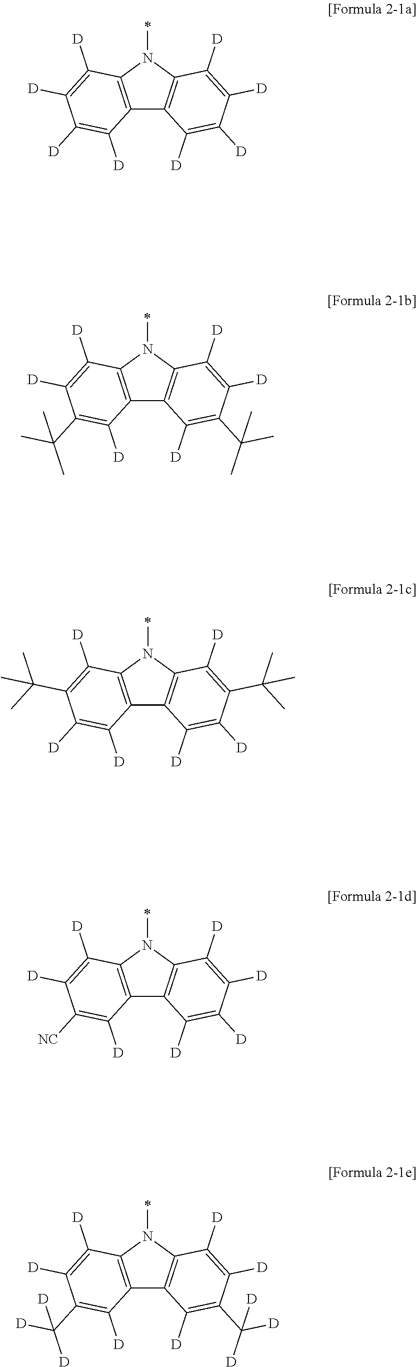

In Formula 1, at least one of A₁ to A₈ may each independently be a first substituent; and the remainder of A₁ to A₈ may each independently be a hydrogen atom or a deuterium atom. In Formula 1, the first substituent may be a substituted or unsubstituted germanium group, a substituted or unsubstituted silyl group, a substituted or unsubstituted alkyl group having 1 to 60 carbon atoms, or a substituted or unsubstituted aryl group having 6 to 60 ring-forming carbon atoms. For example, at least one of A₁ to A₈ may be a substituted or unsubstituted germanium group, a substituted or unsubstituted silyl group, a substituted or unsubstituted alkyl group, or a substituted or unsubstituted aryl group.

In an embodiment, the first substituent may be a substituted or unsubstituted trimethylgermanium group, a substituted or unsubstituted trimethylsilyl group, a substituted or unsubstituted ethyl group, a substituted or unsubstituted isopropyl group, a substituted or unsubstituted propyl group, a substituted or unsubstituted t-butyl group, a substituted or unsubstituted cyclohexyl group, or a substituted or unsubstituted phenyl group.

In an embodiment, the first substituent may be represented by any one of Formula F-1 to Formula F-11:

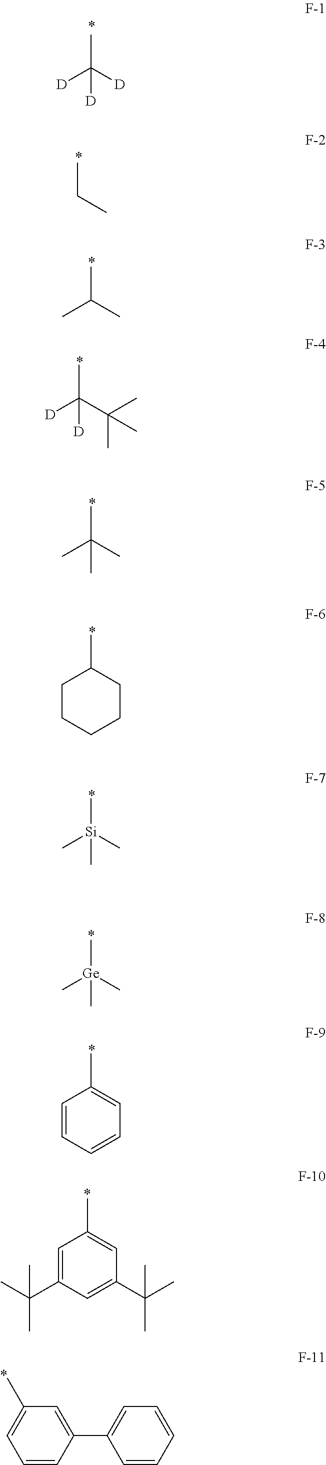

In Formula F-1 and Formula F-4, D is a deuterium atom. Formula F-1 represents a methyl group substituted with a deuterium atom, and Formula F-2 represents an unsubstituted ethyl group. Formula F-3 represents an unsubstituted isopropyl group, and Formula F-4 represents a 2,2-dimethylpropyl group substituted with deuterium atoms. Formula F-5 represents an unsubstituted t-butyl group, and Formula F-6 represents an unsubstituted cyclohexyl group. Formula F-7 represents an unsubstituted trimethylsilyl group, and Formula F-8 represents the unsubstituted trimethylgermanium group. Formula F-9 represents an unsubstituted phenyl group, and Formula F-10 represents a phenyl group substituted with t-butyl groups. Formula F-11 represents a phenyl group substituted with a phenyl group.

In each of the phenyl groups including any two of A₁ to A₈, A₁ to A₈ may be bonded to the phenyl group at a meta-position to each other. In each of the phenyl groups, A₁ to A₈ may be substituents bonded at a meta-position to a bonding position to an adjacent phenyl group.

In an embodiment, with respect to A₁ to A₈, two substituents at bilateral symmetrical positions with respect to the boron atom forming the pentacyclic fused ring may be the same. For example, A₁ may be the same as A₅, and A₂ may be the same as A₆. For example, A₃ may be the same as A₇, and A₄ may be the same as A₈. However, embodiments are not limited thereto.

A first phenyl group to which A₁ and A₂ are bonded, a second phenyl group to which A₃ and A₄ are bonded, and a third phenyl group to which A₉ is bonded may form an ortho-terphenyl group. The third phenyl group may be directly bonded to a nitrogen atom of the pentacyclic fused ring, and the first phenyl group and the second phenyl group may be bonded to the carbon atom at an ortho-position to the carbon atom of the third phenyl group that is directly bonded to the pentacyclic fused ring.

A fourth phenyl group to which A₅ and A₆ are bonded, a fifth phenyl group to which A₇ and A₈ are bonded, and a sixth phenyl group to which A₁₀ is bonded may form an ortho-terphenyl group. The sixth phenyl group may be directly bonded to a nitrogen atom of the pentacyclic fused ring, and the fourth phenyl group and the fifth phenyl group may be bonded to the carbon atom at an ortho-position to the carbon atom of the sixth phenyl group that is directly bonded to the pentacyclic fused ring.

In Formula 1, A₉ and A₁₀ may each independently be a hydrogen atom, a deuterium atom, a cyano group, a substituted or unsubstituted alkyl group having 1 to 60 carbon atoms, or a substituted or unsubstituted aryl group having 6 to 60 ring-forming carbon atoms. For example, A₉ and A₁₀ may each independently be a hydrogen atom, a cyano group, a substituted or unsubstituted t-butyl group, or a substituted or unsubstituted phenyl group.

In Formula 1, R₁ may be a hydrogen atom, a deuterium atom, a halogen atom, a cyano group, a nitro group, a hydroxyl group, a substituted or unsubstituted silyl group, a substituted or unsubstituted amine group, a substituted or unsubstituted alkoxy group, a substituted or unsubstituted alklythio group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₁ may be a substituted or unsubstituted amine group, a substituted or unsubstituted alkyl group having 1 to 10 carbon atoms, a substituted or unsubstituted aryl group having 6 to 20 ring-forming carbon atoms, or a substituted or unsubstituted heterocyclic group having 2 to 20 ring-forming carbon atoms.

In an embodiment, R₁ may be represented by any one of Formula R1-1 to Formula R1-13. Formula R1-1 to Formula R1-5 represent a substituted or unsubstituted alkyl group having 1 to 10 carbon atoms. Formula R1-6 and Formula R1-10 to Formula R1-13 represent a substituted or unsubstituted aryl group, and Formula R1-7 represents an unsubstituted aryl amine group. Formula R1-8 and Formula R1-9 represent an unsubstituted heterocyclic group.

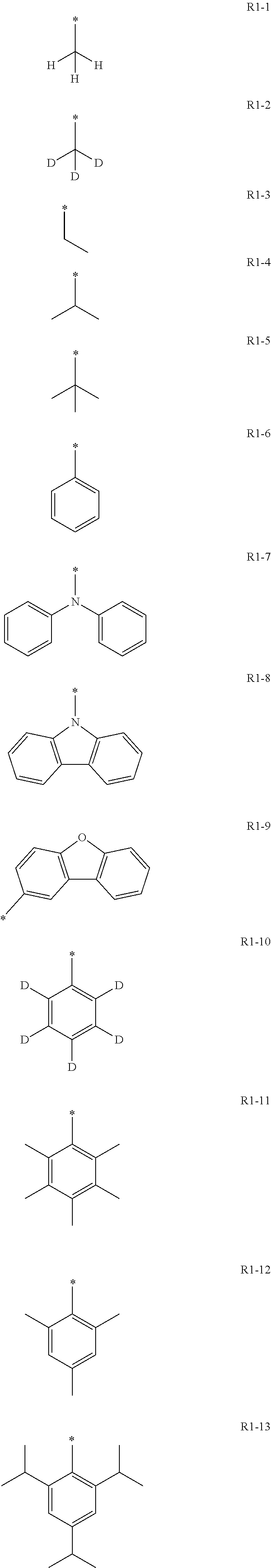

In Formula R1-2 and Formula R1-10, D is a deuterium atom. Formula R1-1 represents an unsubstituted methyl group, and Formula R1-2 represents a methyl group substituted with deuterium atoms. Formula R1-3 represents an unsubstituted ethyl group, and Formula R1-4 represents an unsubstituted isopropyl group, and Formula R1-5 represents an unsubstituted t-butyl group. Formula R1-6 represents an unsubstituted phenyl group, and Formula R1-7 represents an unsubstituted diphenylamine group. Formula R1-8 represents an unsubstituted carbazole group, and Formula R1-9 represents an unsubstituted dibenzofuran group. Formula R1-10 represents a phenyl group substituted with deuterium atoms, and Formula R1-11 and Formula R1-12 represent a phenyl group substituted with methyl groups. Formula R1-13 represents a phenyl group substituted with isopropyl groups.

In Formula 1, n1 to n4 may each independently be an integer from 0 to 3, and n5 to n7 may each independently be an integer from 0 to 2. In Formula 1, R_{b1} to R_{b7} may each independently be a hydrogen atom or a deuterium atom. When n1 is 2 or greater, multiple R_{b1} groups may be the same as each other or at least one group thereof may be different from the others. When n2 to n7 are each 2 or greater, the same description of R_{b1} may be applied to multiple groups of each of R_{b2} to R_{b7}. When n2 to n7 are each 2 or greater, multiple groups of each of R_{b2} to R_{b7} may be the same as each other, or at least one group thereof may be different from the others.

For example, the fused polycyclic compound may include at least one deuterium atom and at least one t-butyl group which are directly or indirectly bonded to the pentacyclic fused ring. The deuterium atom may be directly bonded to the pentacyclic fused ring, or a substituent substituted with deuterium atoms may be bonded to the pentacyclic fused ring. The t-butyl group atom may be directly bonded to the pentacyclic fused ring, or a substituent substituted with t-butyl groups may be bonded to the pentacyclic fused ring.

In an embodiment, Formula 1 may be represented by Formula 1-A1 or Formula 1-A₂. Formula 1-A1 and Formula 1-A2 represent cases where two of Rₐ₁ to Rₐ₈ in Formula 1 are represented by Formula 2, and the remainder of Rₐ₁ to Rₐ₈ in Formula 1 may each independently be hydrogen atoms or deuterium atoms. For example, Formula 1-A1 and Formula 1-A2 represent cases where Rₐ₂ and Rₐ₇ in Formula 1 are represented by Formula 2.

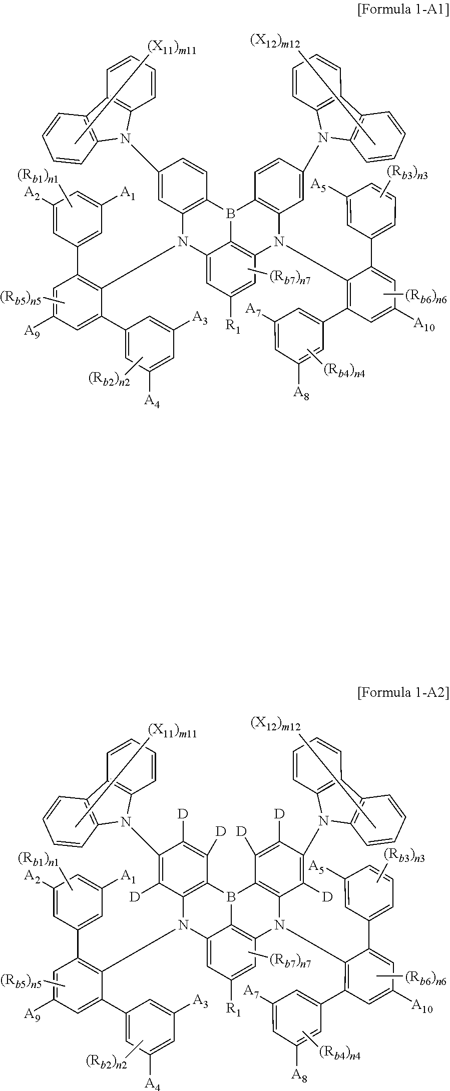

In Formula 1-A1 and Formula 1-A2, A₁ to A₁₀, R₁, n1 to n7, and R_{b1} to Re are the same as described in Formula 1. In Formula 1-A1 and Formula 1-A2, m11 and m12 may each independently be an integer from 0 to 8. When m11 is 2 or greater, multiple X₁₁ groups may be the same as each other or at least one group thereof may be different from the remainder. When m12 is 2 or greater, multiple X₁₂ groups may be the same as each other or at least one group thereof may be different from the remainder.

In Formula 1-A1 and Formula 1-A2, X₁₁ and X₁₂ may each independently be a hydrogen atom, a deuterium atom, a cyano group, or a substituted or unsubstituted alkyl group having 1 to 60 carbon atoms. For example, m11 may be an integer from 2 to 8, and at least one X₁₁ group may be a deuterium atom. For example, m12 may be an integer from 2 to 8, and at least one X₁₂ group may be a deuterium atom. In Formula 1-A1 and Formula 1-A2, a carbazole group containing X₁₁ and a carbazole group containing X₁₂ may be substituted with at least one deuterium atom. In Formula 1-A1 and Formula 1-A2, a carbazole group containing X₁₁ and a carbazole group containing X₁₂ may each independently be represented by any one of Formula 2-1a to Formula 2-1e.

In an embodiment, Formula 1 may be represented by Formula 1-B. Formula 1-B represents a case where at least two of A₁ to A₈ in Formula 1 are represented by the first substituent. For example, Formula 1-B represents a case where at least A₄ and A₈ in Formula 1 are represented by the first substituent.

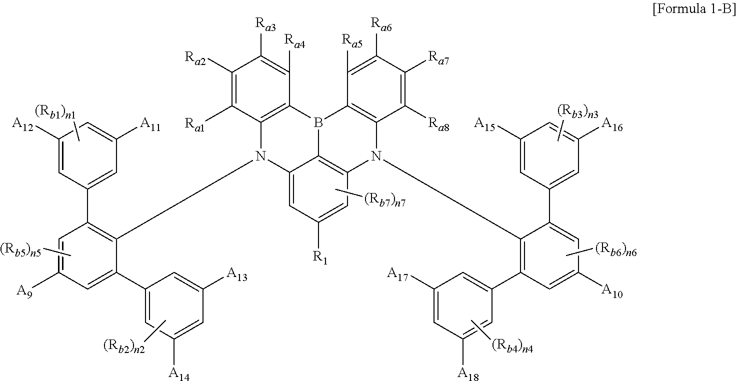

In Formula 1-B, Rₐ₁ to Rₐ₈, A₉, A₁₀, R₁, n1 to n7, and R_{b1} to R_{b7} are the same as described in Formula 1. In Formula 1-B, A₁₄ and A₁₈ may each independently be represented by the first substituent. For example, A₁₄ and A₁₈ may each independently be a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms.

In Formula 1-B, A₁₁ to A₁₃ and A₁₅ to A₁₇ may each independently be a hydrogen atom, a deuterium atom, a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms. For example, A₁₁ to A₁₃ and A₁₅ to A₁₇ may each independently be a hydrogen atom or may be represented by any one of Formula F-1 to Formula F-11 as described above.

In an embodiment, Formula 1-B may be represented by any one of Formula 1-B1 to Formula 1-B3. Formula 1-B1 represents a case where A₁ to A₁₃ and A₁₅ to A₁₇ in Formula 1-B are hydrogen atoms. Formula 1-B2 represents a case where in Formula 1-B, A₁₂ and A₁₆ are represented by the first substituent and A₁₁, A₁₃, A₁₅, and A₁₇ are hydrogen atoms. Formula 1-B3 represents a case where in Formula 1-B, A₁₃ and A₁₇ are represented by the first substituent and A₁₁, A₁₂, A₁₅, and A₁₆ are hydrogen atoms. Formula 1-B2 and Formula 1-B3 represent the cases where four of A₁ to A₈ in Formula 1 are represented by the first substituent.

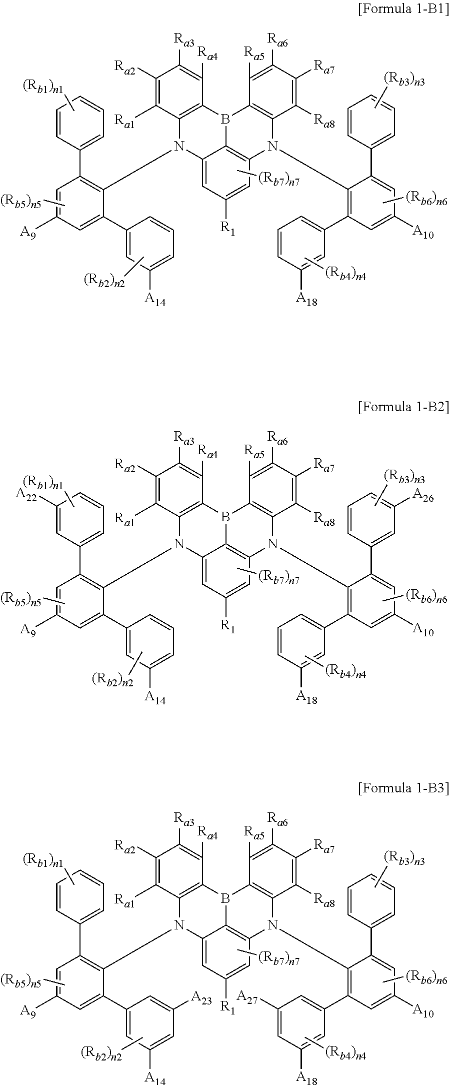

In Formula 1-1B1 to Formula 1-1B3, Rₐ₁ to Rₐ₈, A₉, A₁₀, A₁₄, A₁₈, R₁, n1 to n7, and R_{b1} to R_{b7} are the same as described in Formula 1. In Formula 1-B2 and Formula 1-B3, A₂₂, A₂₃, A₂₆, and A₂₇ may each independently be a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms. For example, A₂₂ and A₂₆ may each independently be a substituted or unsubstituted silyl group, a substituted or unsubstituted alkyl group having 1 to 10 carbon atoms, or a substituted or unsubstituted aryl group having 6 to 20 ring-forming carbon atoms. For example, A₂₃ and A₂₇ may each independently be a substituted or unsubstituted germanium group, a substituted or unsubstituted alkyl group having 1 to 10 carbon atoms, or a substituted or unsubstituted aryl group having 6 to 20 ring-forming carbon atoms.

In an embodiment, Formula 1 may be represented by Formula 1-C1 or Formula 1-C2. Formula 1-C1 and Formula 1-C2 each represent a case where A₉ and A₁₀ are further defined in Formula 1.

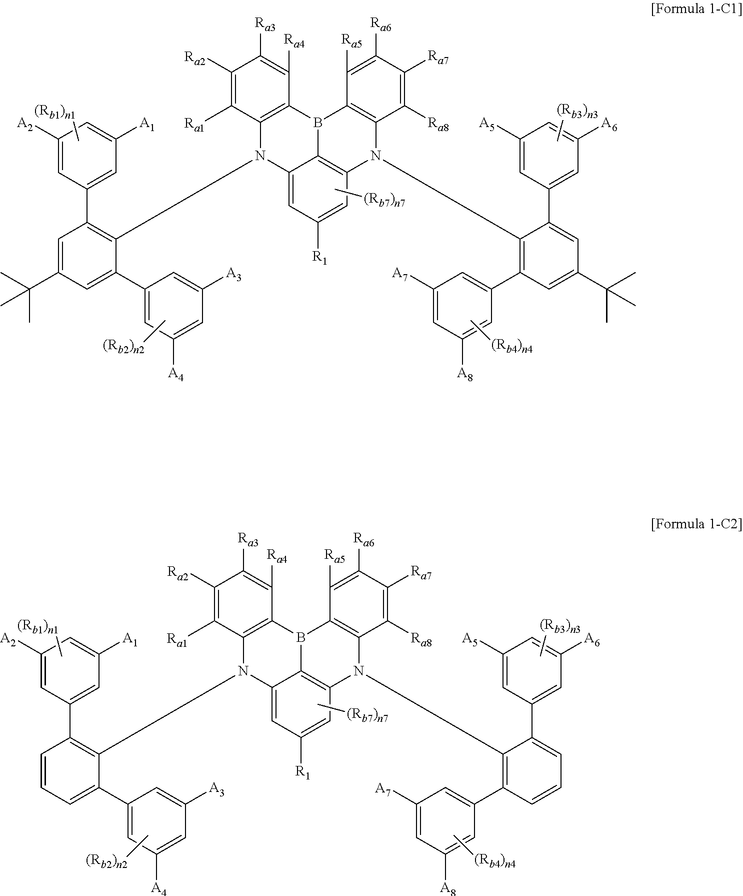

Formula 1-C1 represents a case where A₉ and A₁₀ in Formula 1 are each an unsubstituted t-butyl group. Formula 1-C2 represents a case where A₉ and A₁₀ in Formula 1 are each a hydrogen atom. In Formula 1-C1 and Formula 1-C2, Rₐ₁ to Rₐ₈, A₁ to A₈, R₁, n1 to n4, n7, R_{b1} to R_{b4}, and R_{b7} are the same as described in Formula 1.

In an embodiment, Formula 1 may be represented by Formula 1-X. Formula 1-X represents a case where R_{b1} to R_{b6} in Formula 1 are all hydrogen atoms and Rₐ₂ and Rₐ₇ in Formula 1 are each a group represented by Formula 2.

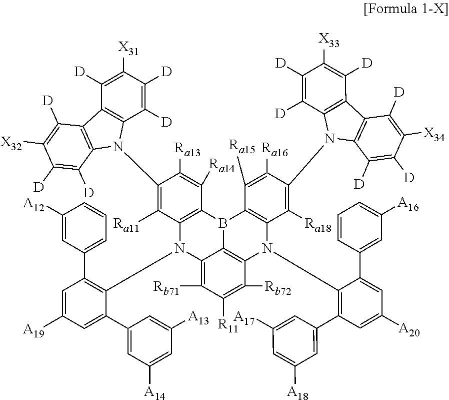

In Formula 1-X, Rₐ₁₁ to Rₐ₁₈ may each independently be a hydrogen atom or a deuterium atom. For example, Rₐ₁₁ to Rₐ₁₈ may all be hydrogen atoms or deuterium atoms.

In Formula 1-X, R_{b71} and R_{b72} may each independently be a hydrogen atom or a deuterium atom. For example, R_{b71} and R_{b72} may both be hydrogen atoms or may both be deuterium atoms.

In Formula 1-X, R₁₁ may be a substituted or unsubstituted alkyl group having 1 to 5 carbon atoms, a substituted or unsubstituted aryl group having 6 to 10 ring-forming carbon atoms, or a substituted or unsubstituted heteroaryl group having 6 to 15 ring-forming carbon atoms. For example, R₁₁ may be a substituted or unsubstituted methyl group, an unsubstituted ethyl group, an unsubstituted isopropyl group, an unsubstituted t-butyl group, a substituted or unsubstituted phenyl group, an unsubstituted diphenylamine group, an unsubstituted carbazole group, or an unsubstituted dibenzofuran group.

In Formula 1-X, A₁₄ and A₁₈ may each independently be represented by the first substituent. For example, A₁₄ and A₁₈ may each independently be a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms.

In Formula 1-X, A₁₂, A₁₃, A₁₆, and A₁₇ may each independently be a hydrogen atom, a deuterium atom, a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms. In Formula 1-X, A₁₉ and A₂₀ may each independently be a hydrogen atom, a cyano group, an unsubstituted t-butyl group, an unsubstituted phenyl group, or a phenyl group substituted with a cyano group. For example, A₁₉ and A₂₀ may be the same.

In Formula 1-X, D is a deuterium atom. In Formula 1-X, X₃₁ to X₃₄ may each independently be a deuterium atom, a cyano group, a substituted or unsubstituted methyl group, or a substituted or unsubstituted t-butyl group. For example, X₃₁ and X₃₃ may be the same, and X₃₂ and X₃₄ may be the same.

In an embodiment, the fused polycyclic compound may be any compound selected from Compound Group 1. In an embodiment, the light emitting element ED may include at least one compound selected from Compound Group 1. In Compound Group 1, D is a deuterium atom, D₃ represents three deuterium atoms, and D₈ represents eight deuterium atoms.

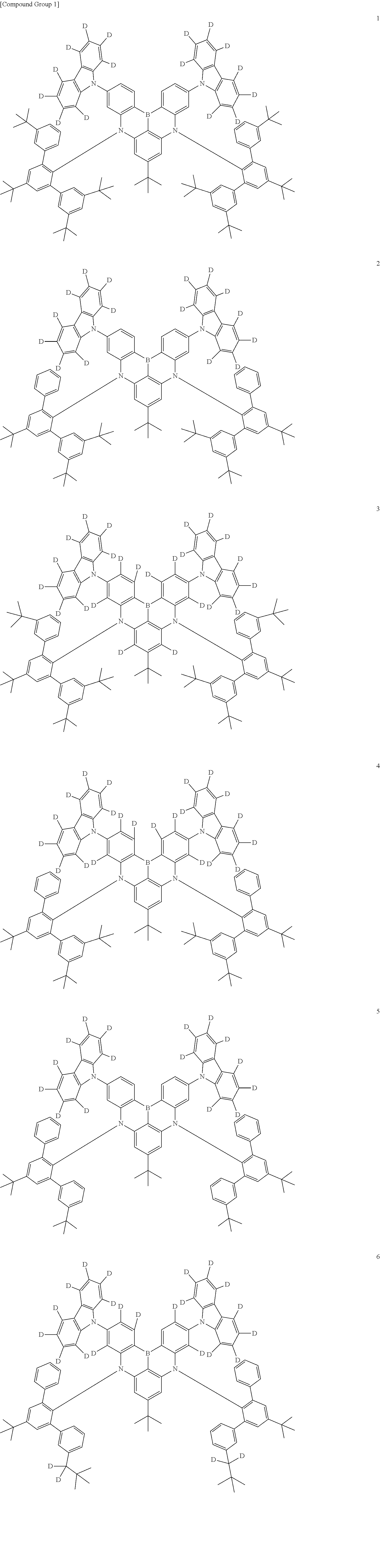

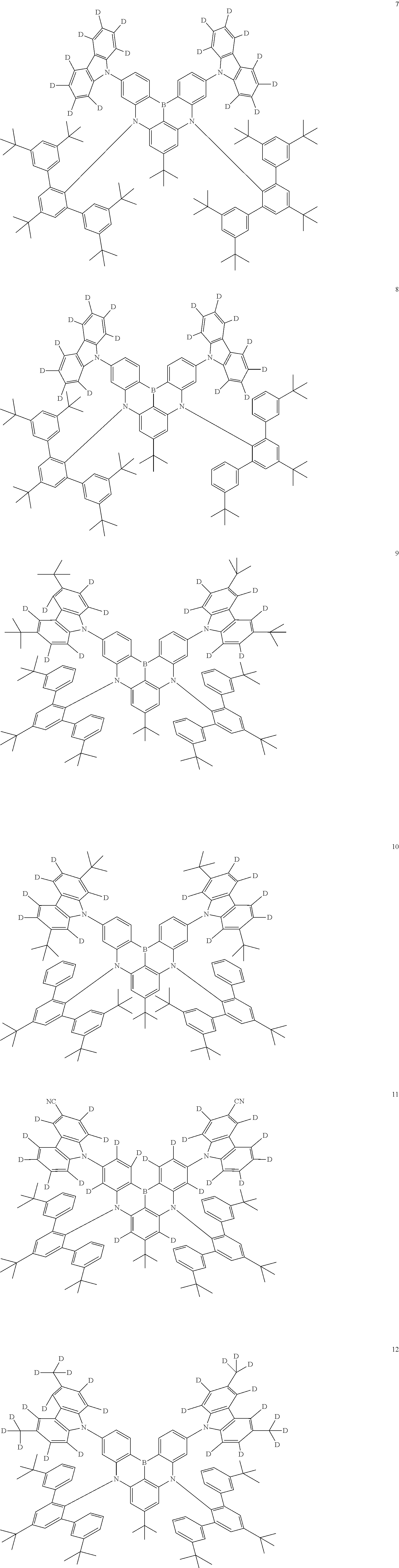

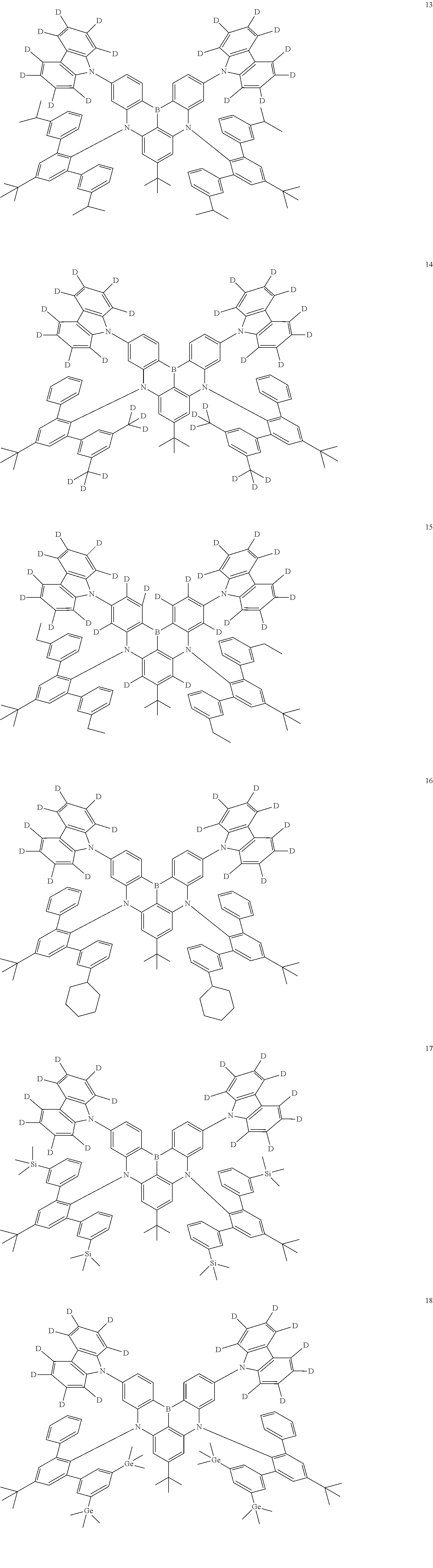

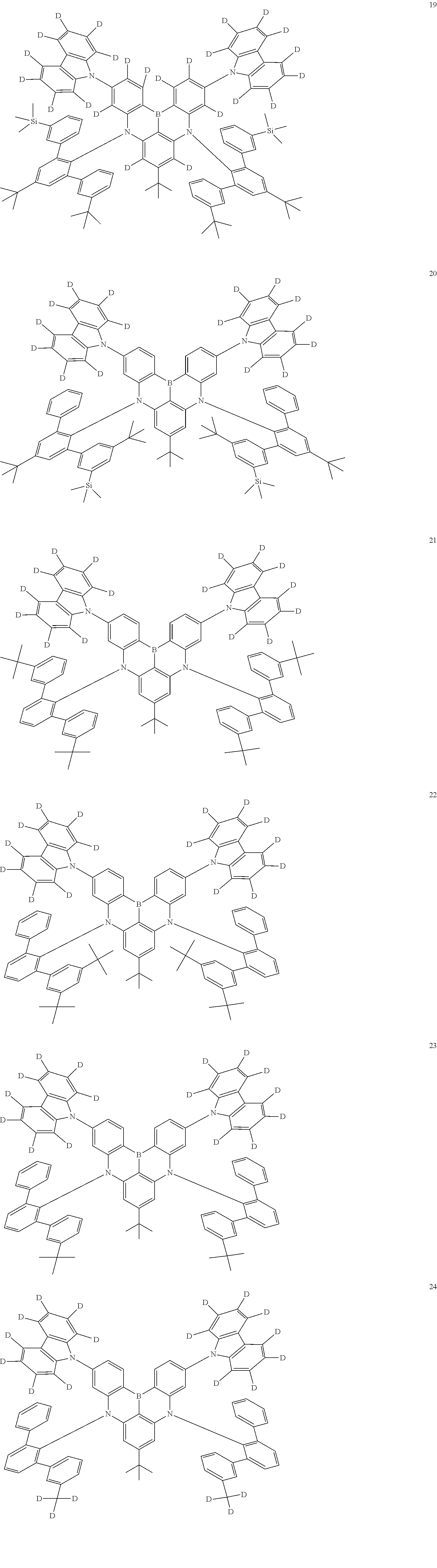

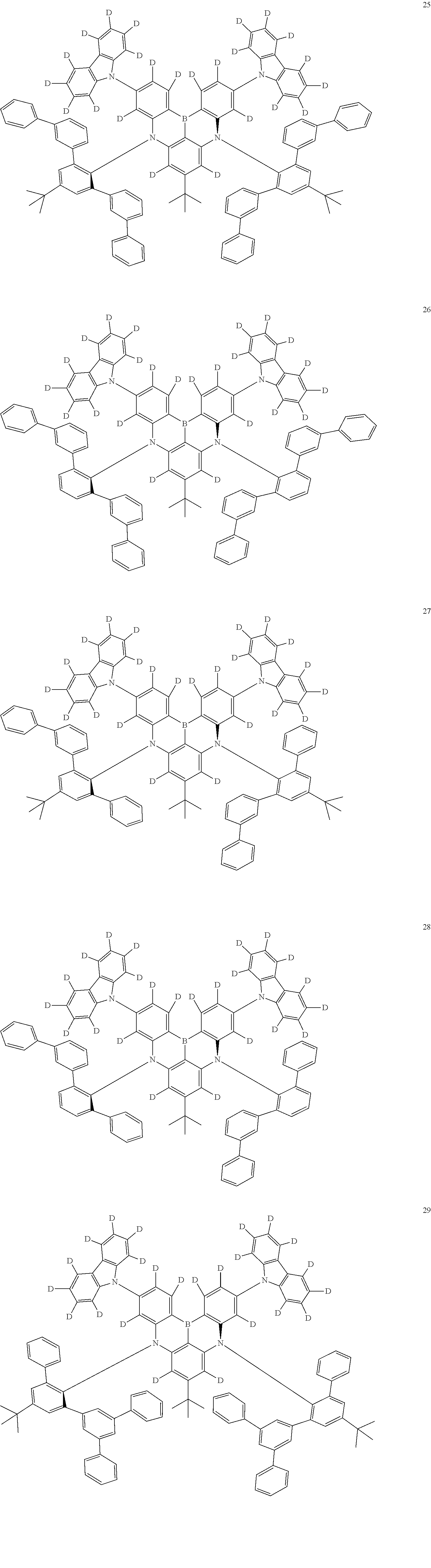

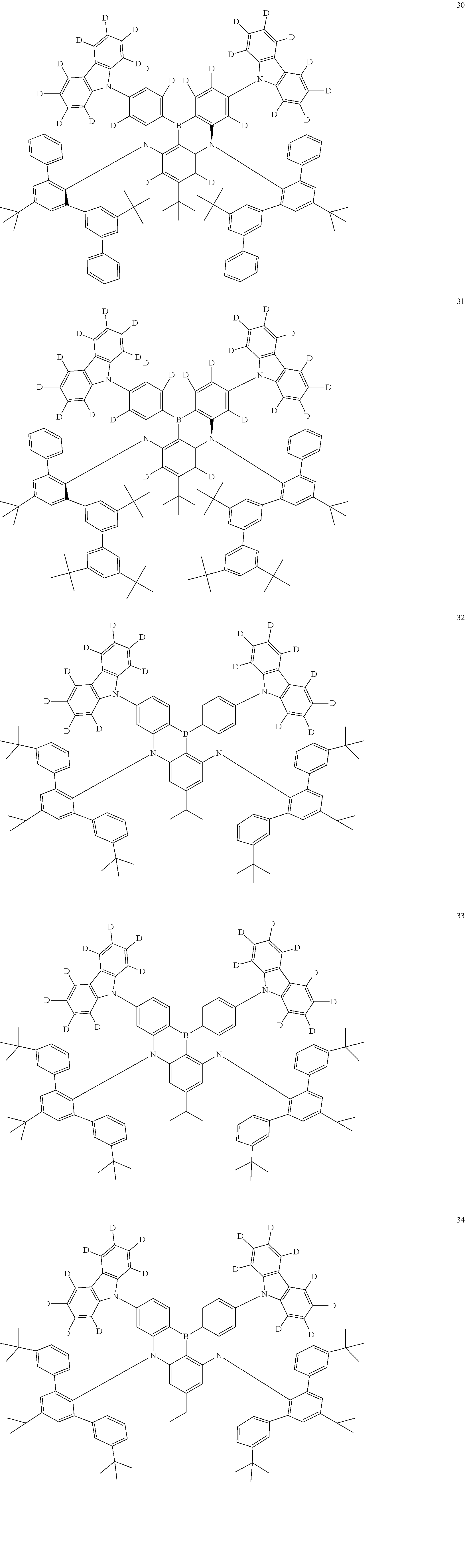

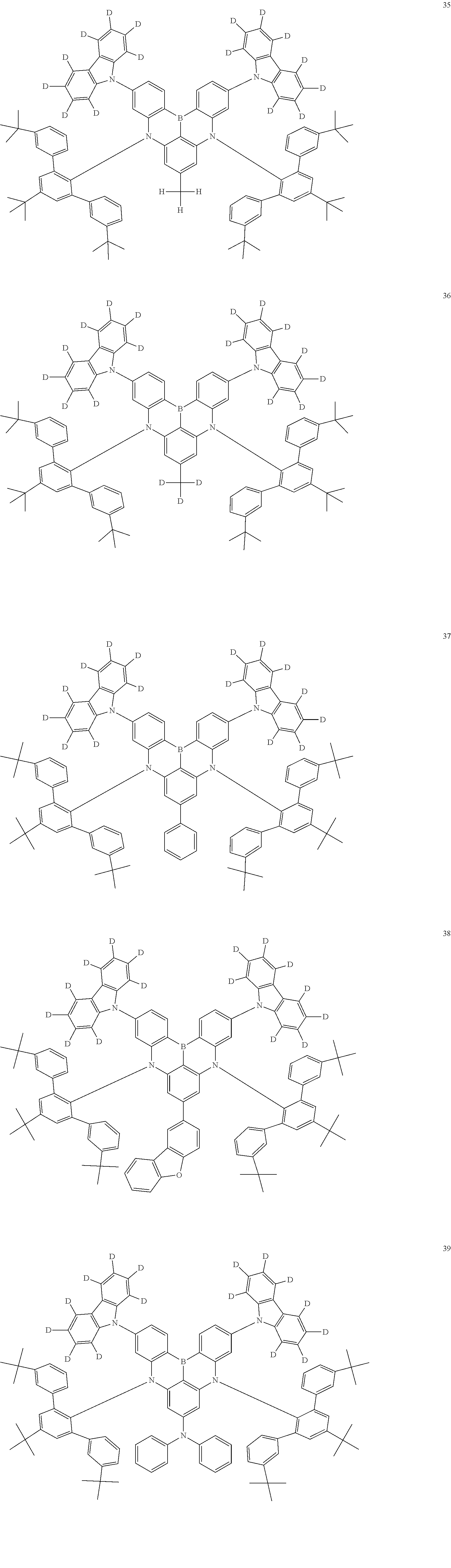

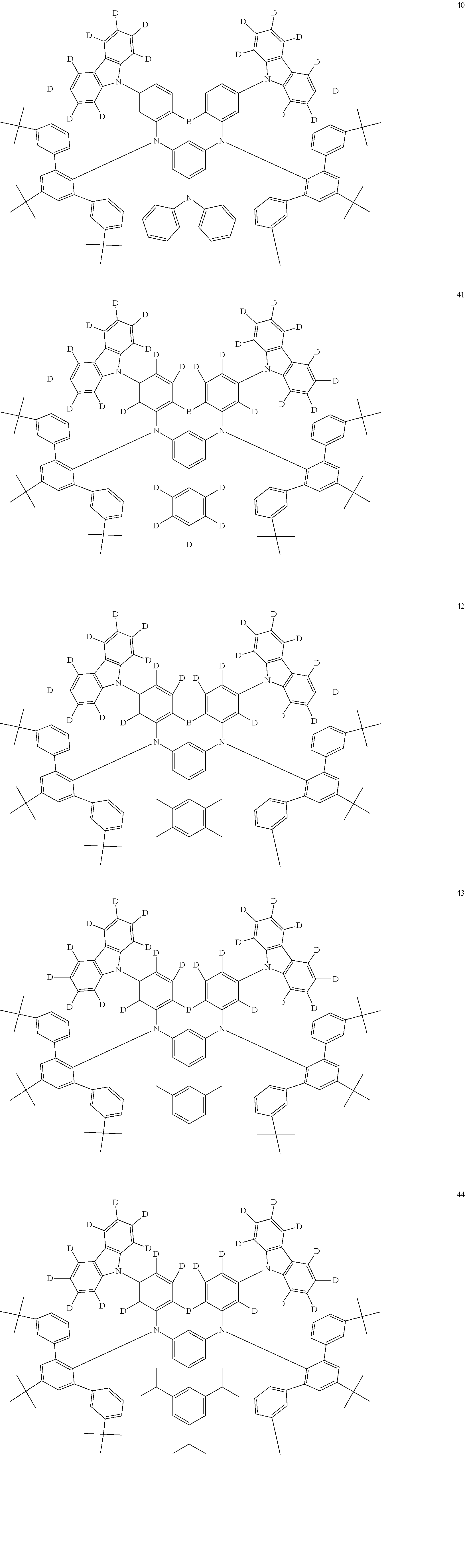

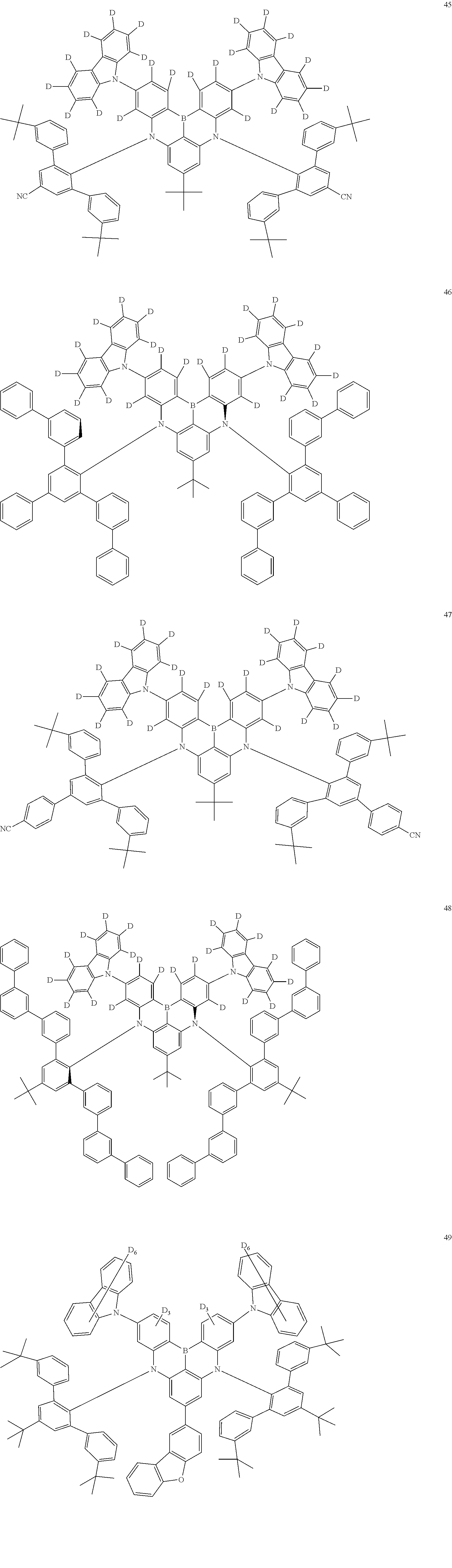

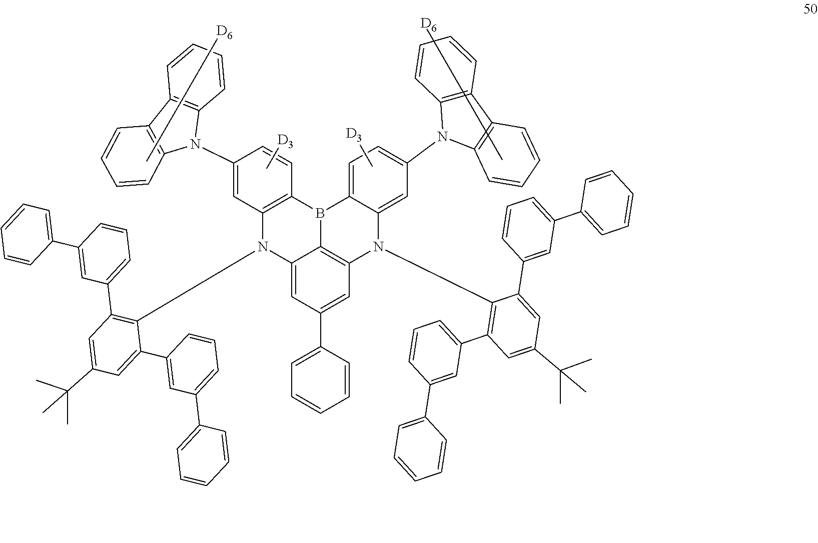

The fused polycyclic compound according to an embodiment may include, as a central structure, a pentacyclic fused ring containing two nitrogen atoms and one boron atom as ring-forming atoms. In the pentacyclic fused ring, substituted ortho terphenyl groups may be bonded to the two nitrogen atoms. At least one phenyl group of two phenyl groups other than the phenyl group directly bonded to the nitrogen atom of the three phenyl groups forming the ortho terphenyl group may be substituted with the first substituent as described above. The fused polycyclic compound according to an embodiment may include a structure represented by Formula Z1:

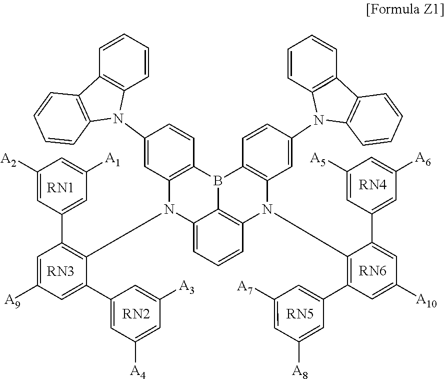

In Formula Z1, A₁ to A₁₀ are the same as described in Formula 1. In Formula Z1, RN1 to RN6 are marked in order to indicate ring groups forming the ortho terphenyl group, and the ring groups of RN1 to RN6 may correspond to the first to sixth phenyl groups as described above.

The fused polycyclic compound according to an embodiment may include the substituted ortho terphenyl group (phenyl groups of RN1 to RN6 in Formula Z1), and thus the steric structure of the molecule may have a spherical shape, thereby preventing interactions between molecules. Accordingly, the fused polycyclic compound may contribute to the improvement in the light efficiency and service life of the light emitting element ED because Dexter energy transfer is prevented. The light emitting element ED including the fused polycyclic compound according to an embodiment may exhibit high efficiency and long service life characteristics.

In an embodiment, the emission layer EML may include a host and a dopant, and the dopant may include the fused polycyclic compound. The fused polycyclic compound according to an embodiment may be included as a dopant material for the emission layer EML. The fused polycyclic compound according to an embodiment may be used as a blue dopant material. The fused polycyclic compound according to an embodiment may emit thermally activated delayed fluorescence (TADF).

In an embodiment, the emission layer EML may include at least one of the second to fourth compounds. The second compound and the third compound may each be a host material. The fourth compound may be a sensitizer. In an embodiment, the emission layer may include the first compound, the second compound, the third compound, and the fourth compound. For example, the emission layer EML may include at least two hosts, a sensitizer, and a dopant. The emission layer EML may include a hole transport host and an electron transport host. The emission layer EML may include a phosphorescent sensitizer as the sensitizer.

In the emission layer EML, the hole transport host and the electron transport host may form an exciplex. A triplet energy of the exciplex formed by the hole transport host and the electron transport host may correspond to a difference between a lowest unoccupied molecular orbital (LUMO) energy level of the electron transport host and a highest occupied molecular orbital (HOMO) energy level of the hole transport host. For example, the absolute value of the triplet energy (T1) of the exciplex formed by the hole transport host and the electron transport host may be in a range of about 2.4 eV to about 3.0 eV. The triplet energy of the exciplex may be a value smaller than an energy gap of each host material. The exciplex may have a triplet energy of equal to or less than about 3.0 eV that is an energy gap between the hole transport host and the electron transport host. However, this is an example, and the embodiments are not limited thereto.

When the emission layer EML includes a hole transport host, an electron transport host, a sensitizer, and a dopant, the hole transport host and the electron transport host may form an exciplex, and energy may be transferred from the exciplex to the sensitizer and from the sensitizer to the dopant, and thus light may be emitted. However, this is an example, and materials included in the emission layer EML are not limited thereto. The hole transport host and the electron transport host may not form an exciplex. When the hole transport host and the electron transport host do not form an exciplex, the energy may be transferred from the hole transport host and the electron transport host to the sensitizer, and from the sensitizer to the dopant, and thus light may be emitted.

In an embodiment, the emission layer EML may include about 0.5 wt % to about 2.5 wt % of the fused polycyclic compound, with respect to a total weight of the emission layer EML. The emission layer EML may include about 10 wt % to about 20 wt % of the fourth compound, with respect to a total weight of the emission layer EML. The light emitting element ED may include about 0.5 wt % to about 2.5 wt % of the fused polycyclic compound and may exhibit high efficiency and long service life characteristics. In an embodiment, the light emitting element ED may further include about 10 wt % to about 20 wt % of the fourth compound, and may exhibit excellent efficiency and service life characteristics.

In an embodiment, the emission layer EML may include a second compound represented by Formula HT-1. In an embodiment, the second compound represented by Formula HT-1 may be used as a hole transport host material for the emission layer EML.

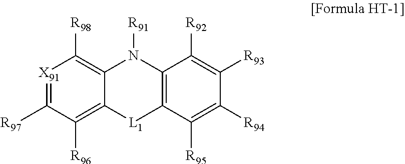

In Formula HT-1, L₁ may be a direct linkage, C(R₉₉)(R₁₀₀), or Si(R₁₀₁)(R₁₀₂). In Formula HT-1, X₉₁ may be N or C(R₁₀₃). When L₁ is a direct linkage and X₉₁ is C(R₁₀₃), the second compound represented by Formula HT-1 may include a carbazole group.

In Formula HT-1, R₉₁ to R₁₀₃ may each independently be a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or may be bonded to an adjacent group to form a ring. For example, R₉₁ may be a substituted phenyl group, an unsubstituted dibenzofuran group, or a substituted fluorenyl group. For example, any one of R₉₂ to R₉₈ may be a substituted or unsubstituted carbazole group. For example, R₉₄ and R₉₅ may be bonded to each other to form a ring. However, embodiments are not limited thereto.

In an embodiment, the second compound represented by Formula HT-1 may be any compound selected from Compound Group 2. In an embodiment, in the light emitting element ED, the second compound may include at least one compound selected from Compound Group 2. In Compound Group 2, D is a deuterium atom, and Ph is a phenyl group.

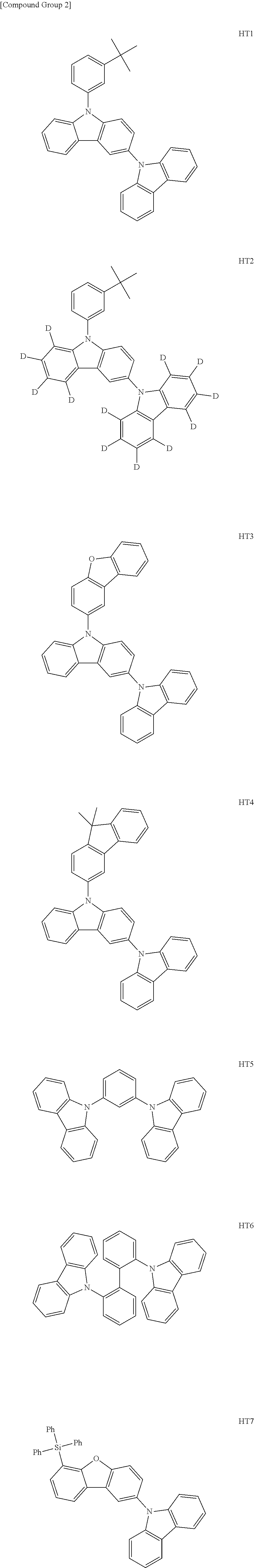

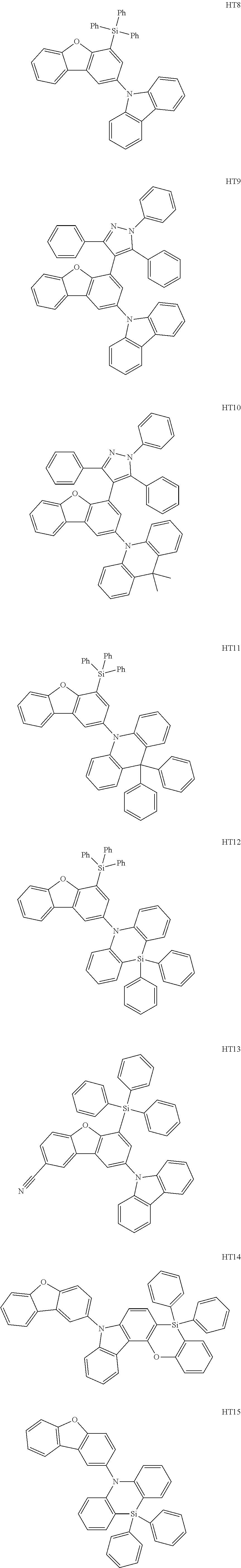

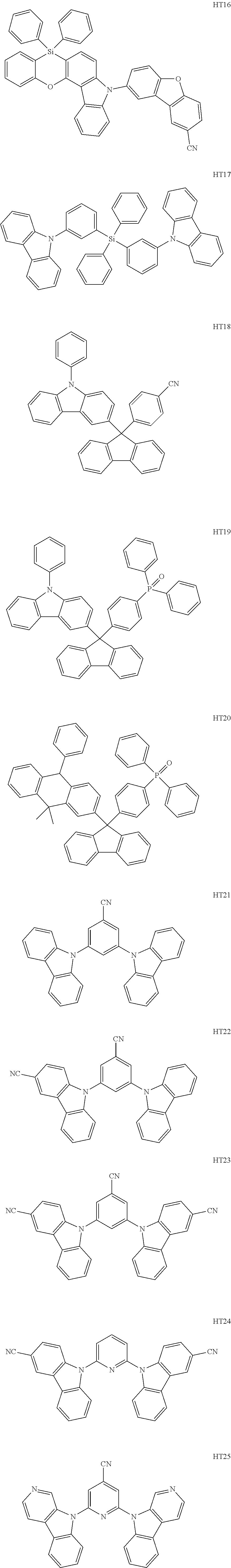

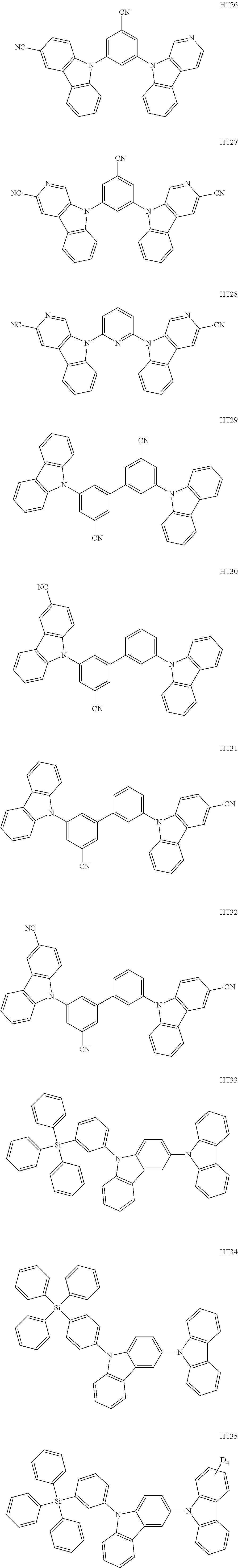

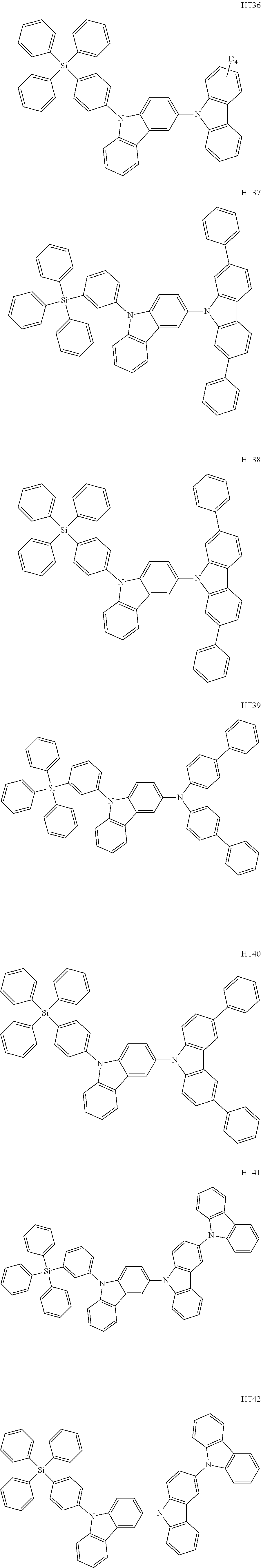

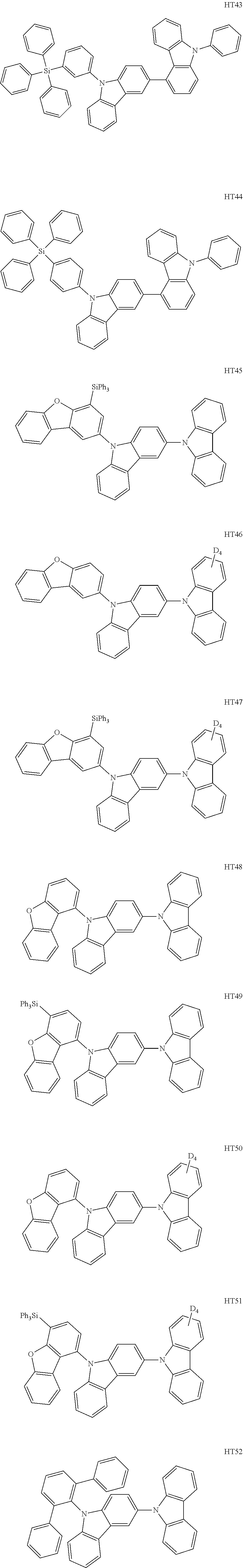

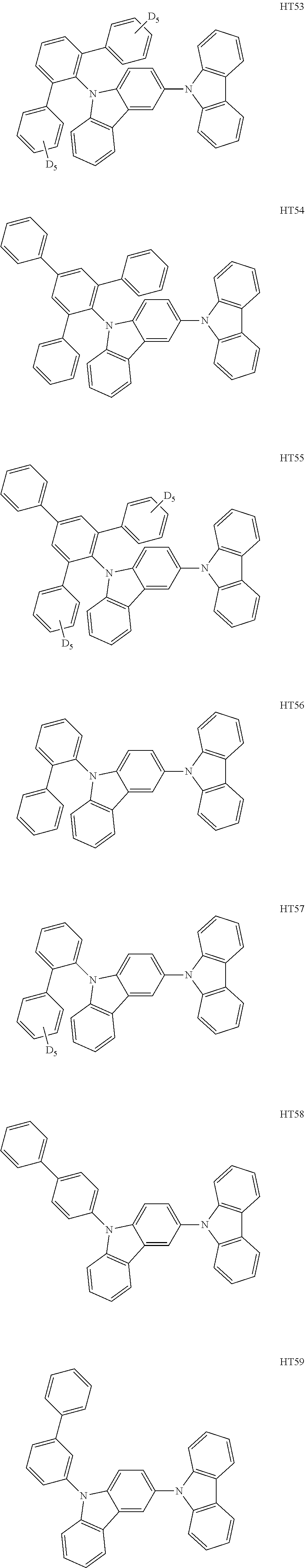

In an embodiment, the emission layer EML may include a third compound represented by Formula ET-1. In an embodiment, the third compound represented by Formula ET-1 may be used as an electron transport host material for the emission layer EML.

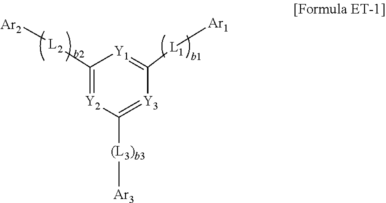

In Formula ET-1, at least one of Y₁ to Y₃ may each be N; and the remainder of Y₁ to Y₃ may each independently be C(Rₐ). In Formula ET-1, Rₐ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

When one of Y₁ to Y₃ is N, the third compound represented by Formula ET-1 may include a pyridine group. When two of Y₁ to Y₃ are N, the third compound represented by Formula ET-1 may include a pyrimidine group. When all of Y₁ to Y₃ are N, the third compound represented by Formula ET-1 may include a triazine group.

In Formula ET-1, b1 to b3 may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₁ to L₃ may each independently be a substituted or unsubstituted arylene group having 6 to 30 ring-forming carbon atoms or a substituted or unsubstituted heteroarylene group having 2 to 30 ring-forming carbon atoms.

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group, or a substituted or unsubstituted carbazole group. However, embodiments are not limited thereto.

In an embodiment, the third compound represented by Formula ET-1 may be selected from Compound Group 3. In an embodiment, in the light emitting element ED, the third compound may include at least one compound selected from Compound Group 3. In Compound Group 3, D is a deuterium atom.

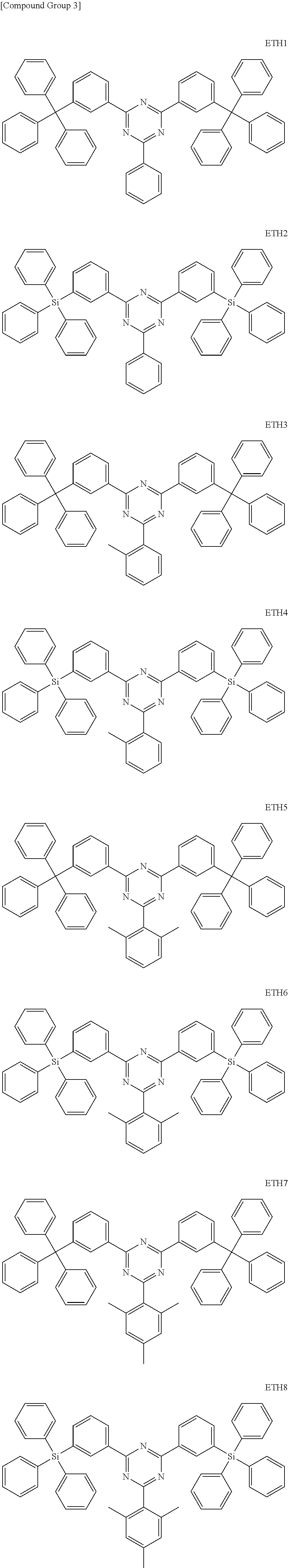

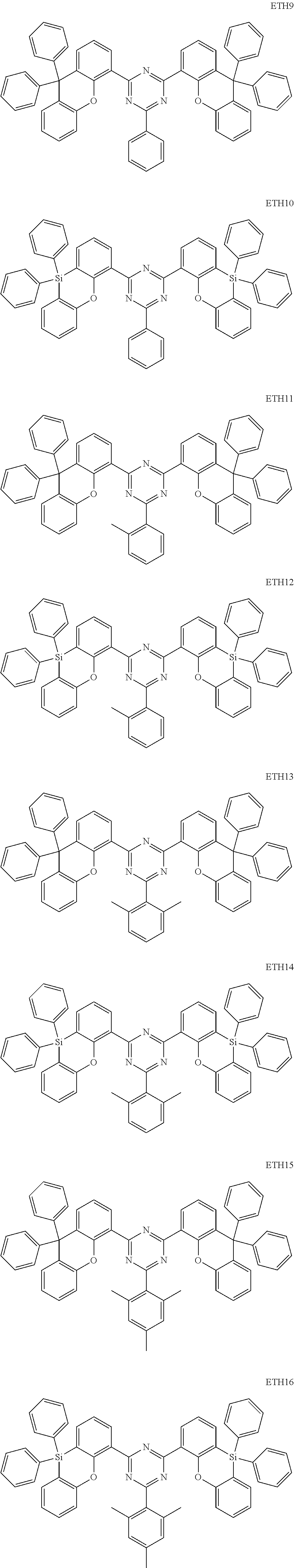

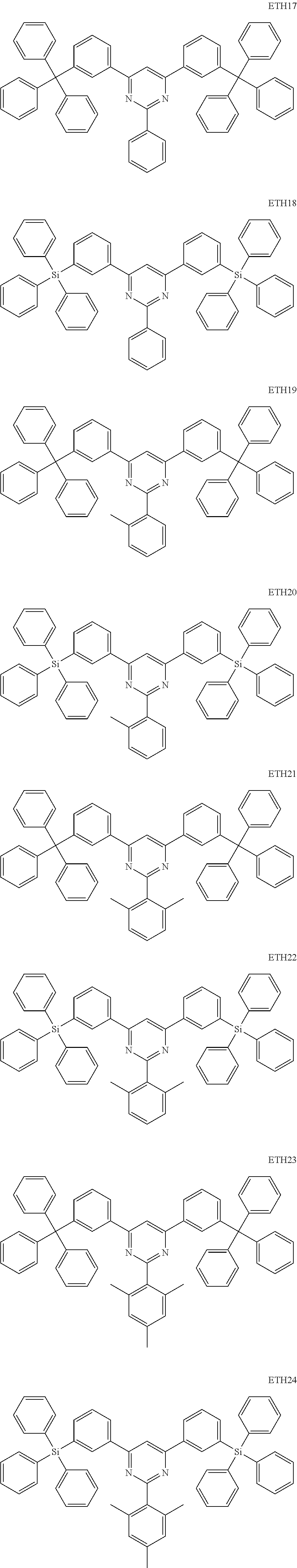

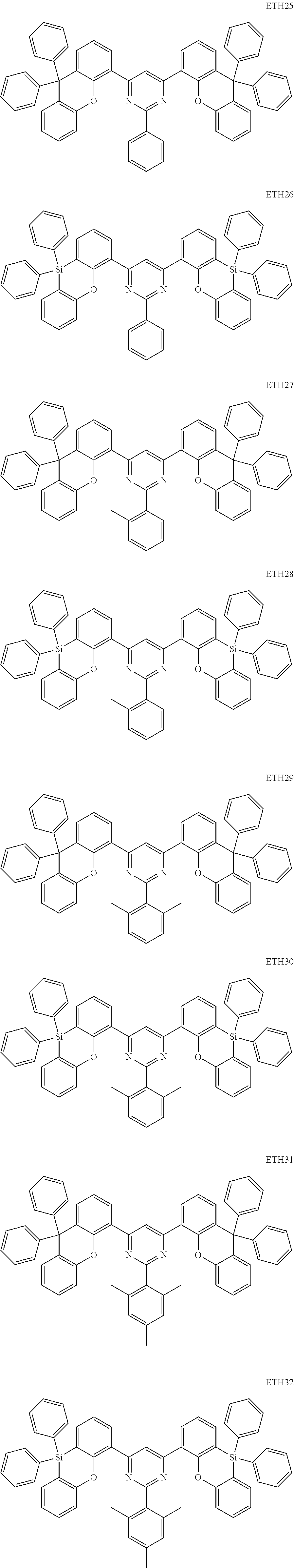

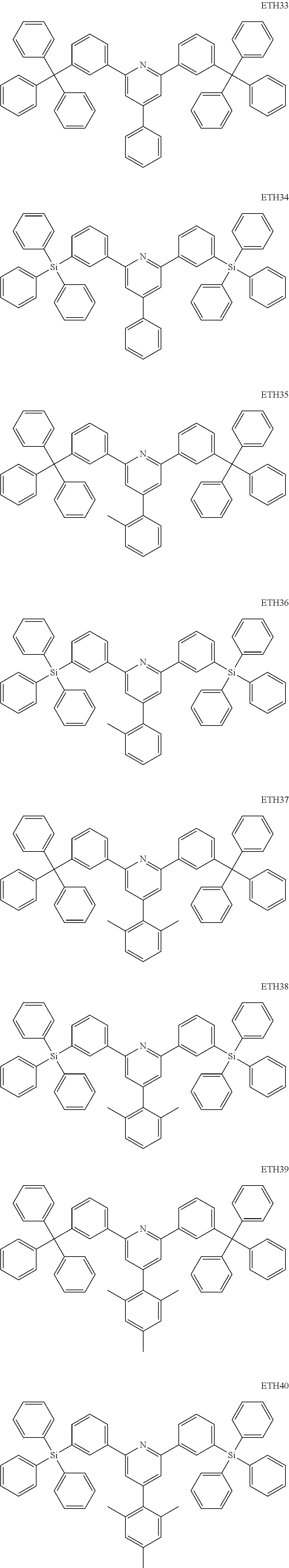

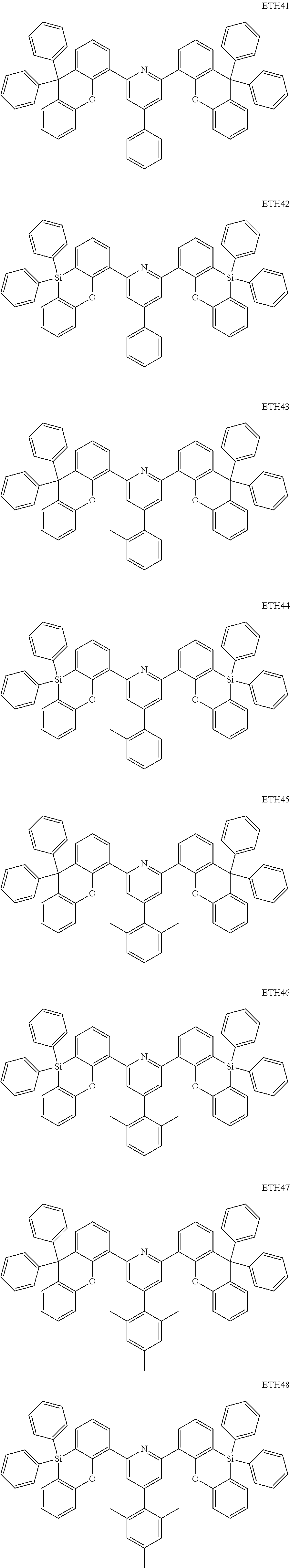

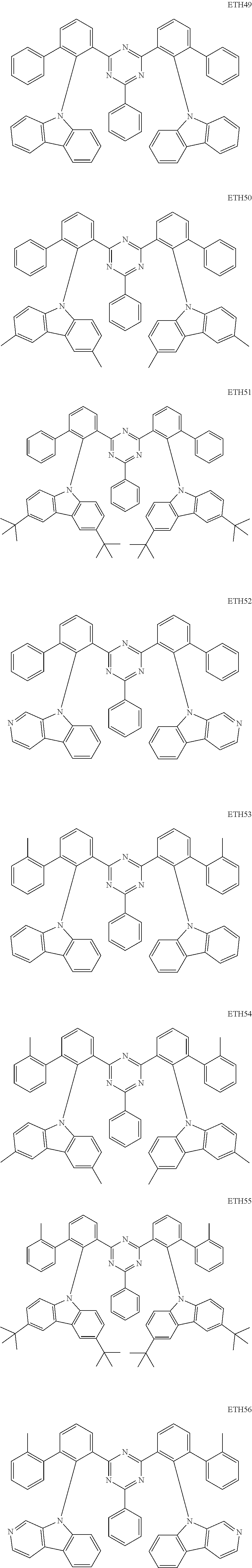

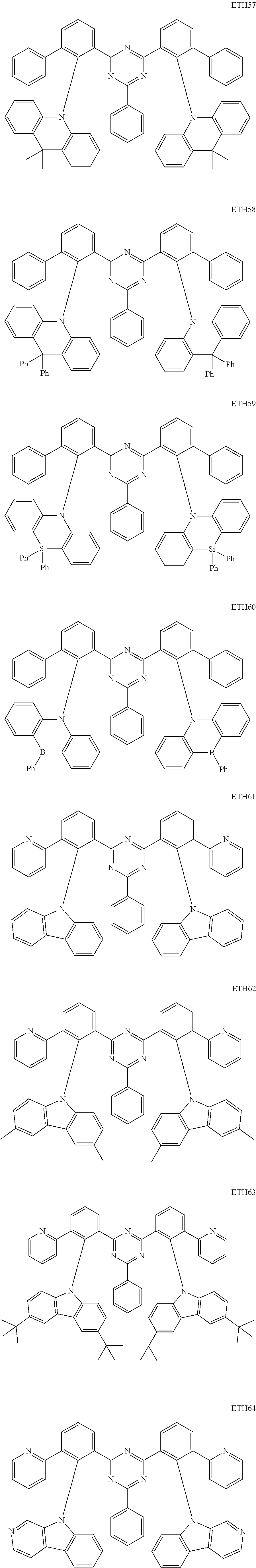

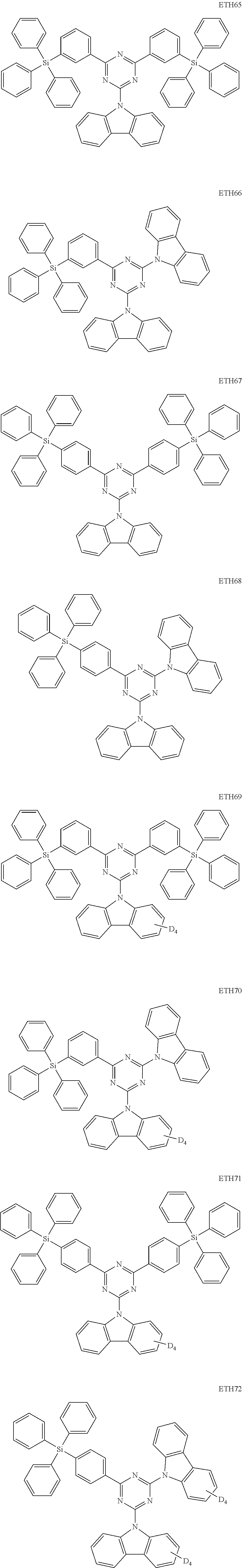

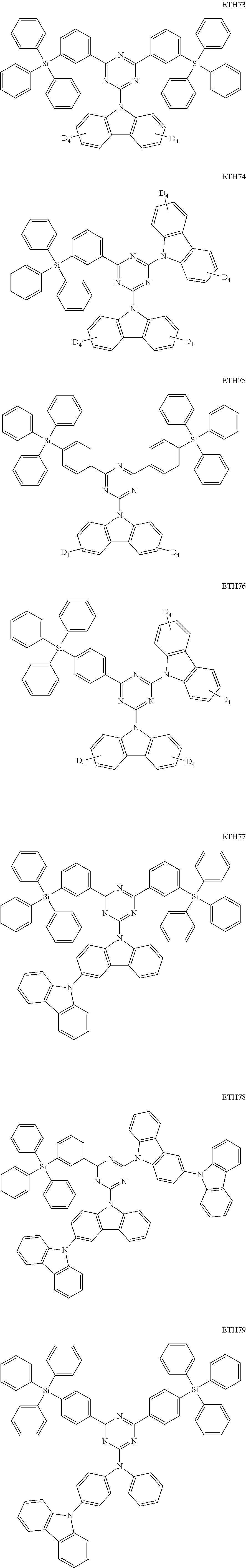

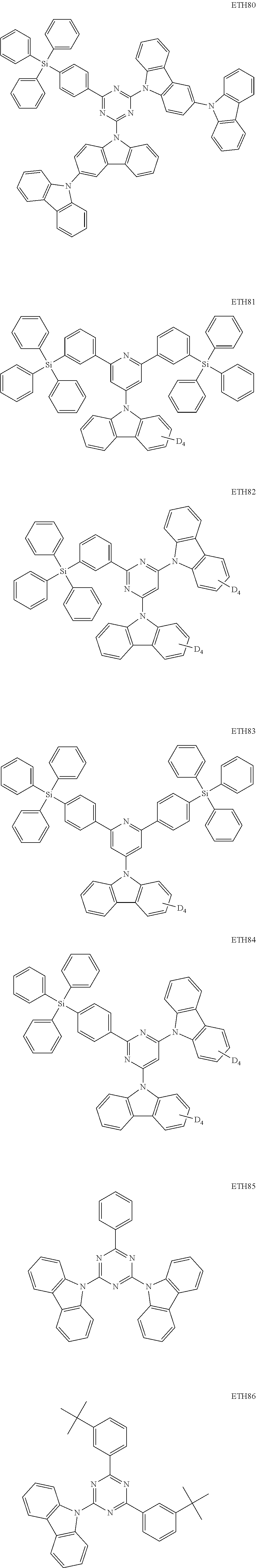

In an embodiment, the emission layer EML may include a fourth compound represented by Formula M-b. In an embodiment, the fourth compound represented by Formula M-b may be used as a phosphorescent dopant material or as a sensitizer for the emission layer EML. For example, the emission layer EML may include the fourth compound as a sensitizer.

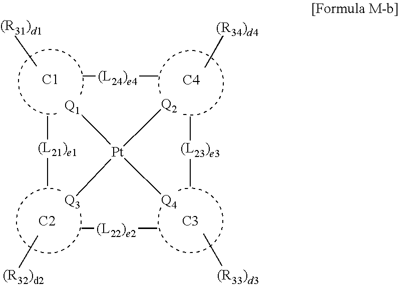

In Formula M-b, Q₁ to Q₄ may each independently be C or N. In Formula M-b, C1 to C4 may each independently be a substituted or unsubstituted hydrocarbon ring group having 5 to 30 ring-forming carbon atoms or a substituted or unsubstituted heterocyclic group having 2 to 30 ring-forming carbon atoms.

In Formula M-b, e1 to e4 may each independently be 0 or 1. In Formula M-b, L₂₁ to L₂₄ may each independently be a direct linkage,

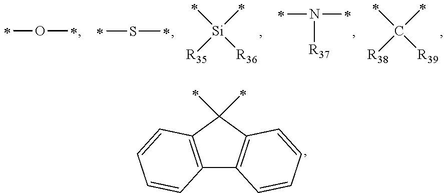

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. In Formula M-b, R₃₁ to R₃₉ may each independently be a hydrogen atom, a deuterium atom, a halogen atom, a cyano group, a substituted or unsubstituted divalent alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, the compound represented by Formula M-b may be used as a blue phosphorescent dopant or a green phosphorescent dopant.

In an embodiment, the fourth compound represented by Formula M-b may be selected from Compound Group 4. In an embodiment, in the light emitting element ED, the fourth compound may include at least one compound selected from Compound Group 4. However, the compounds in Compound Group 4 are only examples, and the compound represented by Formula M-b is not limited to Compound Group 4.

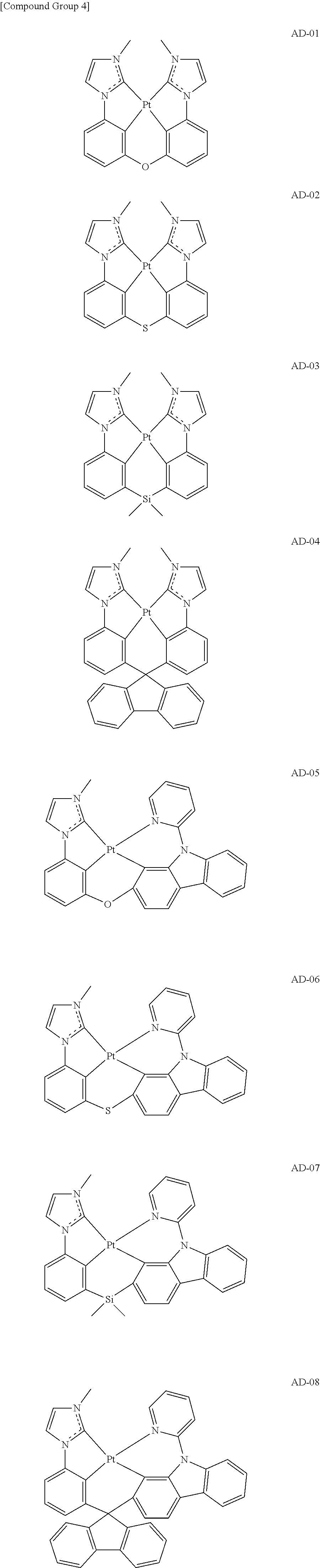

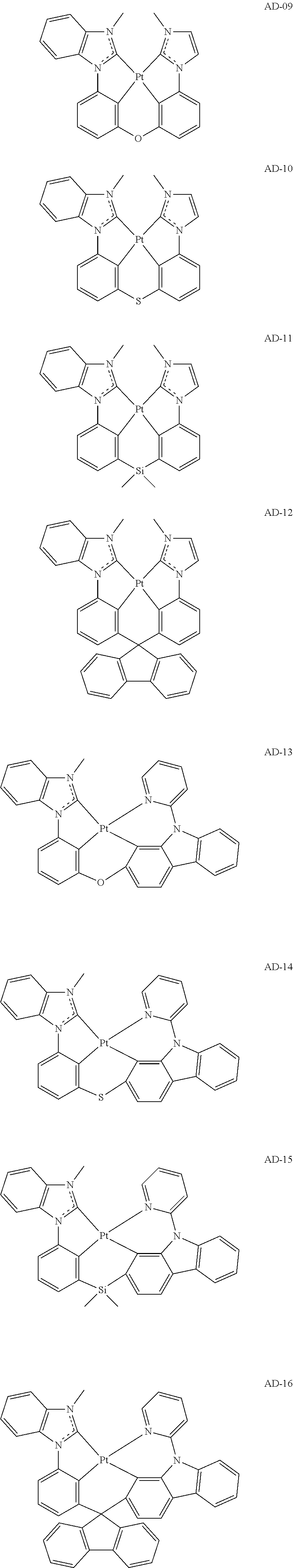

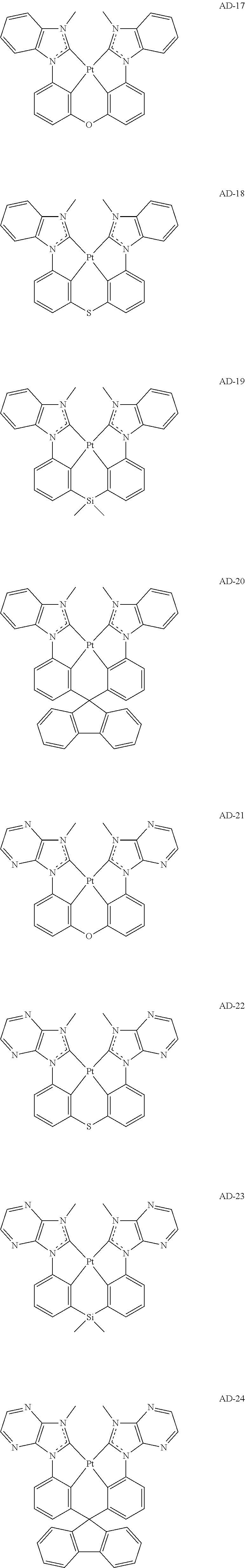

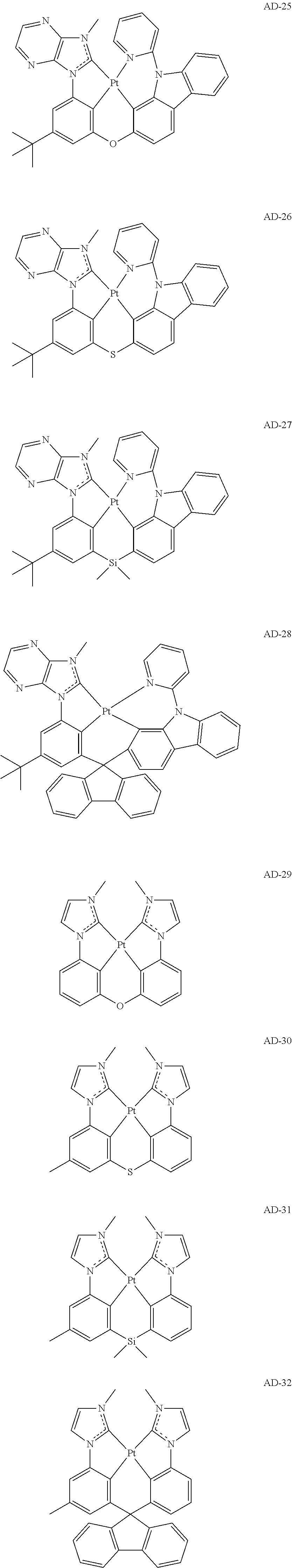

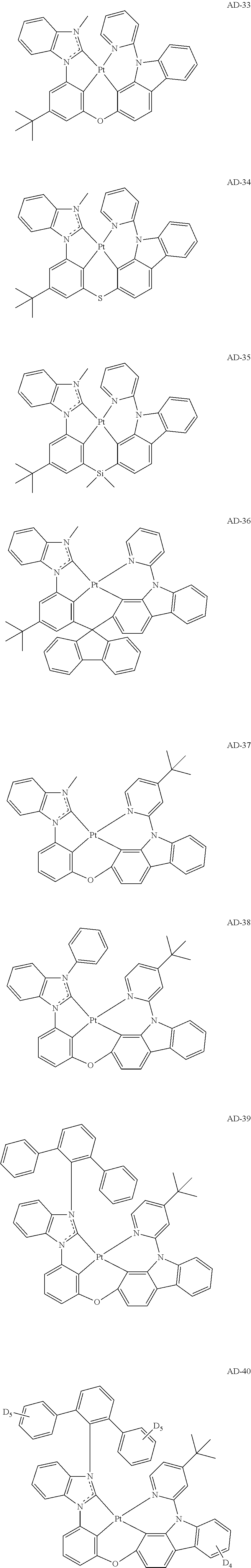

In an embodiment, the emission layer EML may include the fused polycyclic compound and at least one of the second to fourth compounds. When the light emitting element ED includes the fused polycyclic compound and at least one of the second to fourth compounds, it may exhibit high efficiency and long service life characteristics.

The emission layer EML may have a thickness, for example, in a range about 100 Å to about 1,000 k. For example, the emission layer EML may have a thickness in a range of about 100 k to about 300 k. The emission layer EML may be a layer consisting of a single material, a layer including different materials, or a structure including multiple layers including different materials.

The emission layer EML in the light emitting element ED may include an anthracene derivative, a pyrene derivative, a fluoranthene derivative, a chrysene derivative, a dihydrobenzanthracene derivative, or a triphenylene derivative. In an embodiment, the emission layer EML may include an anthracene derivative or a pyrene derivative.

As described above, the emission layer EML may include a host and a dopant. The emission layer EML may include a compound represented by Formula E-1. The compound represented by Formula E-1 may be used as a fluorescent host material.

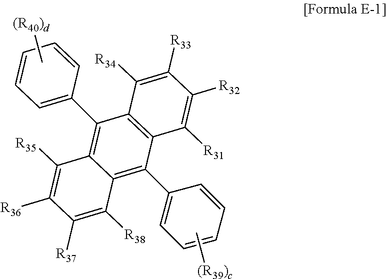

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In an embodiment, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer from 0 to 5. When c is 2 or greater, multiple R₃₉ groups may be the same as each other or at least one may be different from the others. When d is 2 or greater, multiple R₄₀ groups may be the same as each other or at least one may be different from the others.

In an embodiment, the compound represented by Formula E-1 may be any compound selected from Compound E1 to Compound E19:

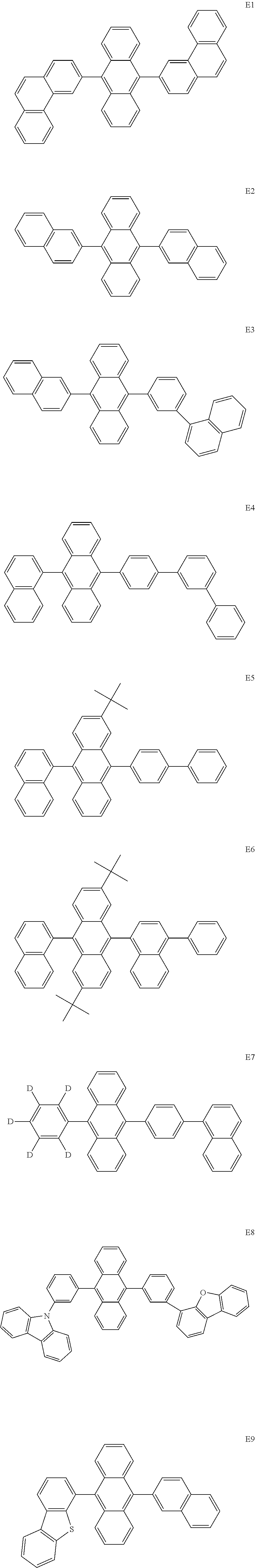

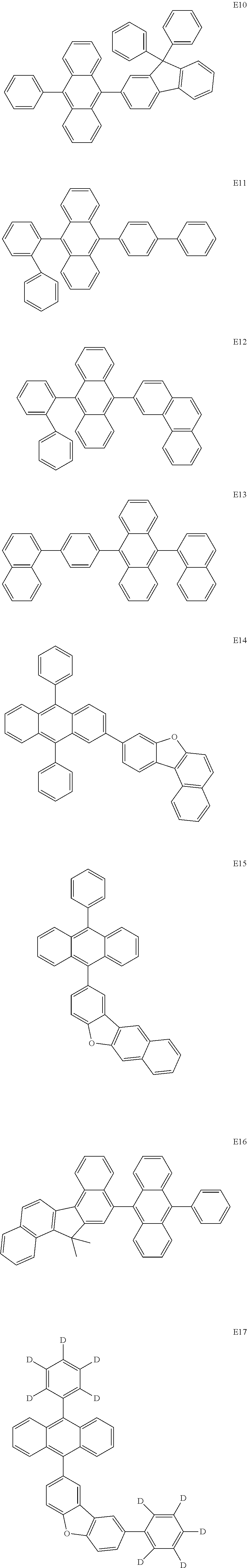

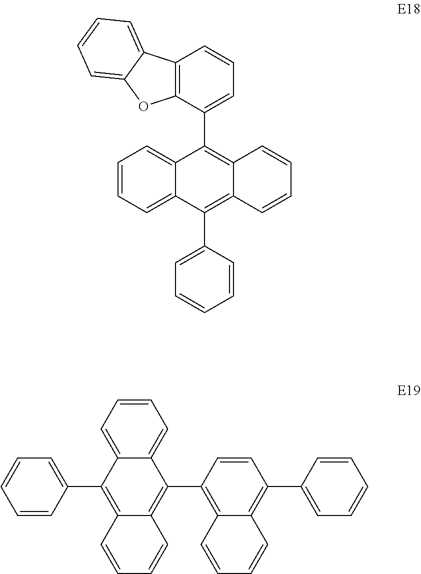

In an embodiment, the emission layer EML may include a compound represented by Formula E-2a or Formula E-2b. The compound represented by Formula E-2a or Formula E-2b may be used as a phosphorescent host material.

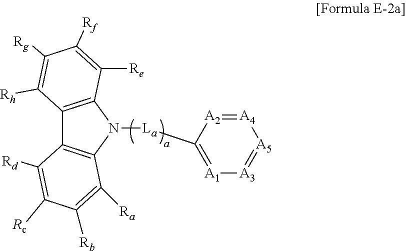

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

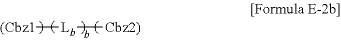

In Formula E-2b, Cbz1 and Cbz2 may each independently be an unsubstituted carbazole group, or a carbazole group substituted with an aryl group having 6 to 30 ring-forming carbon atoms. In Formula E-2b, Le may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or more, multiple Le groups may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

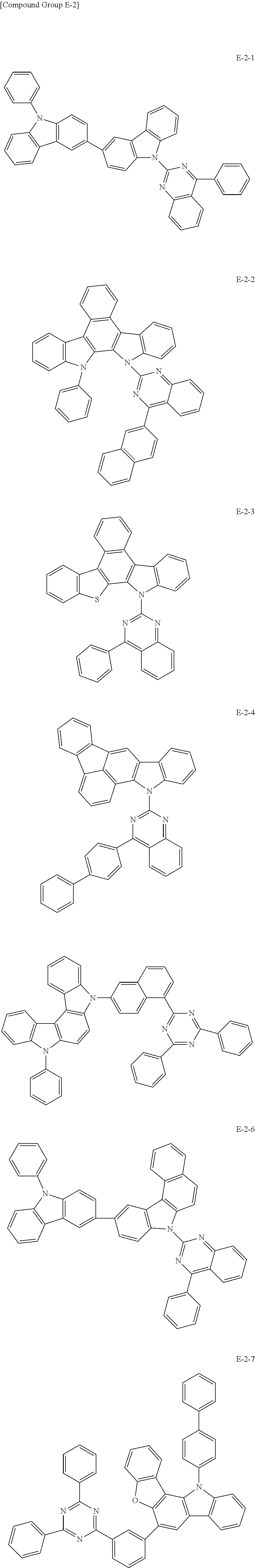

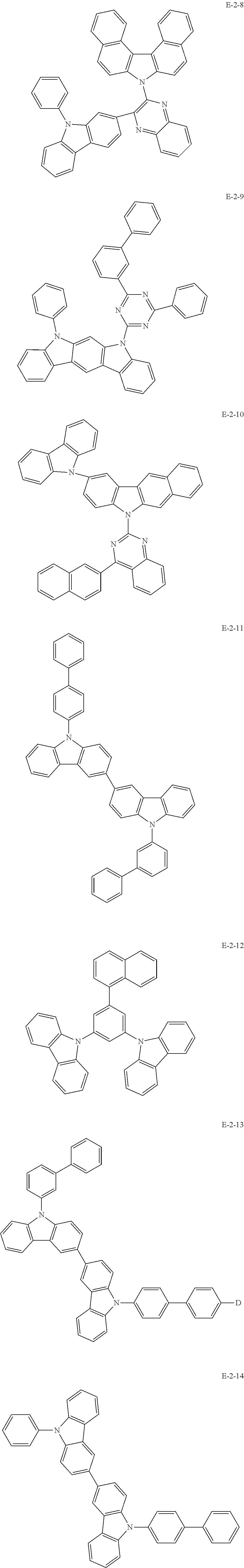

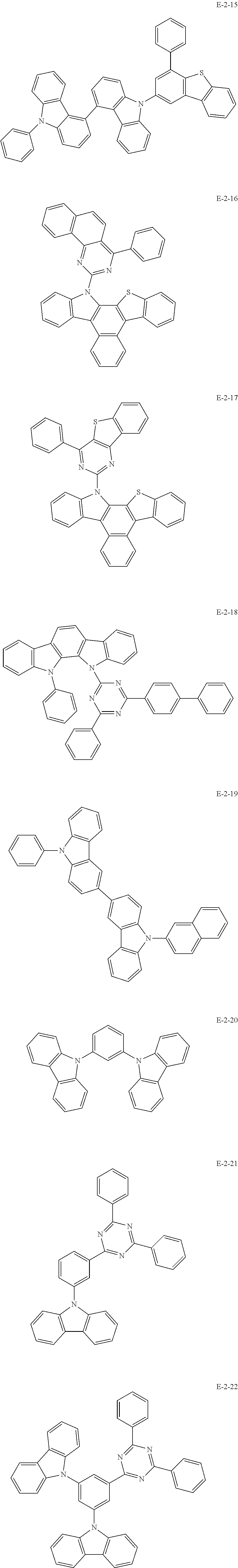

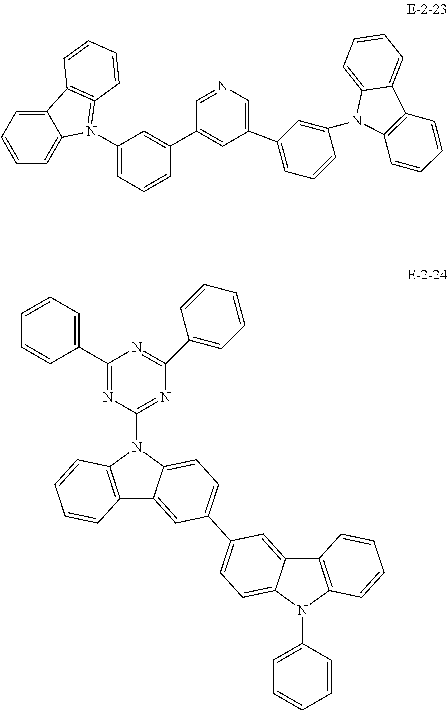

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tins(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include the compound represented by Formula M-a. The compound represented by Formula M-a may be used as a phosphorescent dopant material.

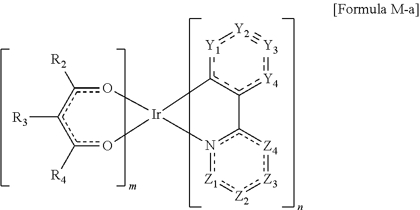

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25.

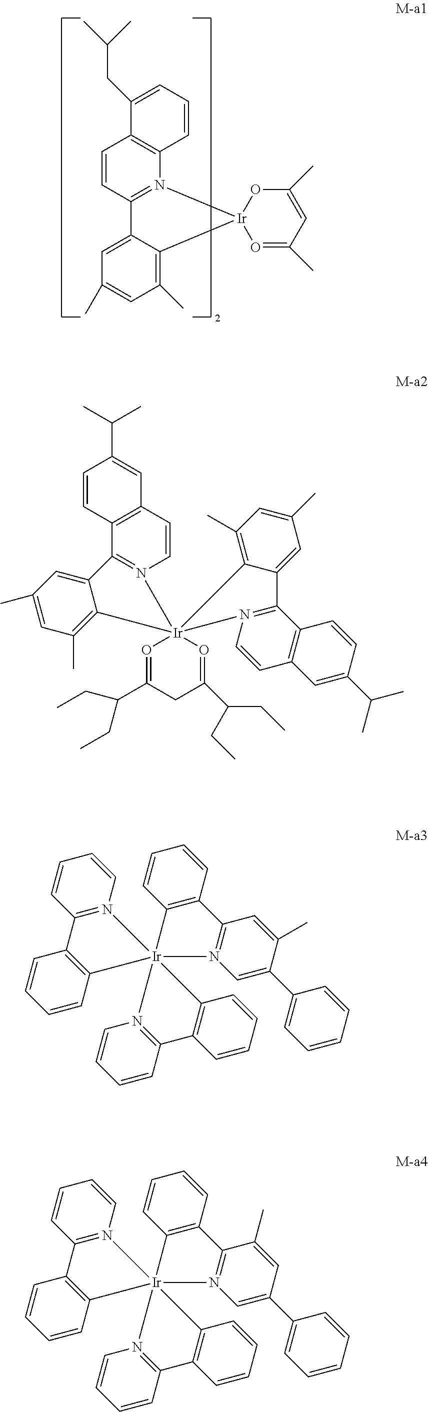

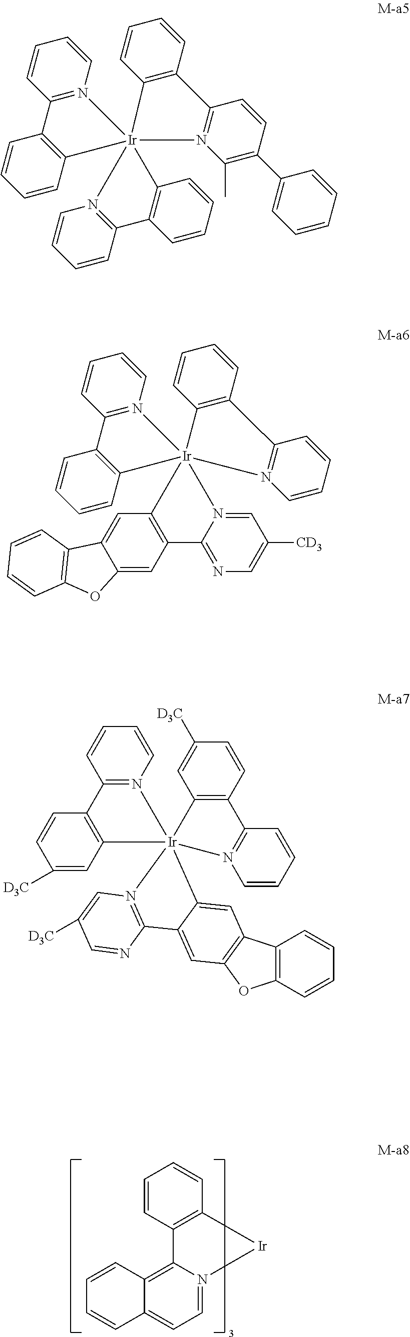

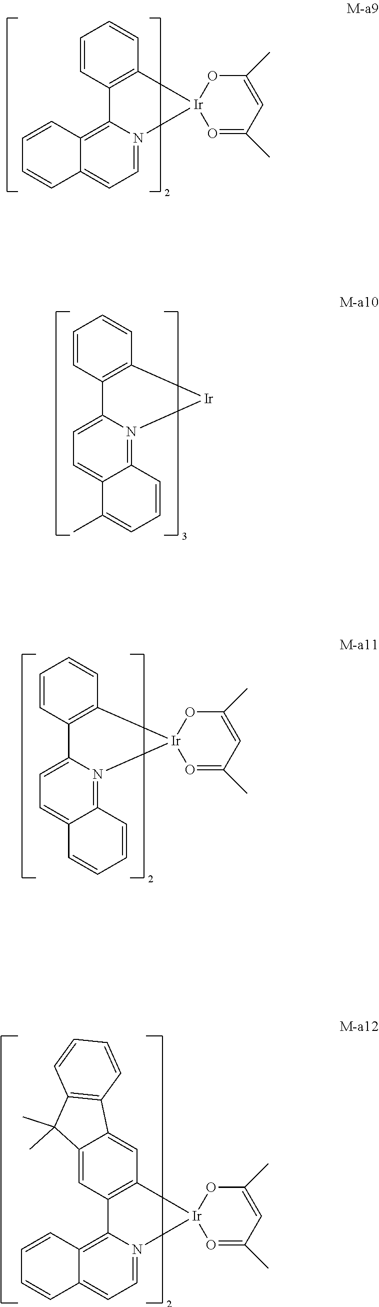

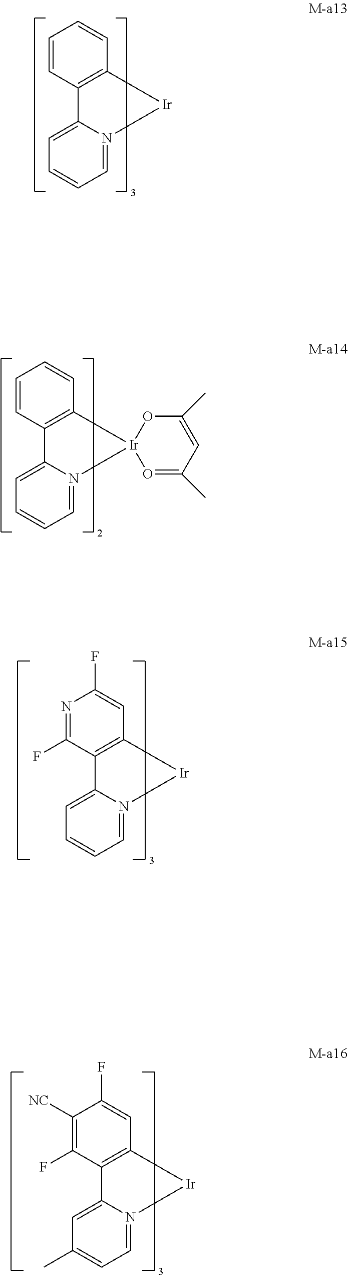

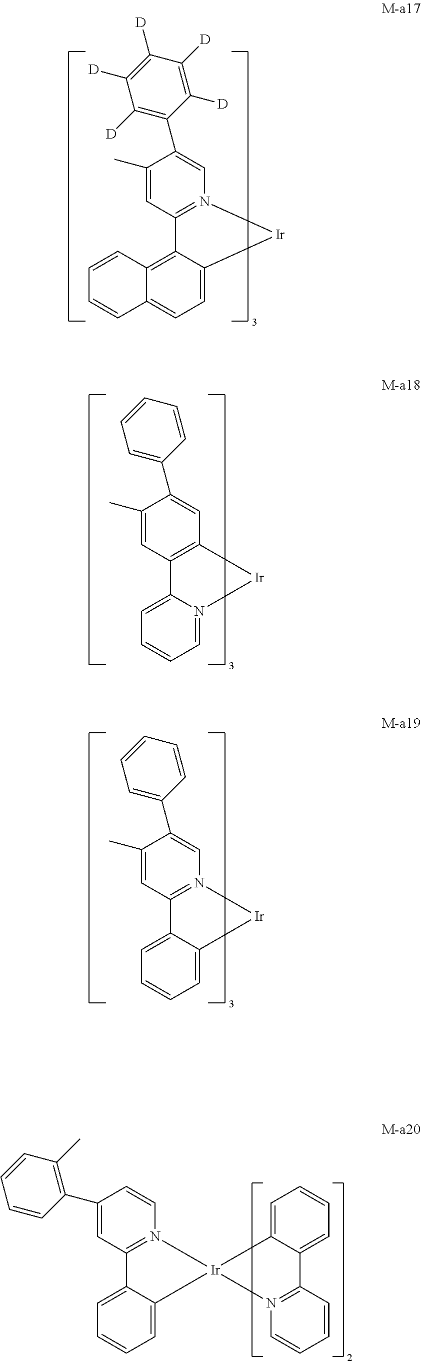

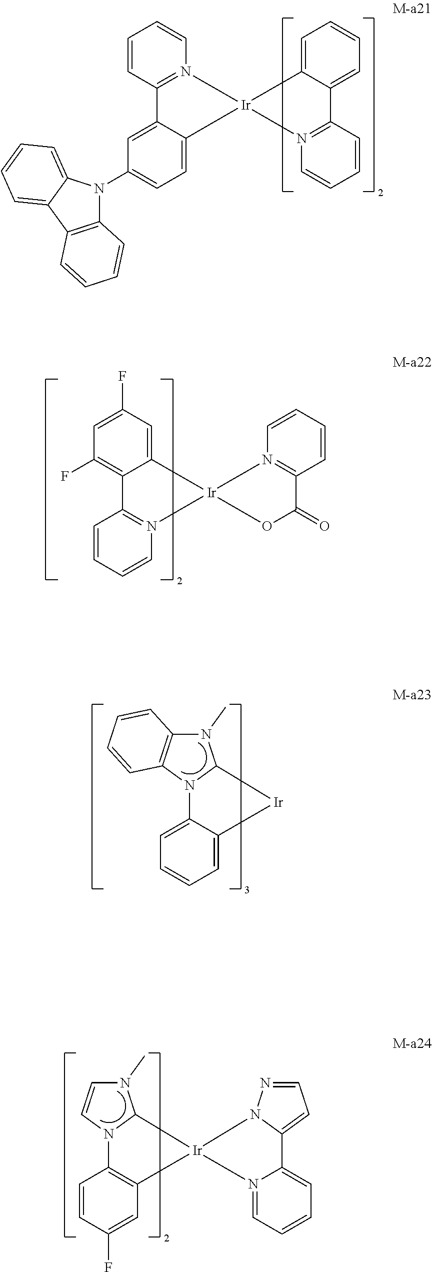

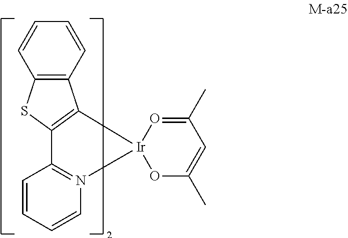

Compound M-a1 and Compound M-a2 may be used as a red dopant material. Compound M-a3 to Compound M-a7 may be used as a green dopant material.

The emission layer EML may include a compound represented by Formula F-a or Formula F-b. The compound represented by Formula F-a or Formula F-b may be used as a fluorescence dopant material.

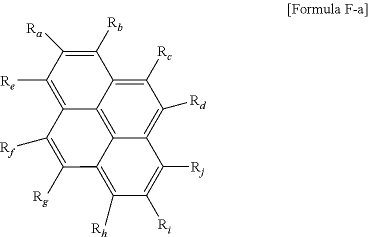

In Formula F-a, two of Rₐ to Rⱼ may each independently be substituted with a group represented by [symbol] NAr₁Ar₂. The remainder of Rₐ to Rⱼ which are not substituted with the group represented by [symbol] NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by [symbol] NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ or Ar₂ may be a heteroaryl group containing O or S as a ring-forming atom.

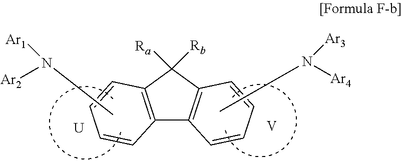

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In Formula F-b, the number of rings represented by U and V may each independently be 0 or 1.

For example, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

In an embodiment, the emission layer EML may include, as a dopant material of the related art, styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl(DPAVBi), perylene and the derivatives thereof (e.g., 2,5,8,11-tetra-t-butylperylene (TBP)), pyrene and the derivatives thereof (e.g., 1,1′-dipyrene, 1,4-dipyrenylbenzene, 1,4-bis(N,N-diphenylamino)pyrene), etc.

The emission layer EML may include a phosphorescent dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (FIr6), or platinum octaethyl porphyrin (PtOEP) may be used as a phosphorescence dopant. However, embodiments are not limited thereto.

In an embodiment, the emission layer EML may include a quantum dot. The quantum dot may be a Group II-VI compound, a Group I-II-VI compound, a Group II-IV-VI compound, a Group I-II-IV-VI compound, a Group III-VI compound, a Group I-III-VI compound, a Group III-V compound, a Group III-II-V compound, a Group II-IV-V compound, a Group IV-VI compound, a Group IV element, a Group IV compound, or any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof; or any combination thereof. In an embodiment, a Group II-VI compound may further include a Group I metal and/or a Group IV element. Examples of a Group I-II-VI compound may include CuSnS or CuZnS, and examples of a Group II-IV-VI compound may include ZnSnS, etc. Examples of a Group I-II-IV-VI compound may include: a quaternary compound selected from the group consisting of Cu₂ZnSnS₂, Cu₂ZnSnS₄, Cu₂ZnSnSe₄, Ag₂ZnSnS₂, and a mixture thereof; or any combination thereof.

Examples of a Group III-VI compound may include: a binary compound such as In₂S₃ or In₂Se₃; a ternary compound such as InGaS₃ or InGaSe₃; or any combination thereof.

Examples of a Group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂, and a mixture thereof; or a quaternary compound such as AgInGaS₂ or CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof; or any combination thereof. In an embodiment, a Group III-V compound may further include a Group II metal. For example, InZnP, etc., may be selected as a Group III-II-V compound.

Examples of a Group II-IV-V compound may include: a ternary compound selected from the group consisting of ZnSnP, ZnSnP₂, ZnSnAs₂, ZnGeP₂, ZnGeAs₂, CdSnP₂, CdGeP₂, or any mixture thereof.

Examples of a Group IV-VI compound may include: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof; or any combination thereof. Examples of a Group IV element may include Si, Ge, or any mixture thereof. Examples of a Group IV compound may include a binary compound selected from the group consisting of SiC, SiGe, and any mixture thereof.

A binary compound, a ternary compound, or a quaternary compound may be present in a particle at a uniform concentration distribution, or may be present in a particle at a partially different concentration distribution. In an embodiment, a quantum dot may have a core/shell structure in which a quantum dot surrounds another quantum dot. A quantum dot having a core/shell structure may have a concentration gradient in which the concentration of a material that is present in the shell decreases toward the core.

In embodiments, the quantum dot may have the above-described core/shell structure including a core containing nanocrystals and a shell surrounding the core. The shell of the quantum dot may serve as a protection layer to prevent chemical deformation of the core to maintain semiconductor properties, and/or may serve as a charging layer to impart electrophoresis properties to the quantum dot. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound such as MgAl₂O₄, CoFe₂O₄, NiFe₂O₄, or CoMn₂O₄; or any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within any of the ranges above, color purity or color reproducibility may be improved. Light emitted through a quantum dot may be emitted in all directions, so that a wide viewing angle may be improved.

The form of a quantum dot is not particularly limited as long as it is a form that is used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoparticles, etc.

A quantum dot may control the color of emitted light according to a particle size thereof. Thus, the quantum dot may have various light emission colors such as green, red, etc.

Referring to FIGS. 3 to 6, the first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiments are not limited thereto. The first electrode EL1 may include the above-described metal materials, combinations of at least two metal materials of the above-described metal materials, oxides of the above-described metal materials, or the like, but embodiments are not limited thereto. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), an emission-auxiliary layer (not shown), or an electron blocking layer EBL.

The hole transport region HTR may be a layer consisting of a single material, a layer including different materials, or a structure including multiple layers including different materials. For example, the hole transport region HTR may have a single layer structure of the hole injection layer HIL or the hole transport layer HTL, or may have a single layer structure formed of a hole injection material and a hole transport material.

The hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective order from the first electrode EL1. However, embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the hole transport region HTR may include a compound represented by Formula H-1:

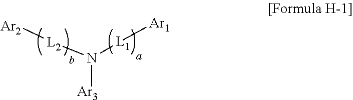

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ and L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In yet another embodiment, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds listed in Compound Group H are only examples, and the compounds represented by Formula H-1 are not limited to Compound Group H:

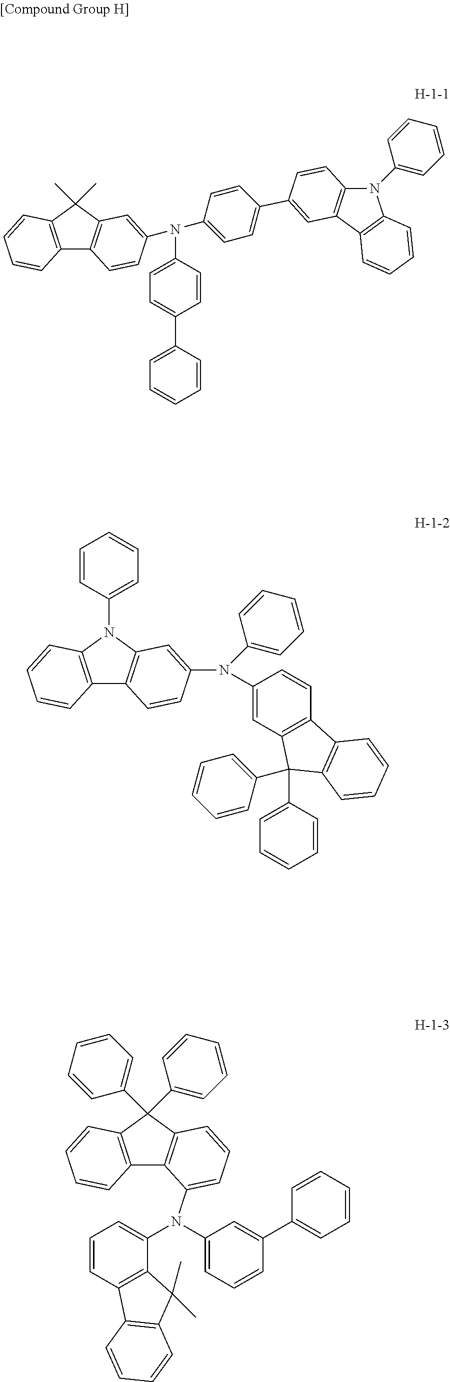 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

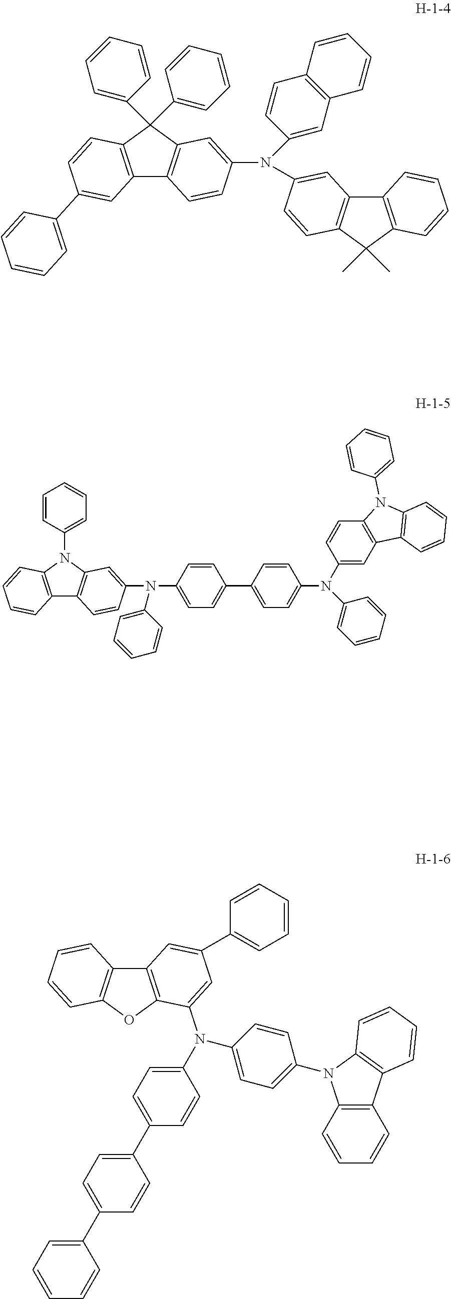 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

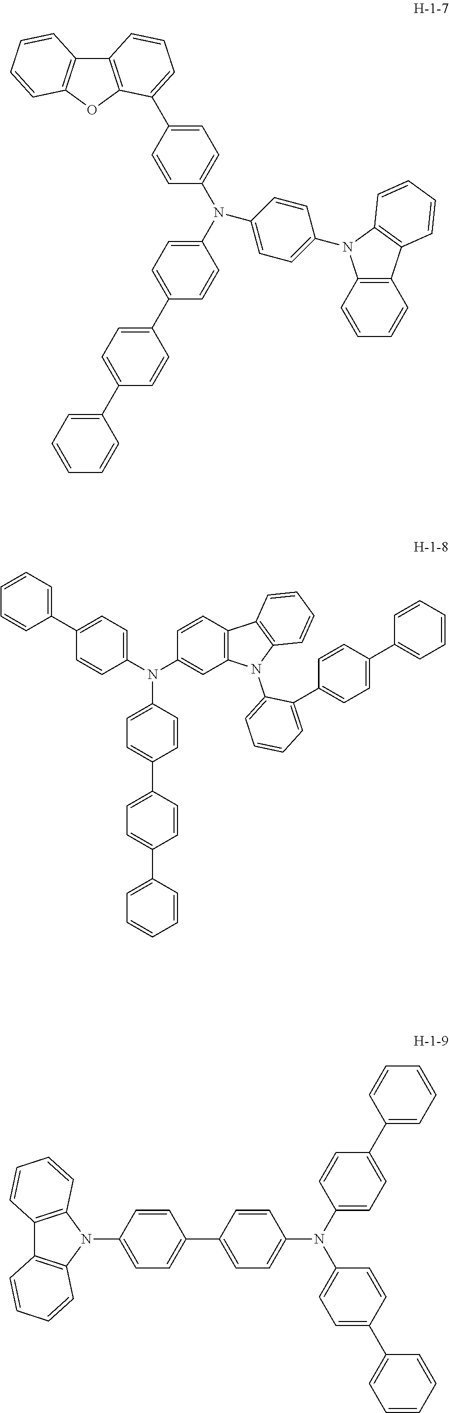 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

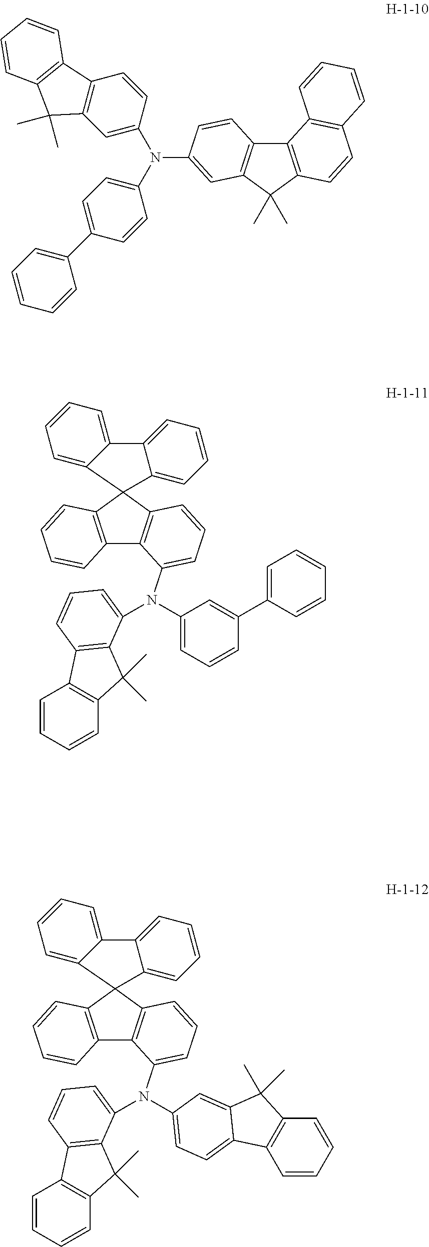 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

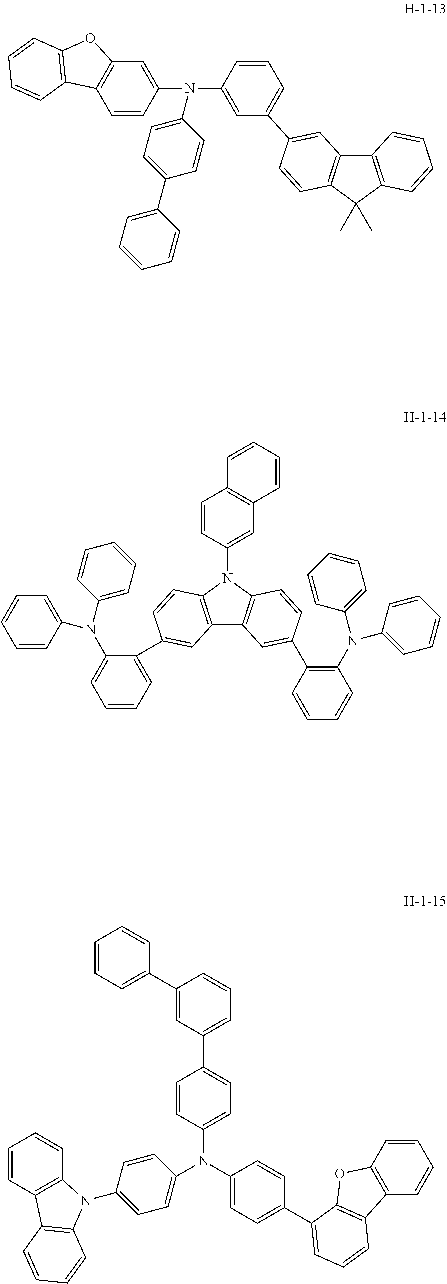 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

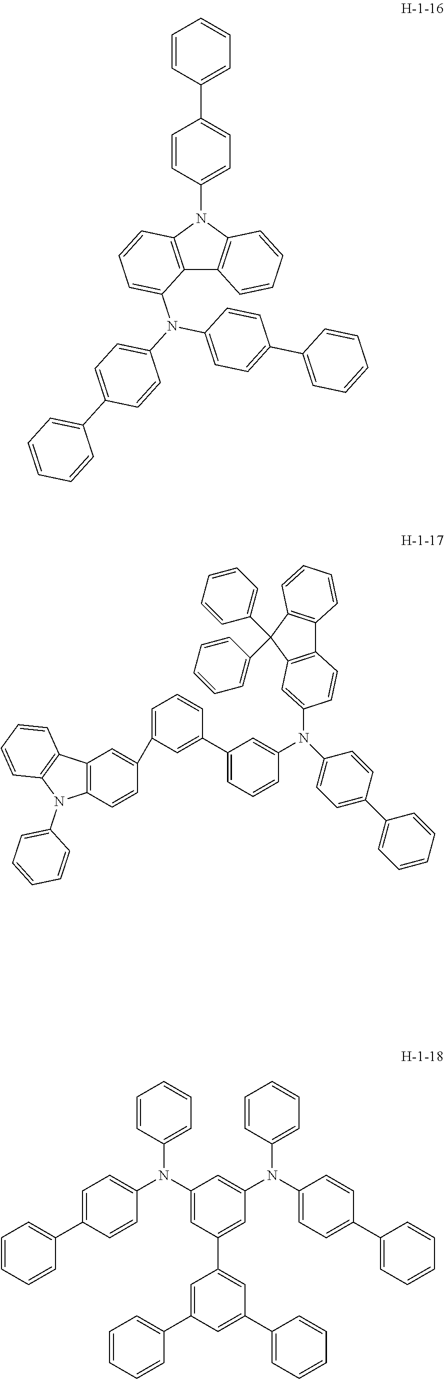 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

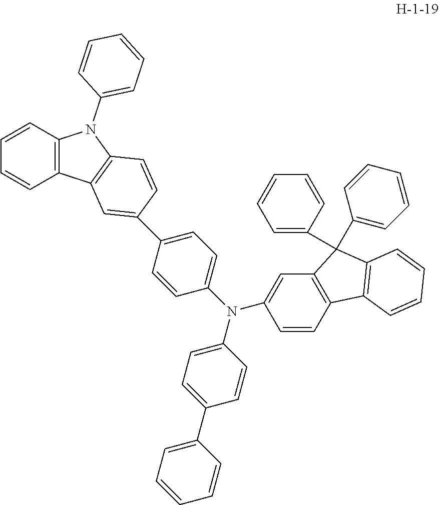 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′, 4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include carbazole derivatives such as N-phenyl carbazole and polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an electron blocking layer EBL, a buffer layer (not shown), or an emission auxiliary layer (not shown).

A thickness of the hole transport region HTR may be, for example, in a range of about 50 Å to about 15,000 Å. For example, the thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have, for example, a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown) or an electron blocking layer EBL, in addition to a hole injection layer HIL and a hole transport layer HTL. The buffer layer (not shown) may compensate for a resonance distance according to a wavelength of light emitted from the emission layer EML and may thus increase light emission efficiency. A material that may be included in the hole transport region HTR may be used as a material to be included in the buffer layer (not shown). The electron blocking layer EBL may prevent electron injection from the electron transport region ETR to the hole transport region HTR.

In the light emitting element ED according to an embodiment as illustrated in each of FIGS. 3 to 6, the electron transport region ETR may be provided on the emission layer EML. The electron transport region ETR may include at least one of a hole blocking layer HBL, an electron transport layer ETL, or an electron injection layer EIL, but embodiments are not limited thereto.

The electron transport region ETR may be a layer consisting of a single material, a layer including different materials, or a structure including multiple layers including different materials. For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto.

The electron transport region ETR may have a thickness, for example, in a range of about 1,000 Å to about 1,500 Å. The electron transport region ETR may be formed by using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the electron transport region ETR may include a compound represented by Formula ET-1 as described herein.

The electron transport region ETR may include an anthracene-based compound. However, the embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebg₂), 9,10-di(naphthalene-2-yl)anthracene (ADN), 1,3-Bis[3,5-di(pyridin-3-yl)phenyl]benzene (BmPyPhB), or any mixture thereof.

The electron transport regions ETR may include a metal halide such as LiF, NaCl, CsF, RbCl, RbI, CuI, or KI; a lanthanide metal such as Yb; or a co-deposited material of the metal halide and the lanthanide metal. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture material of an electron transport material and an insulating organometallic salt. The organometallic salt may be a material having an energy band gap greater than or equal to about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments are not limited thereto. The electron transport region ETR may include the above-described compounds of the hole transport region in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In another embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or an epoxy resin, or an acrylate such as methacrylate. However, the embodiments are not limited thereto, and the capping layer CPL may include at least one of Compounds P1 to P5:

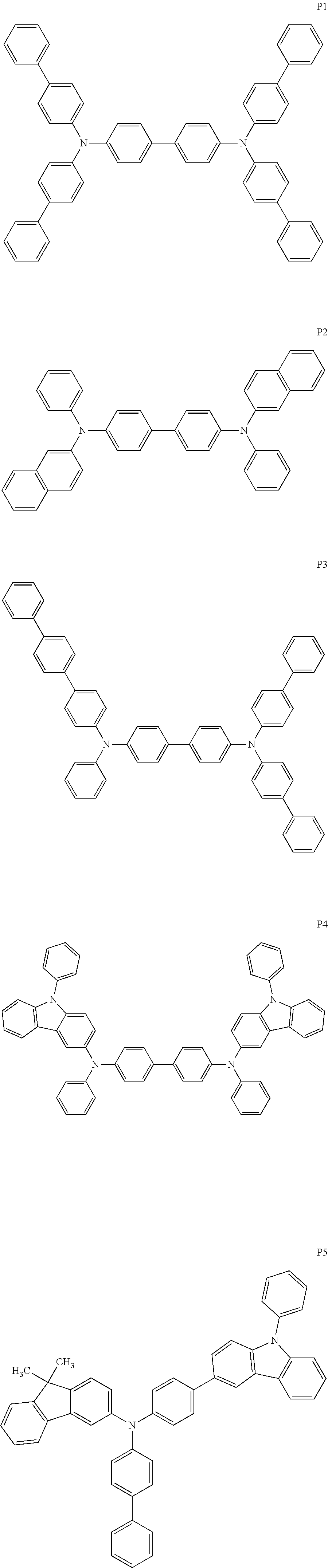 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be greater than or equal to about 1.6. For example, a refractive index of the capping layer CPL may be greater than or equal to about 1.6 with respect to light in a wavelength range of about 550 nm to about 660 nm.

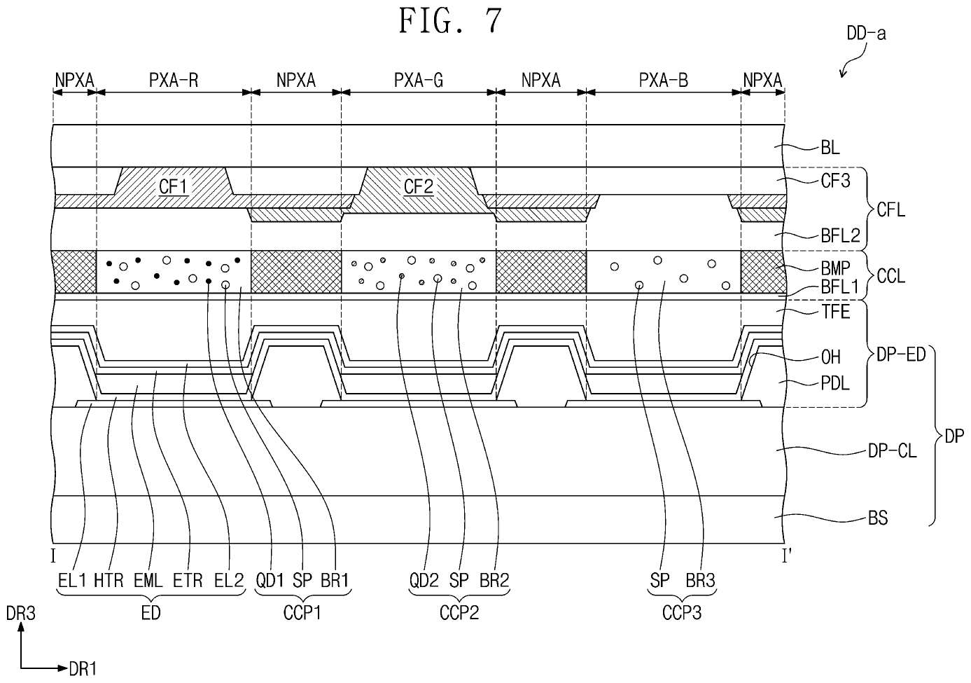

FIGS. 7 to 10 are each a schematic cross-sectional view of a display device according to an embodiment. Hereinafter, in describing the display devices of embodiments with reference to FIGS. 7 to 10, the features which have been described above in reference to FIGS. 1 to 6 will not be described again, and the differing features will be described.

Referring to FIG. 7, the display device DD-a according to an embodiment may include a display panel DP including a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The emission layer EML may include the fused polycyclic compound of an embodiment. The emission layer EML may further include at least one of the second to fourth compounds. In embodiments, a structure of the light emitting element ED shown in FIG. 7 may be the same as a structure of a light emitting element ED according to one of FIGS. 3 to 6 as described herein.

Referring to FIG. 7, the emission layer EML may be disposed in an opening OH defined in a pixel defining film PDL. For example, the emission layer EML, which is divided by the pixel defining film PDL and correspondingly provided to each of the light emitting regions PXA-R, PXA-G, and PXA-B, may each emit light in a same wavelength range. In the display device DD-a according to an embodiment, the emission layer EML may emit blue light. Although not shown in the drawings, in an embodiment, the emission layer EML may be provided as a common layer for each of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and may emit the resulting light. For example, the light control layer CCL may be a layer including a quantum dot or a layer including a phosphor.

The light control layer CCL may include light control parts CCP1, CCP2, and CCP3. The light control parts CCP1, CCP2, and CCP3 may be spaced apart from each other.

Referring to FIG. 7, divided patterns BMP may be disposed between the light control parts CCP1, CCP2, and CCP3 which are spaced apart from each other, but embodiments are not limited thereto. FIG. 7 illustrates that the divided patterns BMP do not overlap the light control parts CCP1, CCP2, and CCP3, but at least a portion of the edges of the light control parts CCP1, CCP2 and CCP3 may overlap the divided patterns BMP.

The light control layer CCL may include a first light control part CCP1 containing a first quantum dot QD1 that converts first color light provided from the light emitting element ED into second color light, a second light control part CCP2 containing a second quantum dot QD2 that converts the first color light into third color light, and a third light control part CCP3 that transmits the first color light.

In an embodiment, the first light control part CCP1 may provide red light that may be the second color light, and the second light control part CCP2 may provide green light that may be the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light control layer CCL may further include a scatterer SP. The first light control part CCP1 may include the first quantum dot QD1 and a scatterer SP, the second light control part CCP2 may include the second quantum dot QD2 and a scatterer SP, and the third light control part CCP3 may not include any quantum dot but may include a scatterer SP.

The scatterer SP may be inorganic particles. For example, the scatterer SP may include at least one of TiO₂, ZnO, Al₂O₃, SiO₂, or hollow silica. The scatterer SP may include one of TiO₂, ZnO, Al₂O₃, SiO₂, or hollow silica, or the scatterer SP may be a mixture of at least two materials selected from TiO₂, ZnO, Al₂O₃, SiO₂, and hollow silica.

The first light control part CCP1, the second light control part CCP2, and the third light control part CCP3 may each include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 may each be a medium in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. A barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may each independently further include an organic film. The barrier layers BFL1 and BFL2 may be formed of a single layer or formed of multiple layers.

In the display device DD-a, the color filter layer CFL may be disposed on the light control layer CCL. The color filter layer CFL may be disposed (e.g., directly disposed) on the light control layer CCL. For example, the barrier layer BFL2 may be omitted.

The color filter layer CFL may include color filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The first to third filters CF1, CF2, and CF3 may be disposed to respectively correspond to the red light emitting region PXA-R, the green light emitting region PXA-G, and the blue light emitting region PXA-B.

The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated but may be provided as one filter.

Although not shown in the drawings, the color filter layer CFL may further include a light shielding part (not shown). The light shielding part (not shown) may be a black matrix. The light shielding part (not shown) may include an organic light shielding material or an inorganic light shielding material containing a black pigment or dye. The light shielding part (not shown) may prevent light leakage, and may separate boundaries between the adjacent filters CF1, CF2, and CF3.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, the embodiments are not limited thereto, and the base substrate BL may include an inorganic layer, an organic layer, or a composite material layer. Although not shown in the drawings, in an embodiment, the base substrate BL may be omitted.

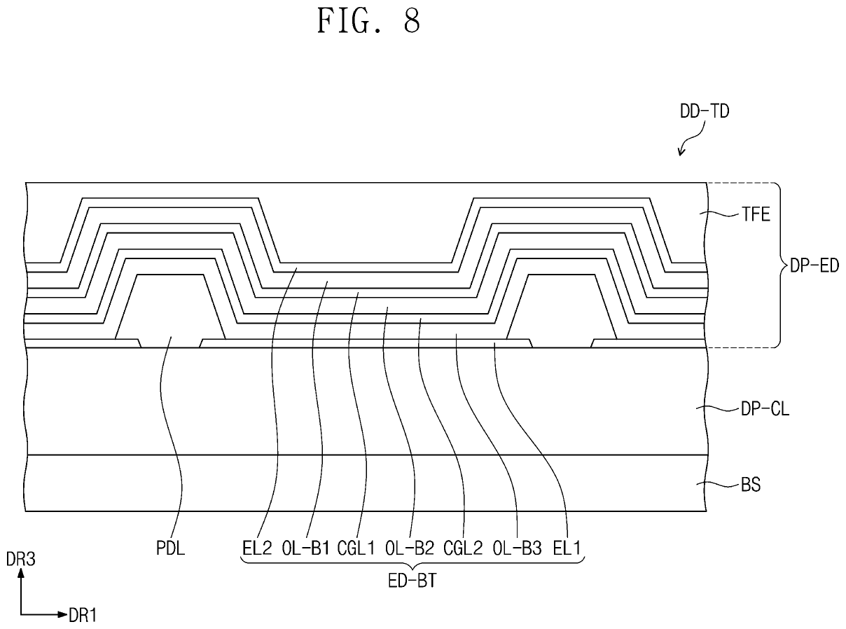

FIG. 8 is a schematic cross-sectional view of a portion of a display device according to an embodiment. FIG. 8 illustrates a schematic cross-sectional view of the part corresponding to the display panel DP of FIG. 7. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween. For example, the light emitting element ED-BT included in the display device DD-TD may be a light emitting element having a tandem structure and including multiple emission layers. At least one of the light emitting structures OL-B1, OL-B2, and OL-B3 may include the fused polycyclic compound according to an embodiment. At least one of the light emitting structures OL-B1, OL-B2, and OL-B3 may include at least one of the second to fourth compounds.

In an embodiment illustrated in FIG. 8, light emitted from the light emitting structures OL-B1, OL-B2, and OL-B3 may each be blue light. However, embodiments are not limited thereto, and the light respectively emitted from the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generation layers CGL1 and CGL2 may each be disposed between two of the neighboring light emitting structures among OL-B1, OL-B2, and OL-B3. Charge generation layers CGL1 and CGL2 may each independently include a p-type charge generation layer and/or an n-type charge generation layer.

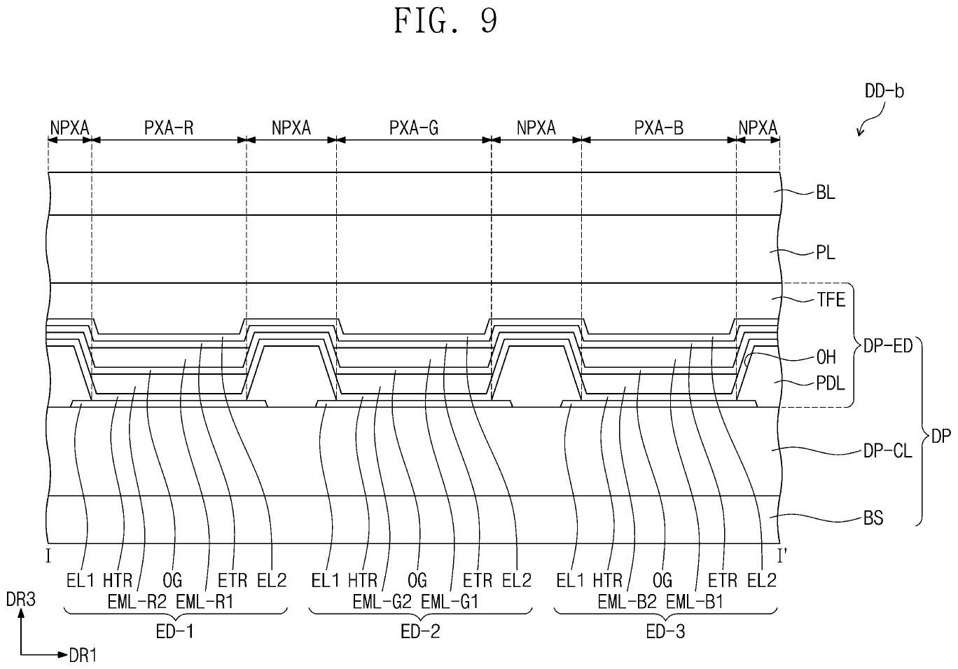

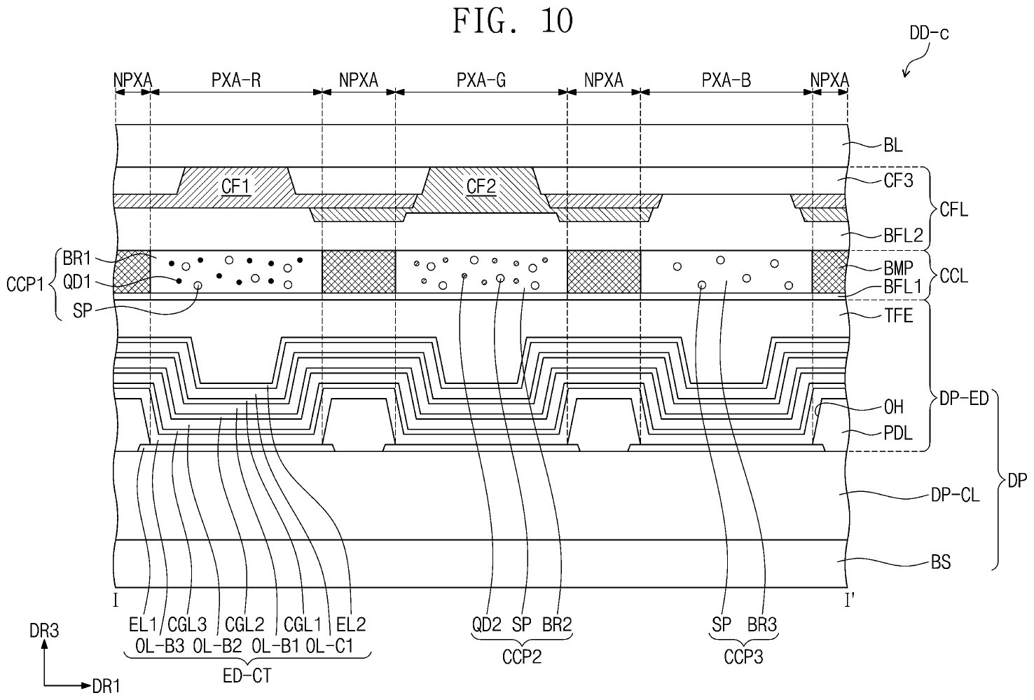

FIG. 9 is a schematic cross-sectional view of a display device DD-b according to an embodiment. The display device DD-b may include light emitting elements ED-1, ED-2, and ED-3 in which two emission layers are stacked. In comparison to the display device DD illustrated in FIG. 2, the embodiment illustrated in FIG. 9 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region. At least one of the first to third light emitting elements ED-1, ED-2, and ED-3 may include the fused polycyclic compound according to an embodiment. At least one of the first to third light emitting elements ED-1, ED-2, and ED-3 may include at least one of the second to fourth compounds. For example, the third light emitting element ED-3 may include the fused polycyclic compound. However, this is an example, and the light emitting element including the fused polycyclic compound according to an embodiment is not limited thereto.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generation layer. For example, the emission auxiliary part OG may include an electron transport region, a charge generation layer, and a hole transport region that are stacked. The emission auxiliary part OG may be provided as a common layer for all of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are stacked.

An optical auxiliary layer PL may be disposed on a display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device.

In contrast to FIGS. 8 and 9, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2. At least one of the first to fourth light emitting structures OL-B1, OL-B2, OL-B3, and OL-C1 may include the fused polycyclic compound according to an embodiment. At least one of the first to fourth light emitting structures OL-B1, OL-B1, OL-B2, and OL-C1 may include at least one of the second to fourth compounds.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in different wavelength regions from each other.

Charge generation layers CGL1, CGL2, and CGL3 may be disposed between adjacent light emitting structures among the first to fourth light emitting structures OL-B1, OL-B2, OL-B3, and OL-C1. The charge generation layers CGL1, CGL2, and CGL3 which are disposed between adjacent light emitting structures OL-B1, OL-B2, OL-B3, and OL-C1 may each independently include a p-type charge generation layer and/or an n-type charge generation layer.

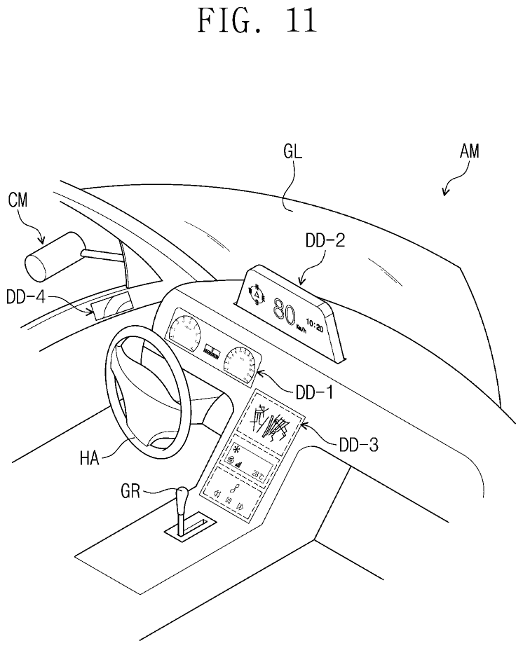

FIG. 11 is a schematic perspective view of a vehicle AM in which first to fourth display devices DD-1, DD-2, DD-3, and DD-4 are disposed. At least one of the first to fourth display devices DD-1, DD-2, DD-3, and DD-4 may have a structure according to one of the display devices DD, DD-TD, DD-a, DD-b, and DD-c as described with reference to FIGS. 1, 2, and 7 to 10.

FIG. 11 illustrates a vehicle AM, but this is only an example, and the first to fourth display devices DD-1, DD-2, DD-3, and DD-4 may be disposed in another transportation means such as bicycles, motorcycles, trains, ships, and airplanes. At least one of the first to fourth display devices DD-1, DD-2, DD-3, and DD-4 may have a structure according to one of the display devices DD, DD-TD, DD-a, DD-b, and DD-c and, according to an embodiment, may be used in a personal computer, a laptop computer, a personal digital terminal, a game console, a portable electronic device, a television, a monitor, an outdoor billboard, or the like. These are merely provided as examples, and thus may be employed in other electronic apparatuses.

At least one of the first to fourth display devices DD-1, DD-2, DD-3, and DD-4 may include the light emitting element ED according to an embodiment as described with reference to FIGS. 3 to 6. The emission layer EML in the light emitting element ED of an embodiment may include the fused polycyclic compound of an embodiment. The emission layer EML may include at least one of the second to fourth compounds. At least one of the first to fourth display devices DD-1, DD-2, DD-3, and DD-4 may include the light emitting element ED which includes the fused polycyclic compound according to an embodiment, thereby improving display efficiency and a display service life.

Referring to FIG. 11, the vehicle AM may include a steering wheel HA and a gearshift GR for driving the vehicle AM, and a front window GL may be disposed so as to face the driver.

The first display device DD-1 may be disposed in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. The first scale and the second scale may each be indicated as a digital image.

A second display device DD-2 may be disposed in a second region facing the driver's seat and overlapping the front window GL. The driver's seat may be a seat in which the steering wheel HA is disposed. For example, the second display device DD-2 may be a head up display (HUD) which displays second information of the vehicle AM. The second display device DD-2 may be optically transparent. The second information may include digital numbers which indicate a driving speed, and may further include information such as the current time. Although not shown in the drawings, according to an embodiment, the second information of the second display device DD-2 may be projected to the front window GL to be displayed.

The third display device DD-3 may be disposed in a third region adjacent to the gearshift GR. For example, the third display device DD-3 may be disposed between the driver's seat and the passenger seat and may be a center information display (CID) for a vehicle for displaying third information. The passenger seat may be a seat that is spaced apart from the driver's seat with the gearshift GR disposed therebetween. The third information may include information about traffic (e.g., navigation information), playing music or radio or a video (or an image), temperatures inside the vehicle AM, etc.

The fourth display device DD-4 may be spaced apart from the steering wheel HA and the gearshift GR, and may be disposed in a fourth region adjacent to the side of the vehicle AM. For example, the fourth display device DD-4 may be a digital side-view mirror which displays fourth information. The fourth display device DD-4 may display an image outside the vehicle AM taken by a camera module CM disposed outside the vehicle AM. The fourth information may include an image outside the vehicle AM.

The first to fourth information as described herein are only examples, and the first to fourth display devices DD-1, DD-2, DD-3, and DD-4 may further display information about the interior and the exterior of the vehicle AM. The first to fourth information may include information that is different from each other. However, embodiments are not limited thereto, and a part of the first to fourth information may include the same information as one another.

Hereinafter, a fused polycyclic according to an embodiment and a light emitting device according to an embodiment will be described in detail with reference to the Examples and the Comparative Examples. The Examples described below are only provided as illustrations to assist the understanding of the disclosure, and the scope thereof is not limited thereto.

### EXAMPLES

1. Synthesis of Fused Polycyclic Compounds of Examples

A synthesis method of the fused polycyclic compound according to an embodiment will be described by illustrating synthesis methods of Compounds 1, 2, 9, 27, 38, 41, 46, and 47. In the following descriptions, the synthesis method of the fused polycyclic compound is provided only as an example, but the synthesis method of the compound according to embodiments are not limited to Examples below.

(1) Synthesis of Compound 1

Compound 1 according to an example may be synthesized by, for example, the steps shown in Reaction Scheme 1 below:

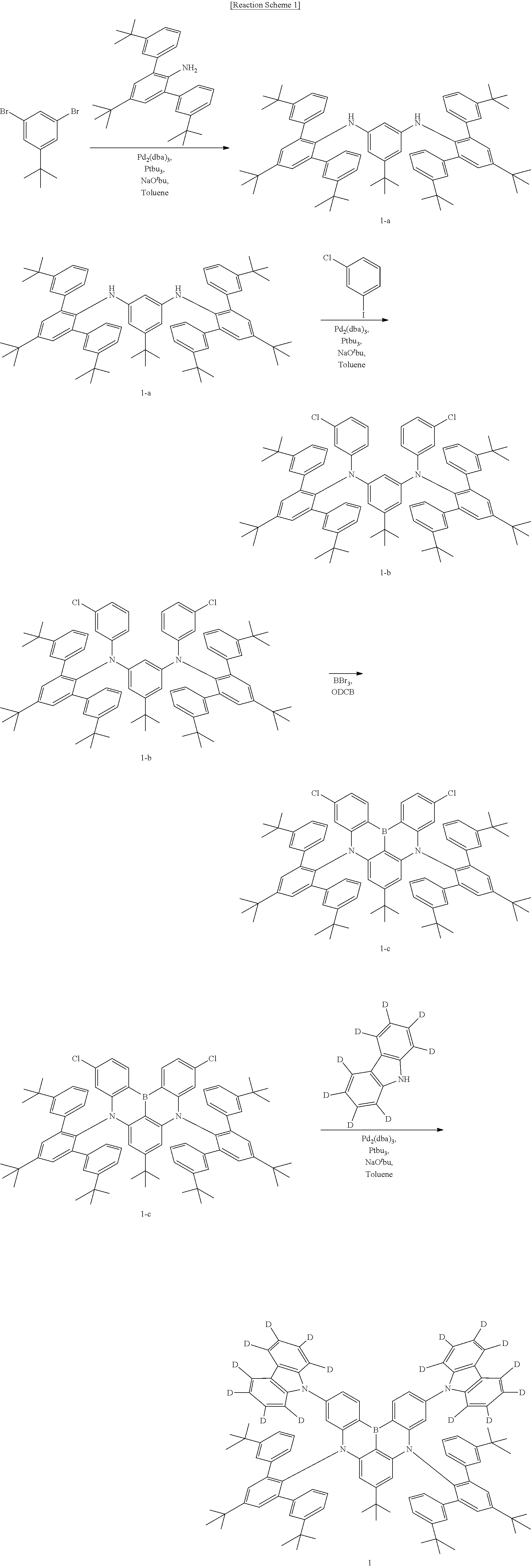

<Synthesis of Intermediate Compound 1-b>

In an argon atmosphere, to a 2 L-flask, 1,3-dibromo-5-tert-butylbenzene (20 g, 68 mmol), 3,3″,5′-tri-tert-butyl-[1,1′:3′,1″-terphenyl]-2′-amine (56 g, 136 mmol), Pd₂(dba)₃ (3.1 g, 3.4 mmol), tris-tert-butyl phosphine (Ptbu₃, 3.1 mL, 6.8 mmol), and sodium tert-butoxide (NaO^{t}bu, 20.7 g, 150 mmol) were added and dissolved in 700 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 1-a (colorless liquid, 45 g, yield: 70%).

ESI-LCMS: [M]⁺: C₇₀H₈₈N₂. 956.6912.

<Synthesis of Intermediate Compound 1-b>

In an argon atmosphere, to a 2 L-flask, Intermediate Compound 1-a (45 g, 47 mmol), 1-Iodo-3-chlorobenzene (23 g, 94 mmol), Pd₂(dba)₃ (2.1 g, 2.3 mmol), tris-tert-butyl phosphine (2.1 mL, 4.2 mmol), and sodium tert-butoxide (11.5 g, 120 mmol) were added and dissolved in 500 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 1-b (white solid, 30 g, yield: 56%).

ESI-LCMS: [M]⁺: C₈₂H₉₄Cl₂N₂. 1176.6687.

<Synthesis of Intermediate Compound 1-c>

In an argon atmosphere, to a 1-L flask, Intermediate Compound 1-b (30 g, 25 mmol) was added and dissolved in 250 mL of o-dichlorobenzene (ODCB), and Br₃ (1.5 equiv.) was added thereto. The reaction solution was stirred at about 140° C. for about 12 hours. After the reaction solution was cooled, the reaction was terminated by adding triethylamine, and the solvent was removed under reduced pressure. The solid thus obtained was purified and separated by silica gel column chromatography using CH₂Cl₂ and hexane as eluent to obtain Intermediate Compound 1-c (yellow solid, 10 g, yield: 34%).

ESI-LCMS: [M]⁺: C₈₂H₉₁BCl₂N₂. 1184.1781.

<Synthesis of Compound 1>

In an argon atmosphere, to a 1 L-flask, Intermediate Compound 1-c (10 g, 8.4 mmol), 9H-carbazole-1,2,3,4,5,6,7,8-d8 (3 g, 16 mmol), Pd₂(dba)₃ (0.4 g, 0.4 mmol), tris-tert-butyl phosphine (0.4 mL, 0.8 mmol), and sodium tert-butoxide (11.5 g, 120 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 1 (yellow solid, 10 g, yield: 82%).

ESI-LCMS: [M]⁺: C₁₀₆H₉₁D₁₆BN₄. 1462.1199

1H-NMR (CDCl₃): d=8.83 (d, 2H), 7.56 (s, 4H), 7.53 (s, 4H), 7.33 (m, 10H), 7.25 (d, 4H), 7.11 (s, 2H), 7.06 (s, 2H), 1.56 (s, 36H), 1.32 (s, 18H), 1.12 (s, 9H)

(2) Synthesis of Compound 2

Compound 2 according to an example may be synthesized by, for example, the steps shown in Reaction Scheme 2 below:

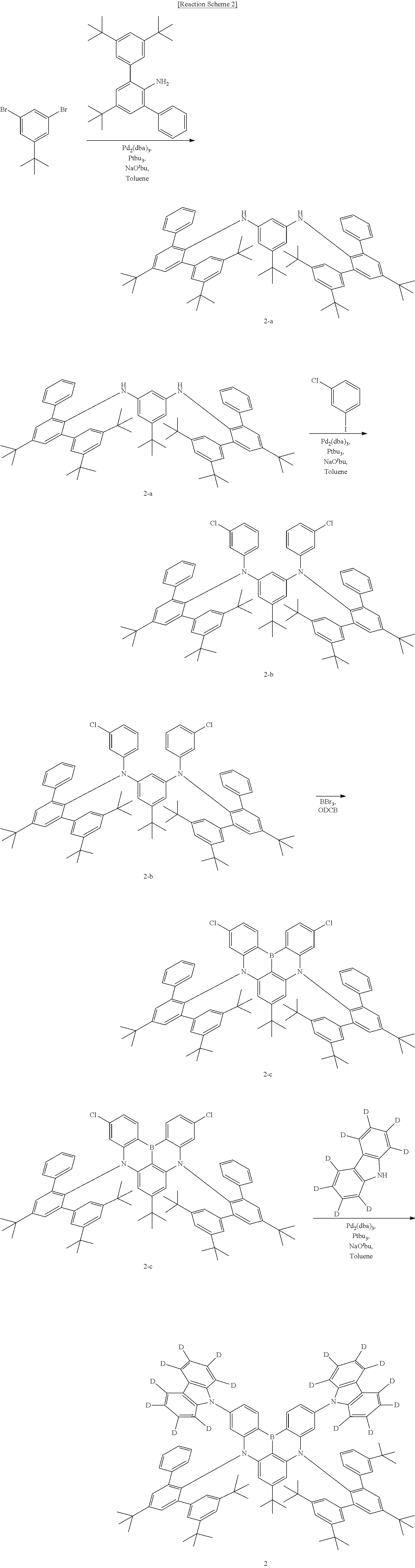

<Synthesis of Intermediate Compound 2-a>

In an argon atmosphere, to a 2-L flask, 1,3-dibromo-5-tert-butylbenzene (20 g, 68 mmol), 3,5,5′-tri-tert-butyl-[1,1′:3′,1″-terphenyl]-2′-amine (56 g, 136 mmol), Pd₂(dba)₃ (3.1 g, 3.4 mmol), tris-tert-butyl phosphine (3.1 mL, 6.8 mmol), and sodium tert-butoxide (20.7 g, 150 mmol) were added and dissolved in 700 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 2-a (colorless liquid, 45 g, yield: 70%).

ESI-LCMS: [M]⁺: C₇₀H₈₈N₂. 956.1197.

<Synthesis of Intermediate Compound 2-b>

In an argon atmosphere, to a 2 L-flask, Intermediate Compound 2-a (45 g, 47 mmol), I-Iodo-3-chlorobenzene (23 g, 94 mmol), Pd₂(dba)₃ (2.1 g, 2.3 mmol), tris-tert-butyl phosphine (2.1 mL, 4.2 mmol), and sodium tert-butoxide (11.5 g, 120 mmol) were added and dissolved in 500 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 2-b (white solid, 28 g, yield: 51%).

ESI-LCMS: [M]⁺: C₈₂H₉₄Cl₂N₂. 1176.4331.

<Synthesis of Intermediate Compound 2-c>

In an argon atmosphere, to a 1-L flask, Intermediate Compound 1-b (25 g, 21 mmol) was added and dissolved in 250 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 2-c (yellow solid, 8 g, yield: 32%).

ESI-LCMS: [M]⁺: C₈₂H₉₁BCl₂N₂. 1184.1056.

<Synthesis of Compound 2>

In an argon atmosphere, to a 1 L-flask, Intermediate Compound 2-c (10 g, 8.4 mmol), 9H-carbazole-1,2,3,4,5,6,7,8-d8 (3 g, 16 mmol), Pd₂(dba)₃ (0.4 g, 0.4 mmol), tris-tert-butyl phosphine (0.4 mL, 0.8 mmol), and sodium tert-butoxide (11.5 g, 120 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 2 (yellow solid, 10 g, yield: 82%).

ESI-LCMS: [M]⁺: C₁₀₆H₉₁D₁₆BN₄. 1462.3167

1H-NMR: 8.86 (d, 2H), 7.32 (s, 2H), 7.19 (s, 4H), 7.08 (d, 4H), 6.88 (t, 4H), 6.81 (d, 4H), 6.34 (s, 2H), 1.52 (s, 36H), 1.38 (s, 18H), 1.16 (s, 9H)

(3) Synthesis of Compound 9

Compound 9 according to an example may be synthesized by, for example, the steps shown in Reaction Scheme 3 below:

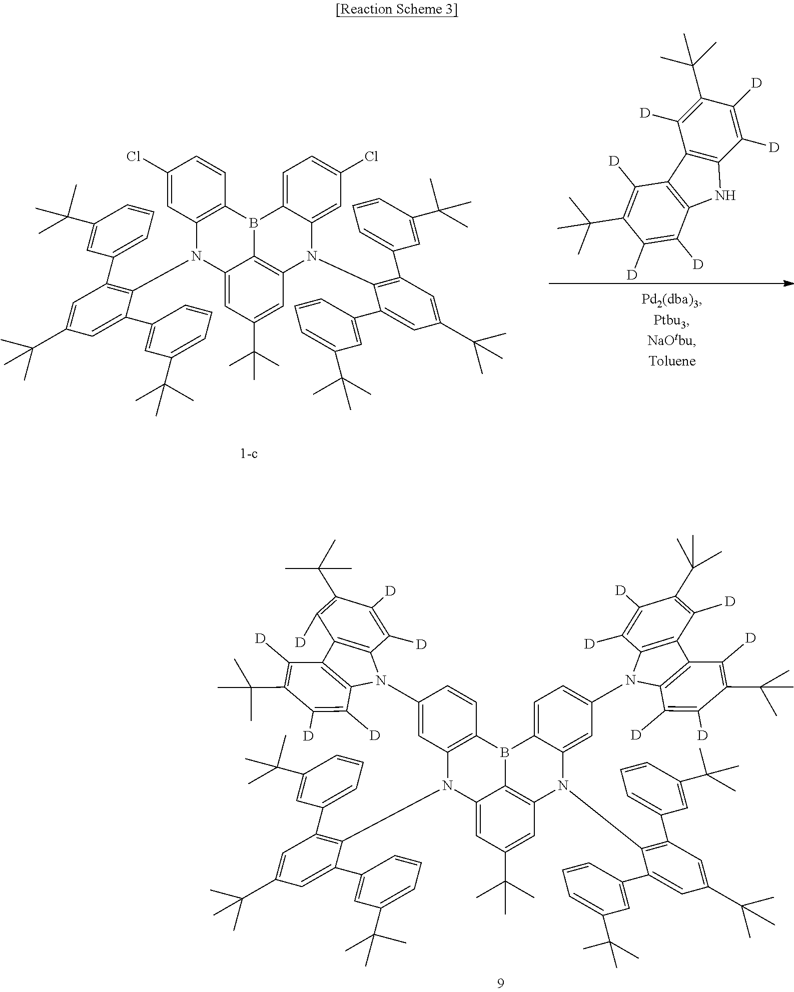

<Synthesis of Compound 9>

In an argon atmosphere, to a 1 L-flask, Intermediate Compound 1-c (10 g, 8.4 mmol), 3,6-di-tert-butyl-9H-carbazole-1,2,4,5,7,8-d6 (4.3 g, 16 mmol), Pd₂(dba)₃ (0.4 g, 0.4 mmol), tris-tert-butyl phosphine (0.4 mL, 0.8 mmol), and sodium tert-butoxide (11.5 g, 120 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 9 (yellow solid, 10 g, yield: 74%).

ESI-LCMS: [M+H]⁺: C₁₂₂H₁₂₇D₁₂BN₄. 1684.5543

1H-NMR: 8.69 (d, 2H), 7.48 (s, 4H), 7.41 (s, 4H), 7.11 (d, 4H), 6.93 (t, 4H), 6.76 (d, 4H), 6.54 (s, 2H), 1.59 (s, 36H), 1.38 (s, 18H), 1.34 (s, 36H), 1.16 (s, 9H)

(4) Synthesis of Compound 27

Compound 27 according to an example may be synthesized by, for example, the steps shown in Reaction Scheme 4 below:

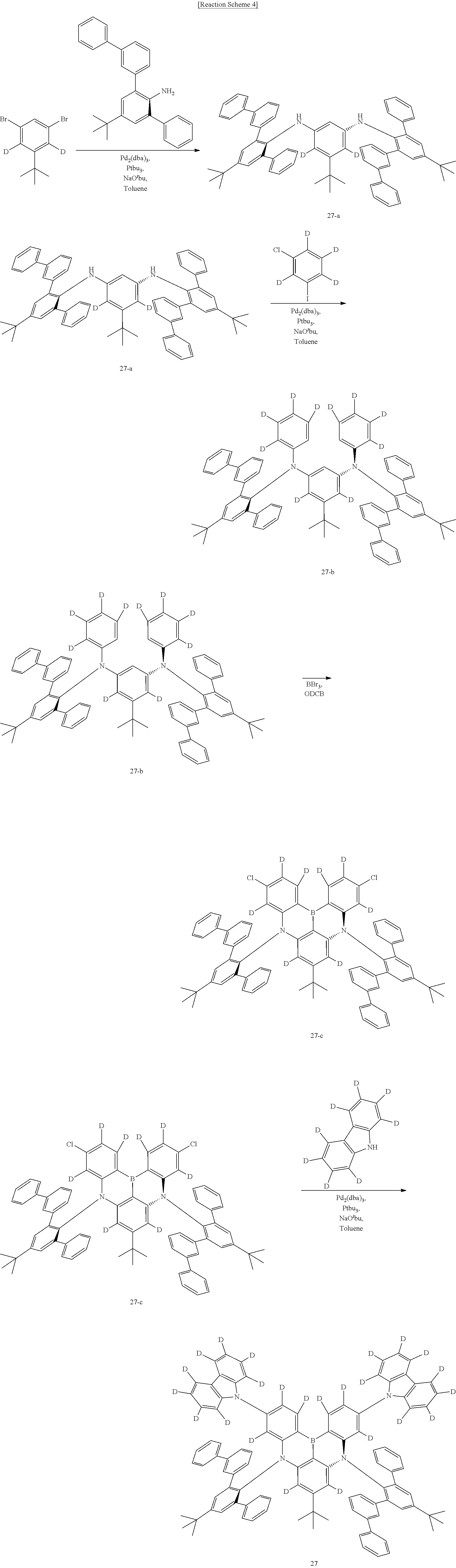

<Synthesis of Intermediate Compound 27-a>

In an argon atmosphere, to a 2-L flask, 1,3-dibromo-5-(tert-butyl)benzene-4,6-d2 (20 g, 68 mmol), 5′-(tert-butyl)-[1,1′:3′,1″:3″,1′″-quaterphenyl]-2′-amine (51 g, 136 mmol), Pd₂(dba)₃ (3.1 g, 3.4 mmol), tris-tert-butyl phosphine (3.1 mL, 6.8 mmol), and sodium tert-butoxide (20.7 g, 150 mmol) were added and dissolved in 700 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 27-a (colorless liquid, 43 g, yield: 72%).

ESI-LCMS: [M]⁺: C₆₆H₆₂D₂N₂. 886.4542.

<Synthesis of Intermediate Compound 27-b>

In an argon atmosphere, to a 2 L-flask, Intermediate Compound 27-a (43 g, 48 mmol), 1-chloro-3-iodobenzene-2,4,5,6-d4 (23 g, 94 mmol), Pd₂(dba)₃ (2.1 g, 2.3 mmol), tris-tert-butyl phosphine (2.1 mL, 4.2 mmol), and sodium tert-butoxide (11.5 g, 120 mmol) were added and dissolved in 500 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 27-b (white solid, 28 g, yield: 53%).

ESI-LCMS: [M]⁺: C₇₈H₆₂D₈Cl₂N₂. 1112.1993.

<Synthesis of Intermediate Compound 27-c>

In an argon atmosphere, to a 1-L flask, Intermediate Compound 27-b (25 g, 22 mmol) was added and dissolved in 250 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 27-c (yellow solid, 5.4 g, yield: 22%).

ESI-LCMS: [M]⁺: C₇₈H₅₉D₈BCl₂N₂. 1120.0294.

<Synthesis of Compound 27>

In an argon atmosphere, to a 1 L-flask, Intermediate Compound 27-c (10 g, 8.9 mmol), 9H-carbazole-1,2,3,4,5,6,7,8-d8 (3 g, 16 mmol), Pd₂(dba)₃ (0.4 g, 0.4 mmol), tris-tert-butyl phosphine (0.4 mL, 0.8 mmol), and sodium tert-butoxide (11.5 g, 120 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 27 (yellow solid, 9.5 g, yield: 76%).

ESI-LCMS: [M]⁺: C₁₀₂H₅₉D₂₄BN₄. 1398.8711

1H-NMR: 8.88 (d, 2H), 7.43 (s, 4H), 7.33 (s, 2H), 7.24 (m, 6H), 7.12 (m, 4H), 6.89 (m, 12H), 6.81 (m, 4H), 1.43 (s, 18H), 1.32 (s, 9H)

(5) Synthesis of Compound 38

Compound 38 according to an example may be synthesized by, for example, the steps shown in Reaction Scheme 5 below:

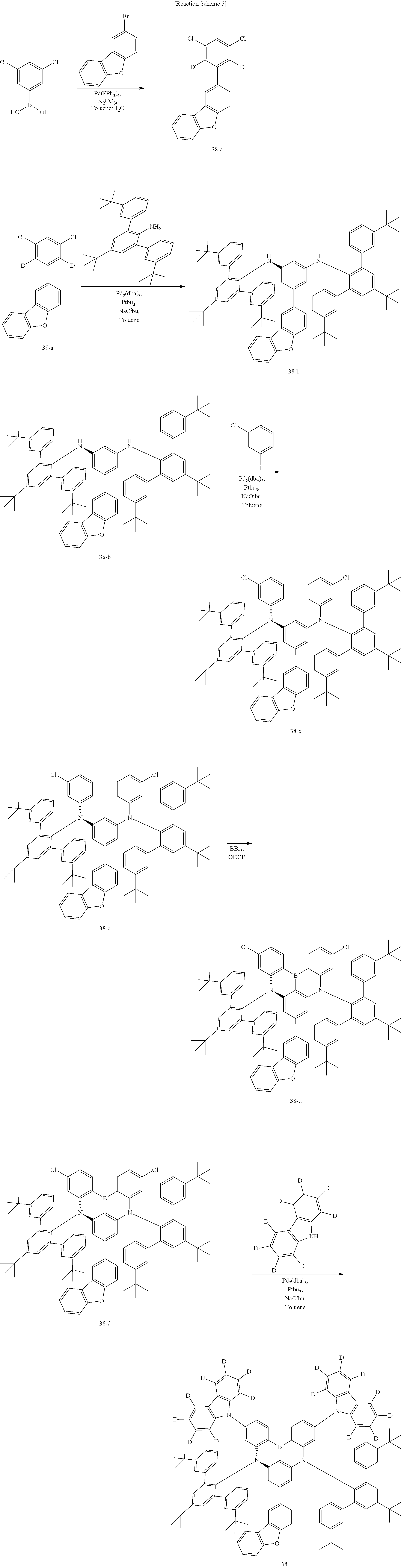

<Synthesis of Intermediate Compound 38-a>

In an argon atmosphere, to a 2 L-flask, (3,5-dichlorophenyl)boronic acid (20 g, 104 mmol), 2-bromodibenzo[b,d]furan (26 g, 104 mmol), Pd(PPh₃)₄ (6 g, 5.2 mmol), and potassium carbonate (K₂CO₃, 41 g, 300 mmol) were added and dissolved in 700 mL of toluene and 200 mL of H₂O, and the reaction solution was stirred under reflux at about 110° C. for about 8 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 38-a (white solid, 25 g, yield: 78%).

ESI-LCMS: [M]⁺: C₁₈H₈D₂Cl₂O. 314.0219.

<Synthesis of Intermediate Compound 38-b>

In an argon atmosphere, to a 2-L flask, Intermediate Compound 38-a (25 g, 80 mmol), 3,3″,5′-tri-tert-butyl-[1,1′:3′,1″-terphenyl]-2′-amine (65.7 g, 160 mmol), Pd₂(dba)₃ (3.7 g, 4 mmol), tris-tert-butyl phosphine (3.7 mL, 8 mmol), and sodium tert-butoxide (20.7 g, 150 mmol) were added and dissolved in 700 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 38-b (white solid, 55 g, yield: 65%).

ESI-LCMS: [M]⁺: C₇₈H₈₆N₂O. 1066.5439.

<Synthesis of Intermediate Compound 38-c>

In an argon atmosphere, to a2 L-flask, Intermediate Compound 38-b (55 g, 51 mmol), 1-chloro-3-iodobenzene (27 g, 110 mmol), Pd₂(dba)₃ (2.1 g, 2.3 mmol), tris-tert-butyl phosphine (2.1 mL, 4.2 mmol), and sodium tert-butoxide (11.5 g, 120 mmol) were added and dissolved in 500 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 38-c (white solid, 33 g, yield: 51%).

ESI-LCMS: [M]⁺: C₉₀H₉₂Cl₂N₂O. 1286.8667.

<Synthesis of Intermediate Compound 38-d>

In an argon atmosphere, to a 1-L flask, Intermediate Compound 38-c (30 g, 23 mmol) was added and dissolved in 250 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 38-d (yellow solid, 12.5 g, yield: 42%).

ESI-LCMS: [M]⁺: C₉₀H₈₉BCl₂N₂O. 1294.2224.

<Synthesis of Compound 38>

In an argon atmosphere, to a 1 L-flask, Intermediate Compound 38-d (10 g, 8.9 mmol), 9H-carbazole-1,2,3,4,5,6,7,8-d8 (3.8 g, 20 mmol), Pd₂(dba)₃ (0.4 g, 0.4 mmol), tris-tert-butyl phosphine (0.4 mL, 0.8 mmol), and sodium tert-butoxide (11.5 g, 120 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 38 (yellow solid, 9.5 g, yield: 76%).

ESI-LCMS: [M]⁺: C₁₁₄H₈₉D₁₆BN₄O. 1572.9331

1H-NMR: 8.73 (d, 2H), 7.53 (s, 4H), 7.48 (d, 1H), 7.35 (m, 3H), 7.12 (m, 10H), 7.02 (m, 5H), 6.88 (s, 2H), 6.75 (s, 2H), 1.53 (s, 36H), 1.42 (s, 18H)

(6) Synthesis of Compound 41

Compound 41 according to an example may be synthesized by, for example, the steps shown in Reaction Scheme 6 below:

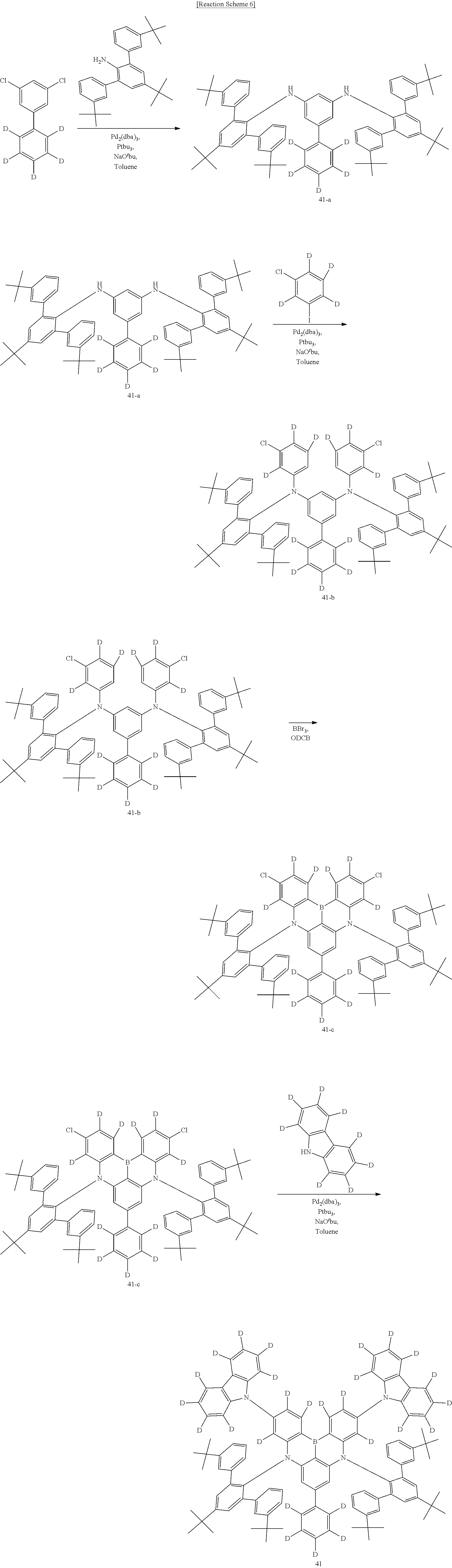

<Synthesis of Intermediate Compound 41-a>

In an argon atmosphere, to a 2-L flask, 3,5-dichloro-1,1′-biphenyl-2′,3′,4′,5′,6′-d5 (15 g, 66 mmol), 3,3″,5′-tri-tert-butyl-[1,1′:3′,1″-terphenyl]-2′-amine (54 g, 132 mmol), Pd₂(dba)₃ (3.0 g, 3.3 mmol), tris-tert-butyl phosphine (P(t-Bu)₃, 3.1 mL, 6.6 mmol), and sodium tert-butoxide (20.7 g, 150 mmol) were added and dissolved in 700 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 41-a (white solid, 50 g, yield: 77%).

ESI-LCMS: [M]⁺: C₇₂H₇₉D₅N₂. 981.6117.

<Synthesis of Intermediate Compound 41-b>

In an argon atmosphere, to a 2 L-flask, Intermediate Compound 41-a (50 g, 51 mmol), 1-chloro-3-iodobenzene-2,4,5,6-d4 (27 g, 110 mmol), Pd₂(dba)₃ (2.1 g, 2.3 mmol), tris-tert-butyl phosphine (2.1 mL, 4.2 mmol), and sodium tert-butoxide (11.5 g, 120 mmol) were added and dissolved in 500 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 41-b (white solid, 33 g, yield: 54%).

ESI-LCMS: [M]⁺: C₈₄H₇₉D₁₁Cl₂N₂. 1207.7208.

<Synthesis of Intermediate Compound 41-c>

In an argon atmosphere, to a 1-L flask, Intermediate Compound 41-b (30 g, 25 mmol) was added and dissolved in 250 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 41-c (yellow solid, 18.5 g, yield: 61%).

ESI-LCMS: [M]⁺: C₈₄H₇₆D₁₁BCl₂N₂. 1215.7004.

<Synthesis of Compound 41>

In an argon atmosphere, to a 1 L-flask, Intermediate Compound 41-c (15 g, 12.3 mmol), 9H-carbazole-1,2,3,4,5,6,7,8-d8 (4.3 g, 24.6 mmol), Pd₂(dba)₃ (0.4 g, 0.4 mmol), tris-tert-butyl phosphine (0.4 mL, 0.8 mmol), and sodium tert-butoxide (3.5 g, 36 mmol) were added and dissolved in 100 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 41 (yellow solid, 13 g, yield: 72%).

ESI-LCMS: [M]⁺: C₁₀₈H₇₆D₂₇BN₄. 1494.0043

1H-NMR: 7.44 (s, 4H), 7.37 (s, 4H), 7.12 (d, 4H), 7.04 (m, 4H), 6.93 (s, 2H), 1.44 (s, 36H), 1.33 (s, 18H)

(7) Synthesis of Compound 46

Compound 46 according to an example may be synthesized by, for example, the steps shown in Reaction Scheme 7 below:

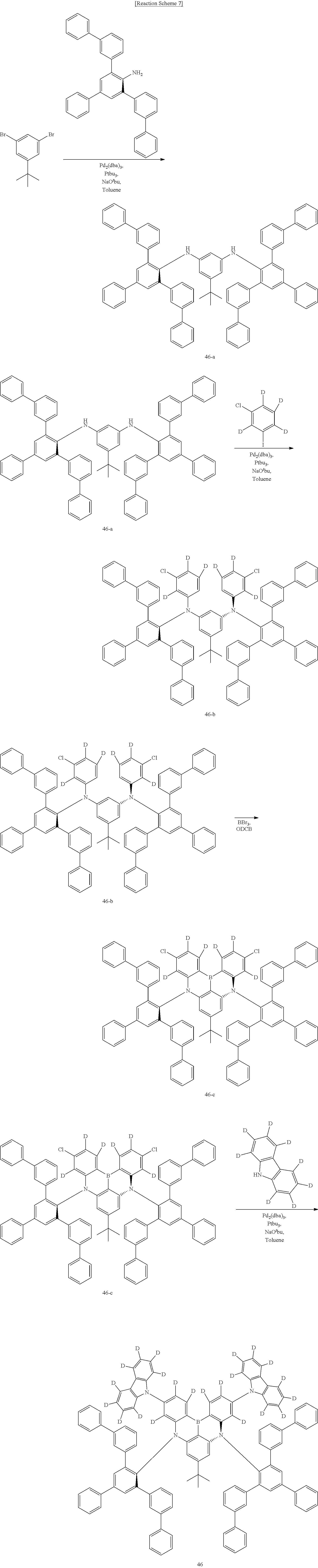

<Synthesis of Intermediate Compound 46-a>

In an argon atmosphere, to a 2-L flask, 3,5-dibromo-tert-butyl benzene (10 g, 34 mmol), 5″-phenyl-[1,1′:3′,1″:3″,1′″:3′″,1″″-quinquephenyl]-2″-amine (32 g, 68 mmol), Pd₂(dba)₃ (3.0 g, 3.3 mmol), tris-tert-butyl phosphine (3.1 mL, 6.6 mmol), and sodium tert-butoxide (9.7 g, 100 mmol) were added and dissolved in 500 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 46-a (white solid, 25 g, yield: 69%).

ESI-LCMS: [M]⁺: C₈₂H₆₄N₂. 1076.5151.

<Synthesis of Intermediate Compound 46-b>

In an argon atmosphere, to a 2 L-flask, Intermediate Compound 46-a (25 g, 23 mmol), 1-chloro-3-iodobenzene-2,4,5,6-d4 (27 g, 110 mmol), Pd₂(dba)₃ (2.1 g, 2.3 mmol), tris-tert-butyl phosphine (2.1 mL, 4.2 mmol), and sodium tert-butoxide (6.7 g, 70 mmol) were added and dissolved in 200 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 46-b (white solid, 14 g, yield: 48%).

ESI-LCMS: [M]⁺: C₉₄H₆₄D₆Cl₂N₂. 1302.5312.

<Synthesis of Intermediate Compound 46-c>

In an argon atmosphere, to a 1-L flask, Intermediate Compound 46-b (14 g, 10.7 mmol) was added and dissolved in 150 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 46-c (yellow solid, 3.3 g, yield: 24%).

ESI-LCMS: [M]⁺: C₉₄H₆₁D₆BCl₂N₂. 1310.1552.

<Synthesis of Compound 46>

In an argon atmosphere, to a 1 L-flask, Intermediate Compound 46-c (3 g, 2.3 mmol), 9H-carbazole-1,2,3,4,5,6,7,8-d8 (0.78 g, 4.6 mmol), Pd₂(dba)₃ (0.4 g, 0.4 mmol), tris-tert-butyl phosphine (0.4 mL, 0.8 mmol), and sodium tert-butoxide (6.6 g, 6.9 mmol) were added and dissolved in 30 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 46 (yellow solid, 2.8 g, yield: 78%).

ESI-LCMS: [M]⁺: C₁₁₈H₆₁D₂₂BN₄. 1588.8811

1H-NMR: 7.54 (s, 4H), 7.42 (s, 4H), 7.24 (d, 12H), 7.18 (m, 4H), 7.08 (m, 18H), 7.06 (s, 2H), 1.36 (s, 9H)

(8) Synthesis of Compound 47

Compound 47 according to an example may be synthesized by, for example, the steps shown in Reaction Scheme 8 below:

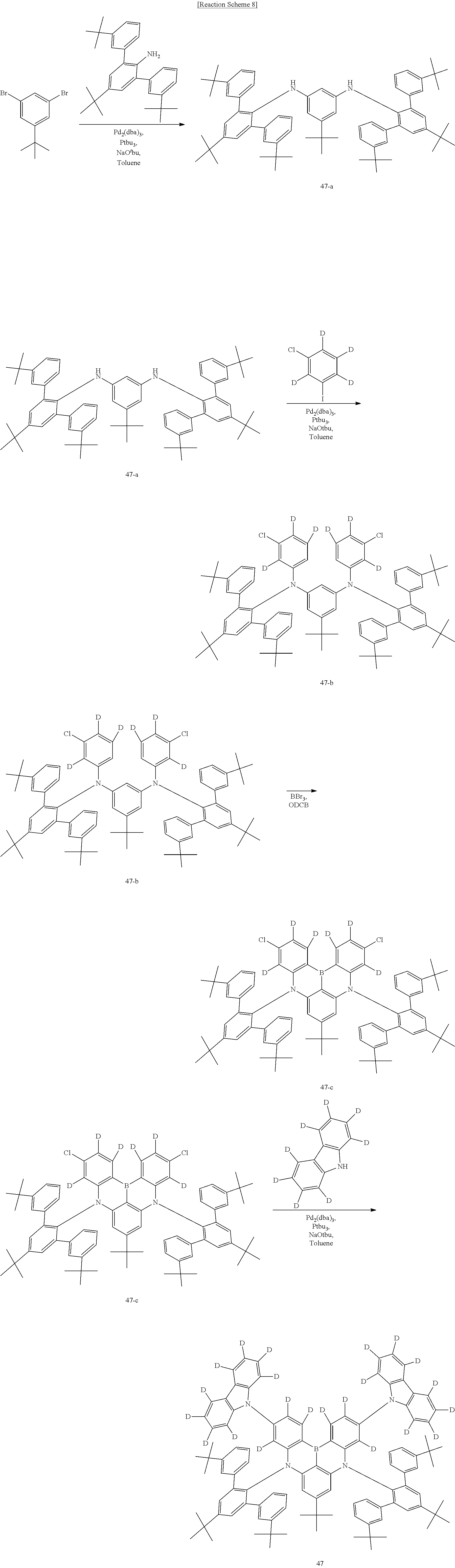

<Synthesis of Intermediate Compound 47-a>

In an argon atmosphere, to a 2-L flask, 3,5-dibromo-tert-butyl benzene (10 g, 34 mmol), 3,3″,5′-tri-tert-butyl-[1,1′:3′,1″-terphenyl]-2′-amine (28 g, 68 mmol), Pd₂(dba)₃ (3.0 g, 3.3 mmol), tris-tert-butyl phosphine (3.1 mL, 6.6 mmol), and sodium tert-butoxide (9.7 g, 100 mmol) were added and dissolved in 500 mL of toluene, and the reaction solution was stirred at about 110° C. for about 2 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 47-a (white solid, 21 g, yield: 65%).

ESI-LCMS: [M]⁺: C₇₀H₈₈N₂. 956.6912.

<Synthesis of Intermediate Compound 47-b>

In an argon atmosphere, to a 2 L-flask, Intermediate Compound 47-a (21 g, 22 mmol), 1-chloro-3-iodobenzene-2,4,5,6-d4 (27 g, 110 mmol), Pd₂(dba)₃ (2.1 g, 2.3 mmol), tris-tert-butyl phosphine (2.1 mL, 4.2 mmol), and sodium tert-butoxide (6.7 g, 70 mmol) were added and dissolved in 200 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Intermediate Compound 47-b (white solid, 14 g, yield: 54%).

ESI-LCMS: [M]⁺: C₈₂H₈₈D₆Cl₂N₂. 1182.7237.

<Synthesis of Intermediate Compound 47-c>

In an argon atmosphere, to a 1-L flask, Intermediate Compound 47-b (14 g, 11.8 mmol) was added and dissolved in 150 mL of o-dichlorobenzene, and BBr₃ (1.5 equiv.) was added thereto. The reaction solution was stirred at about 140° C. for about 12 hours. After the reaction solution was cooled, the reaction was terminated by adding triethylamine, and the solvent was removed under reduced pressure to obtain a solid. The solid thus obtained was purified and separated by silica gel column chromatography using CH₂Cl₂ and hexane as eluent to obtain Intermediate Compound 47-c (yellow solid, 4.3 g, yield: 31%).

ESI-LCMS: [M]⁺: C₈₂H₈₅D₆BCl₂N₂. 1190.7002.

<Synthesis of Compound 47>

In an argon atmosphere, to a 1 L-flask, Intermediate Compound 47-c (4.3 g, 3.6 mmol), 9H-carbazole-1,2,3,4,5,6,7,8-d8 (1.2 g, 7.2 mmol), Pd₂(dba)₃ (0.4 g, 0.4 mmol), tris-tert-butyl phosphine (0.4 mL, 0.8 mmol), and sodium tert-butoxide (6.6 g, 6.9 mmol) were added and dissolved in 30 mL of toluene, and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and filtered. In the filtrate, the solvent was removed under reduced pressure to obtain a solid. The solid thus obtained was purified and separated by silica gel column chromatography using CH₂Cl₂ and hexane as eluent to obtain Compound 47 (yellow solid, 4 g, yield: 75%).

ESI-LCMS: [M]⁺: C₁₀₆H₈₅D₂₂BN₄. 1469.0014

1H-NMR: 7.47 (s, 4H), 7.39 (s, 4H), 7.21 (m, 8H), 7.13 (m, 4H), 6.98 (s, 2H), 1.46 (s, 36H), 1.31 (s, 18H), 1.26 (s, 9H).

2. Evaluation of Compounds

Table 1 below shows Comparative Example Compounds and Example Compounds, and Tables 2 and 3 show the evaluation results of Comparative Example Compounds and Example Compounds.

TABLE 1

| | | | |
|---|---|---|---|
| Compound 1 | 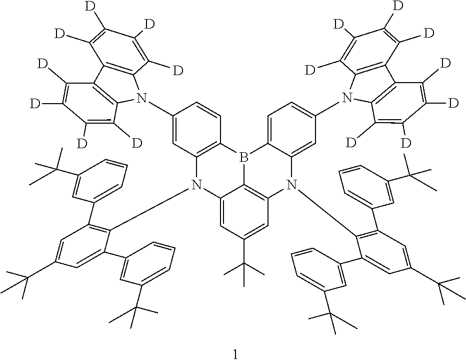 [SMILES: [2H]c1c([2H])c([2H])c2c(c1[2H])c1c([2H])c([2H])c([2H])c([2H])c1n2-c1ccc2c(c1)N(c1c(-c3cccc(C(C)(C)C)c3)cc(C(C)(C)C)cc1-c1cccc(C(C)(C)C)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cccc(C(C)(C)C)c2)cc(C(C)(C)C)cc1-c1cccc(C(C)(C)C)c1] | Compound 2 | 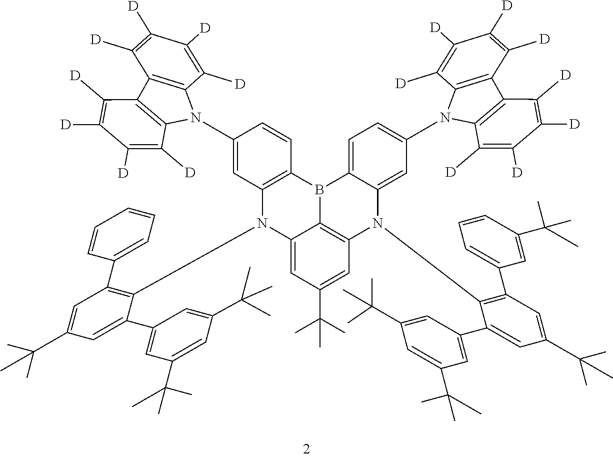 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1cc(C(C)(C)C)cc(C(C)(C)C)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2cccc(C(C)(C)C)c2)cc(C(C)(C)C)cc1-c1cc(C(C)(C)C)cc(C(C)(C)C)c1] |
| Compound 9 | 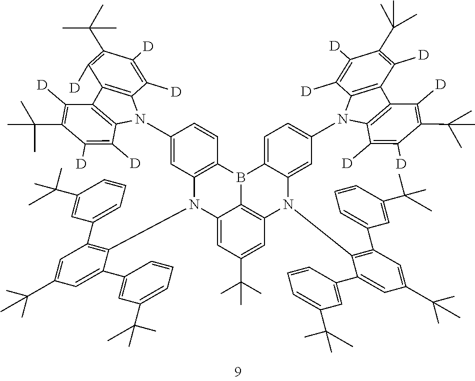 [SMILES: [2H]c1c(C(C)(C)C)c([2H])c2c3c([2H])c(C(C)(C)C)c([2H])c([2H])c3n(-c3ccc4c(c3)N(c3c(-c5cccc(C(C)(C)C)c5)cc(C(C)(C)C)cc3-c3cccc(C(C)(C)C)c3)c3cc(C(C)(C)C)cc5c3B4c3ccc(-n4c6c([2H])c([2H])c(C(C)(C)C)c([2H])c6c6c([2H])c(C(C)(C)C)c([2H])c([2H])c64)cc3N5c3c(-c4cccc(C(C)(C)C)c4)cc(C(C)(C)C)cc3-c3cccc(C(C)(C)C)c3)c2c1[2H]] | Compound 27 | 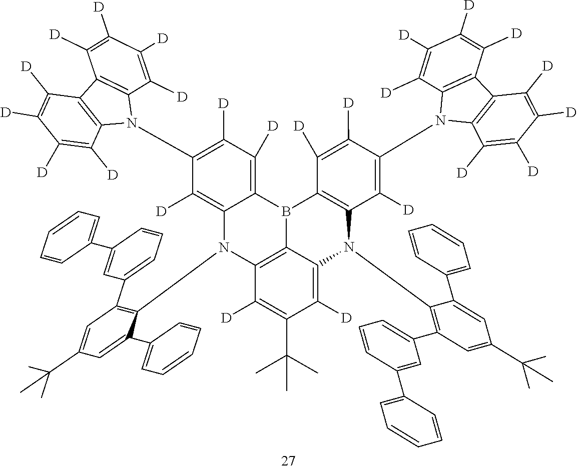 |
| Compound 38 | 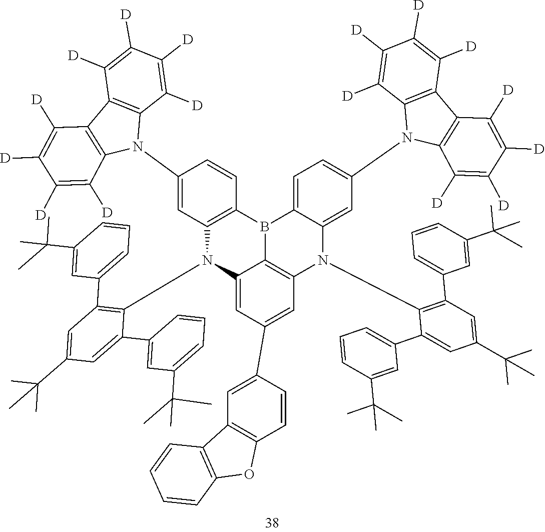 | Compound 41 | 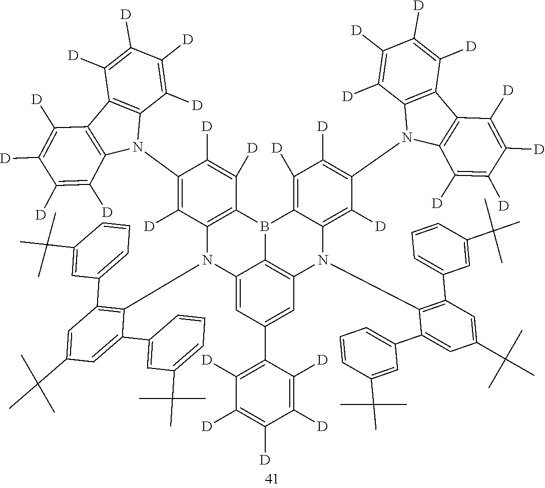 [SMILES: [2H]c1c([2H])c([2H])c(-c2cc3c4c(c2)N(c2c(-c5cccc(C(C)(C)C)c5)cc(C(C)(C)C)cc2-c2cccc(C(C)(C)C)c2)c2c([2H])c(-n5c6c([2H])c([2H])c([2H])c([2H])c6c6c([2H])c([2H])c([2H])c([2H])c65)c([2H])c([2H])c2B4c2c([2H])c([2H])c(-n4c5c([2H])c([2H])c([2H])c([2H])c5c5c([2H])c([2H])c([2H])c([2H])c54)c([2H])c2N3c2c(-c3cccc(C(C)(C)C)c3)cc(C(C)(C)C)cc2-c2cccc(C(C)(C)C)c2)c([2H])c1[2H]] |
| Compound 46 | 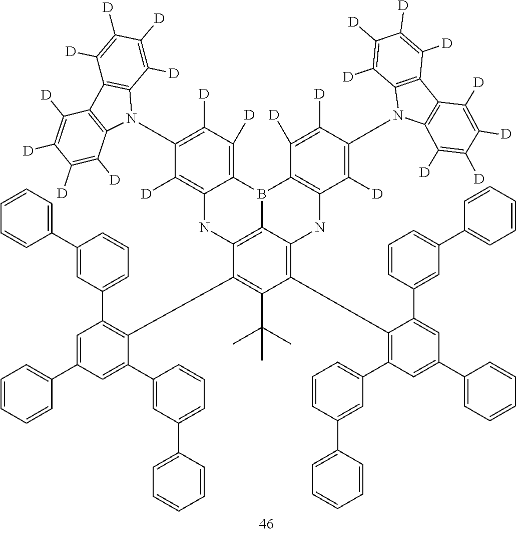 [SMILES: [2H]c1c([2H])c(-n2c3c([2H])c([2H])c([2H])c([2H])c3c3c([2H])c([2H])c([2H])c([2H])c32)c([2H])c2c1B1c3c([2H])c([2H])c(-n4c5c([2H])c([2H])c([2H])c([2H])c5c5c([2H])c([2H])c([2H])c([2H])c54)c([2H])c3Nc3c1c(c(-c1c(-c4cccc(-c5ccccc5)c4)cc(-c4ccccc4)cc1-c1cccc(-c4ccccc4)c1)c(C(C)(C)C)c3-c1c(-c3cccc(-c4ccccc4)c3)cc(-c3ccccc3)cc1-c1cccc(-c3ccccc3)c1)N2] | Compound 47 | 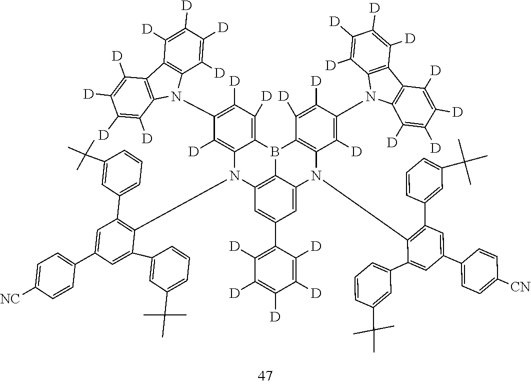 [SMILES: [2H]c1c([2H])c([2H])c(-c2cc3c4c(c2)N(c2c(-c5cccc(C(C)(C)C)c5)cc(-c5ccc(C#N)cc5)cc2-c2cccc(C(C)(C)C)c2)c2c([2H])c(-n5c6c([2H])c([2H])c([2H])c([2H])c6c6c([2H])c([2H])c([2H])c([2H])c65)c([2H])c([2H])c2B4c2c([2H])c([2H])c(-n4c5c([2H])c([2H])c([2H])c([2H])c5c5c([2H])c([2H])c([2H])c([2H])c54)c([2H])c2N3c2c(-c3cccc(C(C)(C)C)c3)cc(-c3ccc(C#N)cc3)cc2-c2cccc(C(C)(C)C)c2)c([2H])c1[2H]] |
| Comparative Example Compound CX1 | 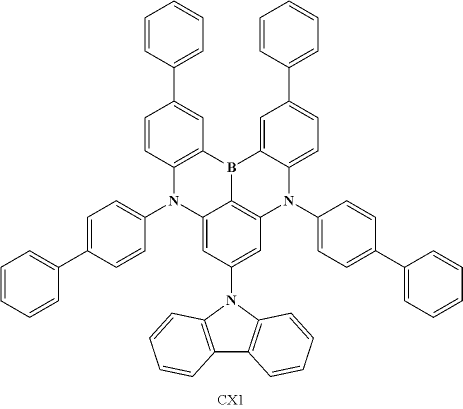 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1] | Comparative Example Compound CX2 | 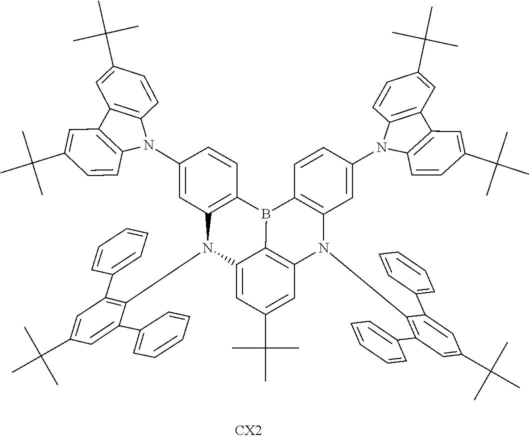 |
| Comparative Example Compound CX3 | 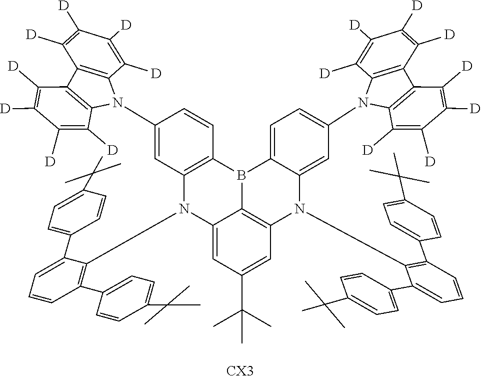 [SMILES: [2H]c1c([2H])c([2H])c2c(c1[2H])c1c([2H])c([2H])c([2H])c([2H])c1n2-c1ccc2c(c1)N(c1c(-c3ccc(C(C)(C)C)cc3)cccc1-c1ccc(C(C)(C)C)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccc(C(C)(C)C)cc2)cccc1-c1ccc(C(C)(C)C)cc1] | Comparative Example Compound CX4 | 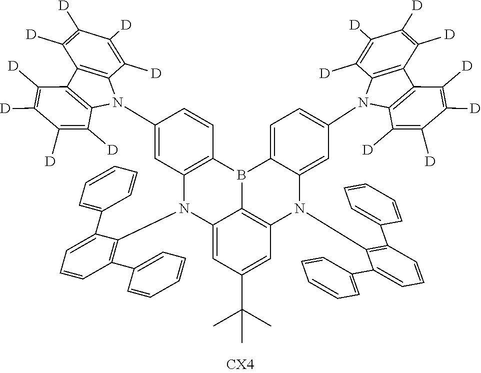 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1] |
| Comparative Example Compound CX5 | 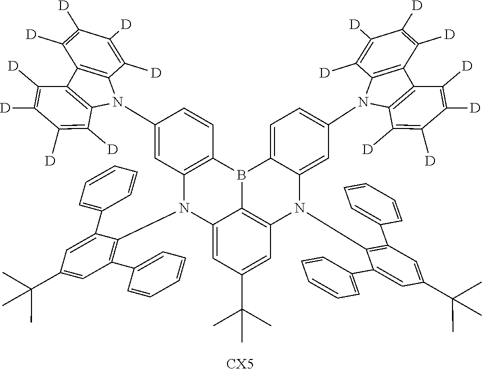 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1ccccc1] | Comparative Example Compound CX6 | 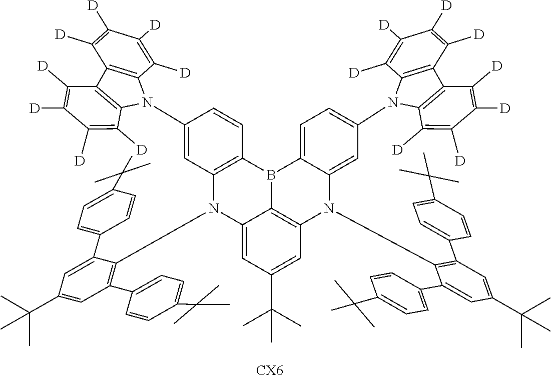 [SMILES: [2H]c1c([2H])c([2H])c2c(c1[2H])c1c([2H])c([2H])c([2H])c([2H])c1n2-c1ccc2c(c1)N(c1c(-c3ccc(C(C)(C)C)cc3)cc(C(C)(C)C)cc1-c1ccc(C(C)(C)C)cc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccc(C(C)(C)C)cc2)cc(C(C)(C)C)cc1-c1ccc(C(C)(C)C)cc1] |
| Comparative Example Compound CX7 | 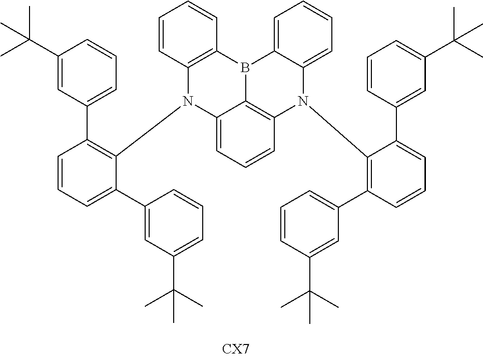 [SMILES: CC(C)(C)c1cccc(-c2cccc(-c3cccc(C(C)(C)C)c3)c2N2c3ccccc3B3c4ccccc4N(c4c(-c5cccc(C(C)(C)C)c5)cccc4-c4cccc(C(C)(C)C)c4)c4cccc2c43)c1] | — | — |

HOMO, LUMO, S1, T1, ΔE_{ST}, and a first temperature of Comparative Example Compounds and Example Compounds were evaluated, and the results are shown in Table 2. PLQY, λ_{Abs}, λₑₘᵢ, Stokes-shift, and FWQM of Comparative Example Compounds and Example Compounds were evaluated, and the results are shown in Table 3. In Tables 2 and 3, the compounds were evaluated in a solution state by diluting the compounds in a toluene solution to a concentration of 10 uM.

In Table 2, HOMO represents a highest occupied molecular orbital energy level, and LUMO represents a lowest unoccupied molecular orbital energy level. S1 represents a singlet energy level, and T1 represents a triplet energy level. The HOMO and LUMO were measured using Smart Manager software of SP2 electrochemical workstation equipment made by ZIVE LAB. The S1 and T1 were measured using FluorEssence software of fluoromax+spectrometer equipment, made by HORIBA, Ltd., equipped with a xenon light source and a monochromator.

In Table 2, ΔE_{ST} represents a difference between S1 and T1. When the compound is synthesized, a step for finally purifying the compound by sublimation is included, and a first temperature (Ts) means a temperature when 10% of the compound is lost when the compound is heated for sublimation. The higher the first temperature (Ts), the more possibility the compound is thermally decomposed, which may lead to a decrease in purity.

TABLE 2

| | | | | | | First |
|---|---|---|---|---|---|---|
| | HOMO | LUMO | S1 | T1 | | temperature |
| | (eV) | (eV) | (eV) | (eV) | ΔE_{ST} | (Ts, ° C.) |
| Compound 1 | −5.29 | −2.08 | 2.70 | 2.58 | 0.12 | 320 |
| Compound 2 | −5.36 | −2.35 | 2.71 | 2.58 | 0.13 | 324 |
| Compound 9 | −5.36 | −2.59 | 2.71 | 2.61 | 0.10 | 328 |
| Compound 27 | −5.35 | −2.27 | 2.70 | 2.58 | 0.12 | 327 |
| Compound 38 | −5.42 | −2.33 | 2.70 | 2.55 | 0.15 | 333 |
| Compound 41 | −5.48 | −2.39 | 2.68 | 2.51 | 0.17 | 322 |
| Compound 46 | −5.38 | −2.23 | 2.71 | 2.59 | 0.12 | 330 |
| Compound 47 | −5.35 | −2.29 | 2.71 | 2.59 | 0.12 | 326 |
| Comparative | −5.29 | −2.38 | 2.71 | 2.54 | 0.17 | 380 |
| Example | | | | | | |
| Compound CX1 | | | | | | |
| Comparative | −5.36 | −2.23 | 2.71 | 2.60 | 0.11 | 350 |
| Example | | | | | | |
| Compound CX2 | | | | | | |
| Comparative | −5.31 | −2.21 | 2.68 | 2.55 | 0.13 | 343 |
| Example | | | | | | |
| Compound CX3 | | | | | | |
| Comparative | −5.31 | −2.27 | 2.71 | 2.59 | 0.12 | 370 |
| Example | | | | | | |
| Compound CX4 | | | | | | |
| Comparative | −5.36 | −2.17 | 2.70 | 2.59 | 0.11 | 355 |
| Example | | | | | | |
| Compound CX5 | | | | | | |
| Comparative | −5.38 | −2.28 | 2.70 | 2.58 | 0.12 | 345 |
| Example | | | | | | |
| Compound CX6 | | | | | | |
| Comparative | −5.15 | −2.15 | 2.71 | 2.52 | 0.19 | 310 |
| Example | | | | | | |
| Compound CX7 | | | | | | |

Referring to Table 2, it may be seen that Comparative Example Compound CX7 and Compounds 1, 2, 9, 27, 38, 41, 46, and 47 exhibit relatively low first temperature (Ts) as compared with Comparative Example Compounds CXM to CX6. Compounds 1, 2, 9, 27, 38, 41, 46, and 47 are fused polycyclic compounds according to examples, and includes at least one carbazole group and at least one ortho terphenyl group substituted with the first substituent which are bonded to the pentacyclic fused ring. As described above, the higher the first temperature (Ts), the greater the likelihood of thermal decomposition of the compound, which may cause a decrease in purity. Accordingly, it may be seen that the fused polycyclic compound of an example has a relatively low possibility of thermal decomposition when the compound is synthesized, and is suitable for a material for the light emitting element.

Referring to Table 2, it may be seen that Comparative Example Compounds CX1 to CX7 and Compounds 1, 2, 9, 27, 38, 41, 46, and 47 have the minimum of an overlap between the HOMO energy level and the LUMO energy level, and a ΔE_{ST} of about 0.2 eV or less. Accordingly, it may be seen that Comparative Example Compounds CX1 to CX7 and Compounds 1, 2, 9, 27, 38, 41, 46, and 47 may have the possibility of reverse intersystem crossing (RISC).

In Table 3 below, PLQY means a photoluminescence quantum yield, and measured using PLQY measurement software of Quantaurus-QY Absolute PL quantum yield spectrometer equipment, made by Hamamatsu Co., equipped with a xenon light source, a monochromator, a photonic multichannel analyzer, and an integrating sphere. λ_{Abs} represents the maximum absorption wavelength, λₑₘᵢ represents the maximum emission wavelength, and FWQM stands for full-width quarter maximum. The λ_{Abs}, λₑₘᵢ and FWQM were measured using FluorEssence software of fluoromax+spectrometer equipment, made by HORIBA, Ltd., equipped with a xenon light source and a monochromator. Stokes-shift represents a difference between the maximum wavelength when the energy is absorbed and the maximum wavelength when the energy is emitted.

TABLE 3

| | PLQY | λ_{Abs} | λₑₘᵢ | | |
|---|---|---|---|---|---|
| | (%) | (nm) | (nm) | Stokes-shift | FWQM |
| Compound 1 | 92.8 | 448 | 459 | 11 | 35 |
| Compound 2 | 92.6 | 448 | 458 | 10 | 34 |
| Compound 9 | 90.9 | 446 | 456 | 10 | 33 |
| Compound 27 | 90.1 | 446 | 459 | 13 | 34 |
| Compound 38 | 96.3 | 447 | 459 | 12 | 35 |
| Compound 41 | 91.8 | 450 | 462 | 12 | 36 |
| Compound 46 | 95.3 | 448 | 458 | 10 | 35 |
| Compound 47 | 99.0 | 448 | 458 | 10 | 34 |
| Comparative | 92.7 | 447 | 457 | 10 | 31 |
| Example | | | | | |
| Compound CX1 | | | | | |
| Comparative | 70.3 | 445 | 457 | 12 | 36 |
| Example | | | | | |
| Compound CX2 | | | | | |
| Comparative | 83.8 | 445 | 459 | 14 | 39 |
| Example | | | | | |
| Compound CX3 | | | | | |
| Comparative | 75.8 | 446 | 458 | 12 | 37 |
| Example | | | | | |
| Compound CX4 | | | | | |
| Comparative | 66.9 | 446 | 459 | 13 | 36 |
| Example | | | | | |
| Compound CX5 | | | | | |
| Comparative | 84.0 | 445 | 459 | 14 | 39 |
| Example | | | | | |
| Compound CX6 | | | | | |
| Comparative | 84.6 | 443 | 457 | 14 | 37 |
| Example | | | | | |
| Compound CX7 | | | | | |

Referring to Table 3, it may be seen that Comparative Example Compound CX1, CX2, CX4, and CX5 and Compounds 1, 2, 9, 27, 38, 41, 46, and 47 have relatively small values of Stokes-shift as compared with Comparative Example Compounds CX3, CX6, and CX7. It may be seen that Comparative Example Compound CX1 and Compounds 1, 2, 9, 27, 38, 41, 46, and 47 have PLQY superior to Comparative Example Compounds CX2 to CX7.

In Table 3, Comparative Example Compound CX3 has a relatively large value of Stokes-shift, and the maximum absorption wavelength (λ_{Abs}) is blue-shifted. Comparative Example Compound CX3 is a compound in which a t-butyl group is bonded to the carbon atom at the para-position of both side phenyl groups (e.g., the first phenyl group, the second phenyl group, the fourth phenyl group, and the fifth phenyl group) in the ortho terphenyl group. Accordingly, the luminescence center is excessively bent, and thus Comparative Example Compound CX3 exhibits relatively large FWQM and Stokes-shift values, and the maximum absorption wavelength (λ_{Abs}) is blue-shifted. Thus, for Comparative Example Compound CX3, the Fφrster resonance energy transfer (FRET) may not be readily performed, and the stability of material deteriorates.

3. Manufacture and Evaluation of Light Emitting Elements

(1) Manufacture of Light Emitting Elements

Light emitting elements including the fused polycyclic compound of an example or Comparative Example Compound in the emission layer were manufactured as follows. Compounds 1, 2, 9, 27, 38, 41, 46, and 47 which are fused polycyclic compounds of examples were used as a dopant material for the emission layer to manufacture the light emitting elements of Examples 1 to 8. Comparative Example Compound CX1 to CX7 were used as a dopant material to manufacture the light emitting elements of Comparative Examples 1 to 7.

A glass substrate (made by Corning Co.), on which an ITO electrode of about 15 Ω/cm² (about 1,200 Å) was formed as a first electrode, was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

On the first electrode, NPD was deposited to form a 300 Å-thick hole injection layer. On the hole injection layer, H-1-19 was deposited to form a 200 Å-thick hole transport layer, and on the hole transport layer, CzSi was deposited to form a 100 Å-thick electron blocking layer.

On the electron blocking layer, as in Table 4, a host mixture in which the first host (HT) and the second host (ET) were mixed in a weight ratio of 1:1, a sensitizer, and a dopant were co-deposited in a weight ratio of 85:14:1 to form a 200 Å-thick emission layer. Example Compounds or Comparative Example Compounds were used as a dopant.

On the emission layer, TSP01 was deposited to form a 200 Å-thick hole blocking layer, and on the hole blocking layer, TPBi was deposited to form a 300 Å-thick electron transport layer. On the electron transport layer, LiF was deposited to form a 10 Å-thick electron injection layer, and on the electron injection layer, Al was deposited to form a 3,000 Å-thick second electrode. On the second electrode, P4 was deposited to form a 700 Å-thick capping layer, thereby manufacturing a light emitting element.

(Materials Used to Manufacture Light Emitting Elements)

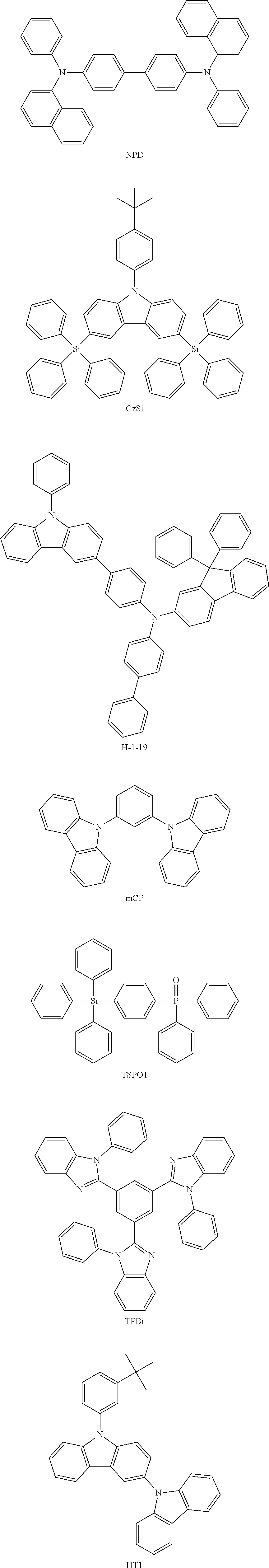

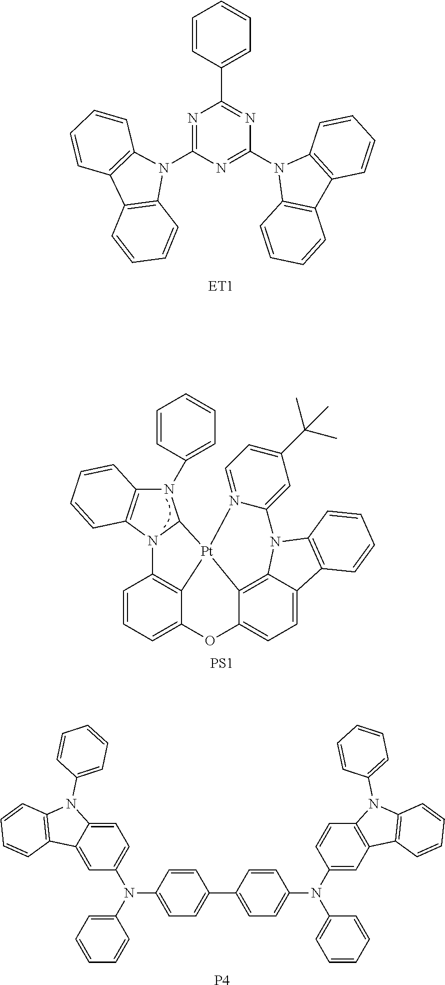

Among the materials used when the light emitting element was manufactured, Compound HT1 is the same as HT1 in Compound Group 2 as described above, and Compound ET1 is the same as ETH85 in Compound Group 3 as described above. Compound PS1 is the same as AD-37 in Compound Group 4 as described above.

(2) Evaluation of Light Emitting Elements

The light emitting elements of Comparative Examples and Examples were evaluated and the results are shown in Table 4 below. Driving voltage at a current density of 1,000 cd/m2, top luminous efficiency, light emission wavelength, service life, CIE(x,y), and Q.E. were measured by using Keithley MU 236 and a luminance meter PR650.

The Q.E represents an external quantum efficiency, the top luminous efficiency represents luminous efficiency in a top emission type light emitting element, and the CIE(x,y) represents CIE chromaticity coordinates. For the service life (T₉₅), the time taken to be reduced to 95% brightness relative to an initial brightness was measured, and a relative service life was calculated based on Comparative Example 1, and the results are listed in Table 4.

TABLE 4

| | | | | | Top | | | | |
|---|---|---|---|---|---|---|---|---|---|
| Examples of | | | | Driving | luminous | Luminescence | Service | | |
| manufactured | Host | | | voltage | efficiency | wavelength | life | CIE | Q.E |
| elements | (HT/ET) | Sensitizer | Dopant | (V) | (cd/A) | (nm) | (T95) | (x, y) | (%) |
| Example 1 | HT1/ET1 | PS1 | Compound | 4.0 | 25.1 | 462 | 3.9 | 0.137, | 53.7 |
| | | | 1 | | | | | 0.053 | |
| Example 2 | HT1/ET1 | PS1 | Compound | 3.9 | 24.6 | 462 | 4.3 | 0.135, | 49.8 |
| | | | 2 | | | | | 0.055 | |
| Example 3 | HT1/ET1 | PS1 | Compound | 4.1 | 23.7 | 461 | 3.3 | 0.134, | 48.4 |
| | | | 9 | | | | | 0.052 | |
| Example 4 | HT1/ET1 | PS1 | Compound | 4.2 | 25.9 | 462 | 4.1 | 0.131, | 50.5 |
| | | | 27 | | | | | 0.053 | |
| Example 5 | HT1/ET1 | PS1 | Compound | 4.1 | 24.1 | 461 | 3.0 | 0.138, | 49.9 |
| | | | 38 | | | | | 0.049 | |
| Example 6 | HT1/ET1 | PS1 | Compound | 4.1 | 25.2 | 463 | 4.7 | 0.134, | 54.0 |
| | | | 41 | | | | | 0.056 | |
| Example 7 | HT1/ET1 | PS1 | Compound | 4.1 | 24.3 | 462 | 4.5 | 0.138, | 50.3 |
| | | | 46 | | | | | 0.051 | |
| Example 8 | HT1/ET1 | PS1 | Compound | 4.1 | 25.5 | 462 | 4.8 | 0.134, | 55.0 |
| | | | 47 | | | | | 0.054 | |
| Comparative | HT1/ET1 | PS1 | Comparative | 4.4 | 19.3 | 462 | 1 | 0.132, | 43.9 |
| Example 1 | | | Example | | | | | 0.051 | |
| | | | Compound | | | | | | |
| | | | CX1 | | | | | | |
| Comparative | HT1/ET1 | PS1 | Comparative | 4.2 | 21.5 | 462 | 1.6 | 0.136. | 46.1 |
| Example 2 | | | Example | | | | | 0.054 | |
| | | | Compound | | | | | | |
| | | | CX2 | | | | | | |
| Comparative | HT1/ET1 | PS1 | Comparative | 4.2 | 21.1 | 461 | 1.1 | 0.137, | 46.4 |
| Example 3 | | | Example | | | | | 0.052 | |
| | | | Compound | | | | | | |
| | | | CX3 | | | | | | |
| Comparative | HT1/ET1 | PS1 | Comparative | 4.3 | 18.6 | 462 | 2.1 | 0.137, | 41.6 |
| Example 4 | | | Example | | | | | 0.052 | |
| | | | Compound | | | | | | |
| | | | CX4 | | | | | | |
| Comparative | HT1/ET1 | PS1 | Comparative | 4.2 | 19.6 | 461 | 1.5 | 0.137, | 42.8 |
| Example 5 | | | Example | | | | | 0.053 | |
| | | | Compound | | | | | | |
| | | | CX5 | | | | | | |
| Comparative | HT1/ET1 | PS1 | Comparative | 4.2 | 20.6 | 462 | 1.8 | 0.137, | 46.8 |
| Example 6 | | | Example | | | | | 0.052 | |
| | | | Compound | | | | | | |
| | | | CX6 | | | | | | |
| Comparative | HT1/ET1 | PS1 | Comparative | 5.4 | 16.3 | 462 | 0.2 | 0.135, | 35.3 |
| Example 7 | | | Example | | | | | 0.054 | |
| | | | Compound | | | | | | |
| | | | CX7 | | | | | | |

Referring to Table 4, it may be seen that the light emitting elements of Examples 1 to 8 have excellent luminous efficiency and external quantum efficiency (Q.E) as compared with the light emitting elements of Comparative Examples 1 to 7. It may be seen that the light emitting elements of Examples 1 to 8 have relatively long service lives as compared with the light emitting elements of Comparative Examples 1 to 7. The light emitting elements of Examples 1 to 8 include Compounds 1, 2, 9, 27, 38, 41, 46, and 47, and are compounds in which the first substituent is bonded to at least one carbazole group and the carbon atom at the meta-position of the both side phenyl groups (the first phenyl group, the second phenyl group, the fourth phenyl group, and the fifth phenyl group as described above) in the ortho terphenyl group. Compounds 1, 2, 9, 27, 38, 41, 46, and 47 are the fused polycyclic compounds according to embodiments. Accordingly, the fused polycyclic compounds may have a decrease in Dexter energy transfer due to the prevention of the interaction between molecules. The light emitting element including the fused polycyclic compound may exhibit high efficiency and long service life characteristics.

Referring to Table 4, it may be seen that the light emitting elements of Comparative Examples 1 to 7 and Examples 1 to 8 exhibit similar light emission wavelengths. It may be seen that the light emitting elements of Comparative Examples 1 to 7 and Examples 1 to 8 exhibit similar CIE chromaticity coordinates.

The light emitting elements of Comparative Examples 1 to 3 include Comparative Example Compounds CX1 to CX3. Comparative Example Compound CX1 does not include a carbazole group, Comparative Example Compound CX2 does not include a substituent besides a hydrogen atom at the carbon atom at the meta-position in the both side phenyl groups of the ortho terphenyl group. Accordingly, it may be seen that the light emitting elements of Comparative Examples 1 and 2 including Comparative Example Compounds CX1 and CX2 respectively exhibit relatively low efficiency and short service life.

Comparative Example Compound CX3 includes an unsubstituted t-butyl group at the carbon atom at the para-position in both side phenyl groups of the ortho terphenyl group. As described above with reference to Table 3, the luminescence center is excessively bent, and thus Comparative Example Compound CX3 exhibits relatively large FWQM and Stokes-shift values, and the maximum absorption wavelength (λ_{Abs}) is blue-shifted. Accordingly, it may be seen that the light emitting element of Comparative Example 3 including Comparative Example Compound CX3 exhibits relatively low efficiency and short service life.

Comparative Example Compounds CX4 and CX5 do not include a substituent besides a hydrogen atom in the both side phenyl groups of the ortho terphenyl group. Comparative Example Compound CX6 does not include a substituent besides a hydrogen atom at the carbon atom at the meta-position in the both side phenyl groups, but includes an unsubstituted t-butyl group at the carbon atom at the para-position. Comparative Example Compound CX7 does not include at least one carbazole group (i.e., Formula 2) directly bonded to the pentacyclic fused ring. Accordingly, it may be seen that the light emitting elements of Comparative Example 4 to 7 exhibit relatively low efficiency and short service life.

In the light emitting element, the emission layer may include the fused polycyclic compound. The fused polycyclic compound according to an embodiment may include the pentacyclic fused ring containing two nitrogen atoms and one boron atom as ring-forming atoms, and the ortho terphenyl groups may be bonded to the two nitrogen atoms respectively. At least one carbazole group may be directly bonded to the pentacyclic fused ring. In the ortho terphenyl group, the first substituent may be bonded to at least one carbon atom of the carbon atoms at the meta-position in both side phenyl groups bonded to the central phenyl group. The first substituent may be a substituted or unsubstituted germanium group, a substituted or unsubstituted silyl group, a substituted or unsubstituted alkyl group having 1 to 60 carbon atoms, or a substituted or unsubstituted aryl group having 6 to 60 ring-forming carbon atoms. Accordingly, the fused polycyclic compound according to an example may have a decrease in Dexter energy transfer due to the prevention of the interaction between molecules. The light emitting element including the fused polycyclic compound according to an embodiment having a decrease in Dexter energy transfer may exhibit high efficiency and long service life characteristics.

The light emitting element may include the fused polycyclic compound, thereby exhibiting high efficiency and long service life characteristics.

The fused polycyclic compound may contribute to the improvement in the light efficiency and a long service life of the light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises:
a first compound represented by Formula 1; and
at least one of a second compound represented by Formula HT-1, a third compound represented by Formula ET-1, or a fourth compound represented by Formula M-b: 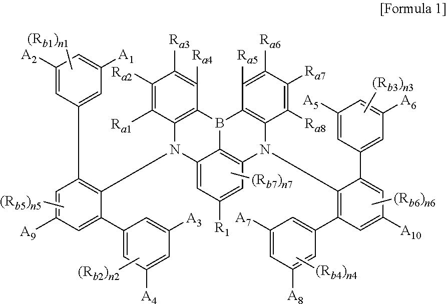
wherein, in Formula 1,
at least one of Rₐ₁ to Rₐ₈ is each independently a group represented by Formula 2,
the remainder of Rₐ₁ to Rₐ₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms,
at least one of A₁ to A₈ is each independently a first substituent,
the remainder of A₁ to A₈ are each independently a hydrogen atom or a deuterium atom,
the first substituent is a substituted or unsubstituted germanium group, a substituted or unsubstituted silyl group, a substituted or unsubstituted alkyl group having 1 to 60 carbon atoms, or a substituted or unsubstituted aryl group having 6 to 60 ring-forming carbon atoms,
A₉ and A₁₀ are each independently a hydrogen atom, a deuterium atom, a cyano group, a substituted or unsubstituted alkyl group having 1 to 60 carbon atoms, or a substituted or unsubstituted aryl group having 6 to 60 ring-forming carbon atoms,
R₁ is a hydrogen atom, a deuterium atom, a halogen atom, a cyano group, a nitro group, a hydroxyl group, a substituted or unsubstituted silyl group, a substituted or unsubstituted amine group, a substituted or unsubstituted alkoxy group, a substituted or unsubstituted alklythio group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or is bonded to an adjacent group to form a ring,
n1 to n4 are each independently an integer from 0 to 3,
n5 to n7 are each independently an integer from 0 to 2, and
R_{b1} to R_{b7} are each independently a hydrogen atom or a deuterium atom; 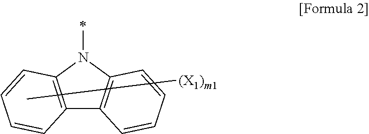
wherein in Formula 2,
m1 is an integer from 0 to 8, and
X₁ is a hydrogen atom, a deuterium atom, a cyano group, or a substituted or unsubstituted alkyl group having 1 to 60 carbon atoms: 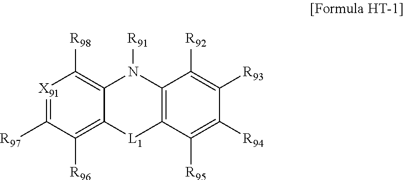
wherein in Formula HT-1,
L₁ is a direct linkage, C(R₉₉)(R₁₀₀), or Si(R₁₀₁)(R₁₀₂),
X₉₁ is N or C(R₁₀₃), and
R₉₁ to R₁₀₃ are each independently a hydrogen atom, a deuterium atom, a cyano group, a substituted or unsubstituted silyl group, a substituted or unsubstituted oxy group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring; 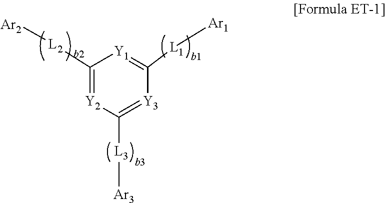
wherein in Formula ET-1,
at least one of Y₁ to Y₃ is each N, and
the remainder of Y₁ to Y₃ are each independently C(Rₐ),
Rₐ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and 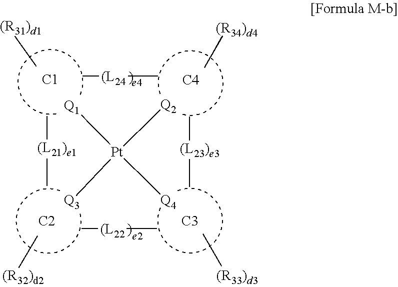
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 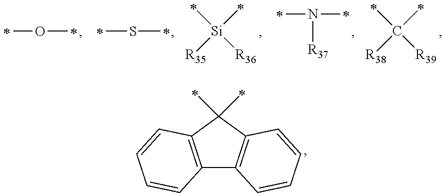
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

2. The light emitting element of claim 1, wherein the first compound is represented by Formula 1-A1 or Formula 1-A2: 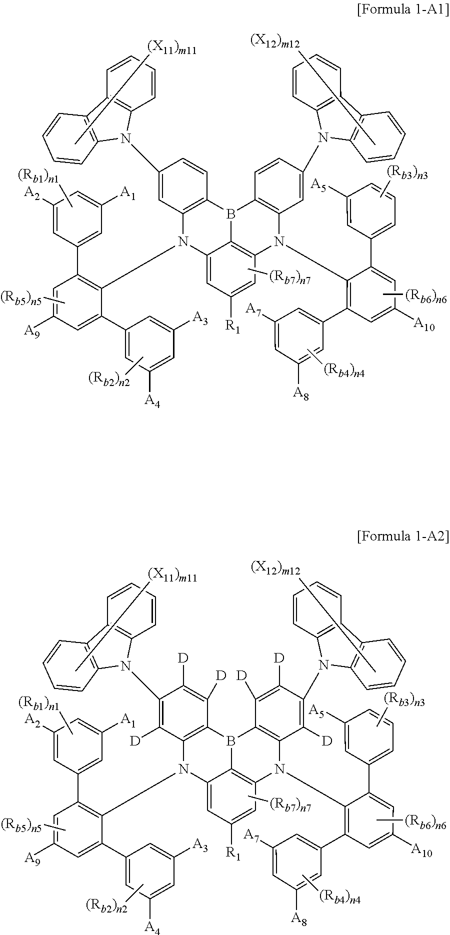
wherein in Formula 1-A1 and Formula 1-A2,
m11 and m12 are each independently an integer from 0 to 8,
X₁₁ and X₁₂ are each independently a hydrogen atom, a deuterium atom, a cyano group, or a substituted or unsubstituted alkyl group having 1 to 60 carbon atoms, and
A₁ to A₁₀, R₁, n1 to n7, and R_{b1} to R_{b7} are the same as defined in Formula 1.

3. The light emitting element of claim 1, wherein the first compound is represented by Formula 1-B: 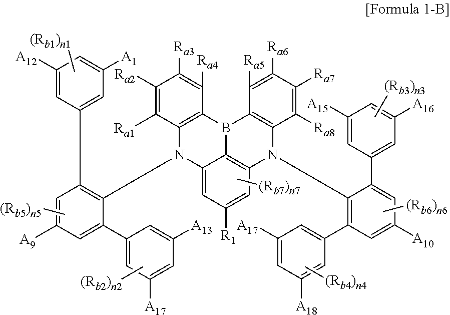
wherein in Formula 1-B,
A₁₄ and A₁₈ are each independently a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms,
A₁₁ to A₁₃ and A₁₅ to A₁₇ are each independently a hydrogen atom, a deuterium atom, a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and
Rₐ₁ to Rₐ₈, A₉, A₁₀, R₁, n1 to n7, and R_{b1} to R_{b7} are the same as defined in Formula 1.

4. The light emitting element of claim 3, wherein the first compound is represented by one of Formula 1-B1 to Formula 1-B3: 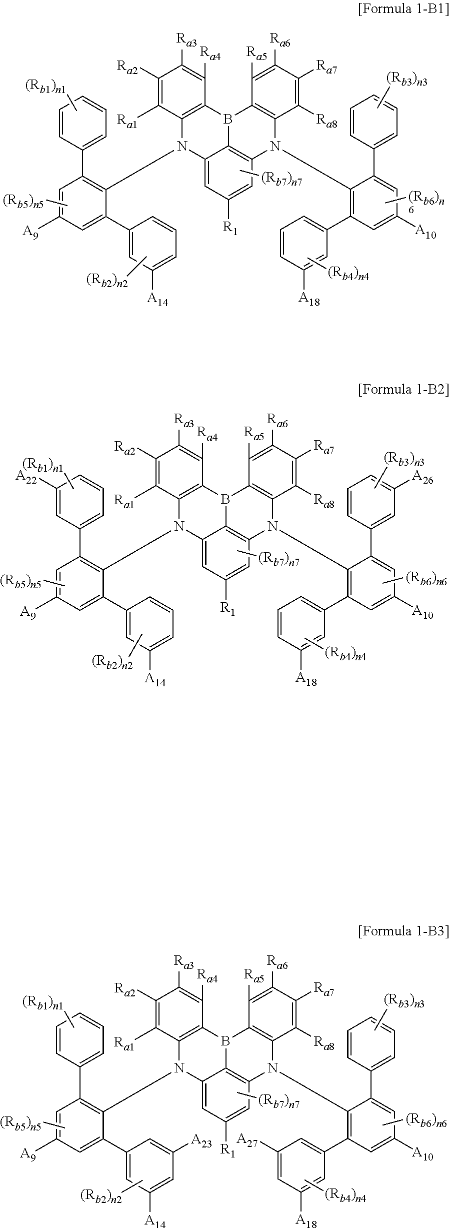
wherein in Formula 1-B2 and Formula 1-B3,
A₂₂, A₂₃, A₂₆, and A₂₇ are each independently a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and
wherein in Formula 1-B1 to Formula 1-B3,
Rₐ₁ to Rₐ₈, A₉, A₁₀, A₁₄, A₁₈, R₁, n1 to n7, and R_{b1} to R_{b7} are the same as defined in Formula 1-B.

5. The light emitting element of claim 1, wherein the first substituent is a substituted or unsubstituted trimethylgermanium group, a substituted or unsubstituted trimethylsilyl group, a substituted or unsubstituted ethyl group, a substituted or unsubstituted isopropyl group, a substituted or unsubstituted propyl group, a substituted or unsubstituted t-butyl group, a substituted or unsubstituted cyclohexyl group, or a substituted or unsubstituted phenyl group.

6. The light emitting element of claim 1, wherein the first substituent is represented by one of Formula F-1 to Formula F-11: 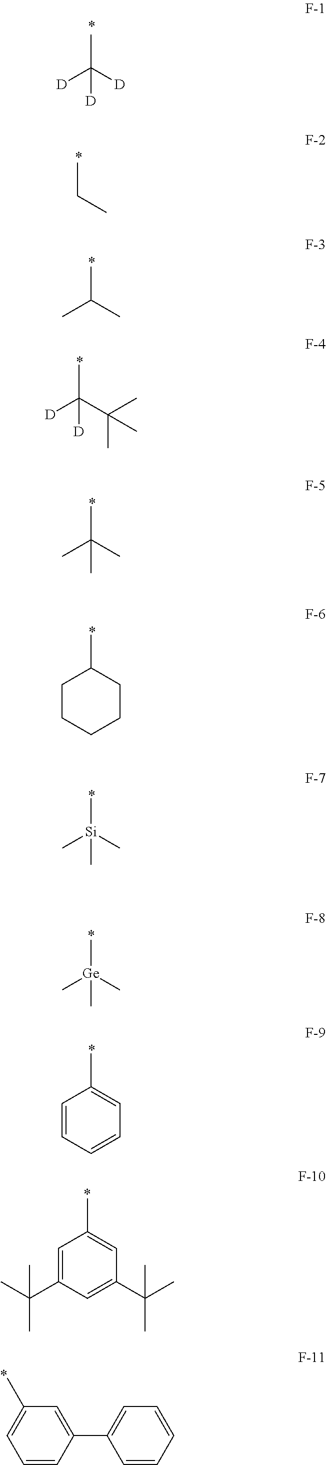
wherein in Formula F-1 and Formula F-4,
D is a deuterium atom.

7. The light emitting element of claim 1, wherein the first compound is represented by Formula 1-C1 or Formula 1-C2: 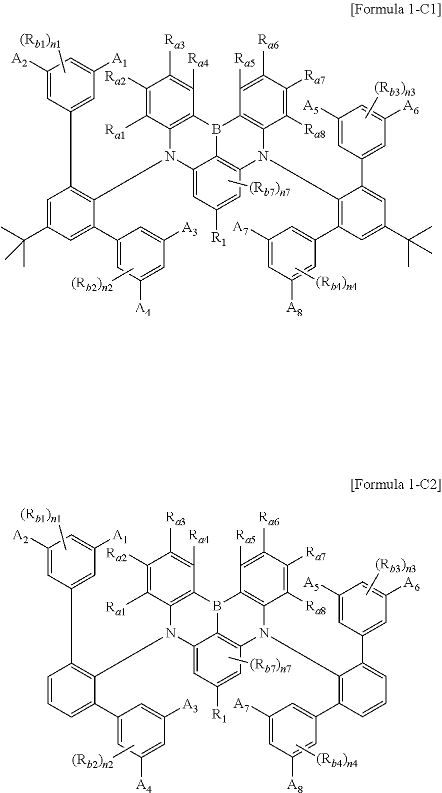
wherein in Formula 1-C1 and Formula 1-C2,
Rₐ₁ to Rₐ₈, A₁ to A₈, R₁, n1 to n4, n7, R_{b1} to R_{b4}, and R_{b7} are the same as defined in Formula 1.

8. The light emitting element of claim 1, wherein the group represented by Formula 2 is a group represented by Formula 2-1: 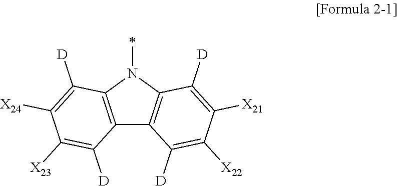
wherein in Formula 2-1,
X₂₁ to X₂₄ are each independently a deuterium atom, a cyano group, a substituted or unsubstituted methyl group, or a substituted or unsubstituted t-butyl group, and
D is a deuterium atom.

9. The light emitting element of claim 1, wherein in Formula 1, R₁ is represented by one of Formula R1-1 to Formula R1-13: 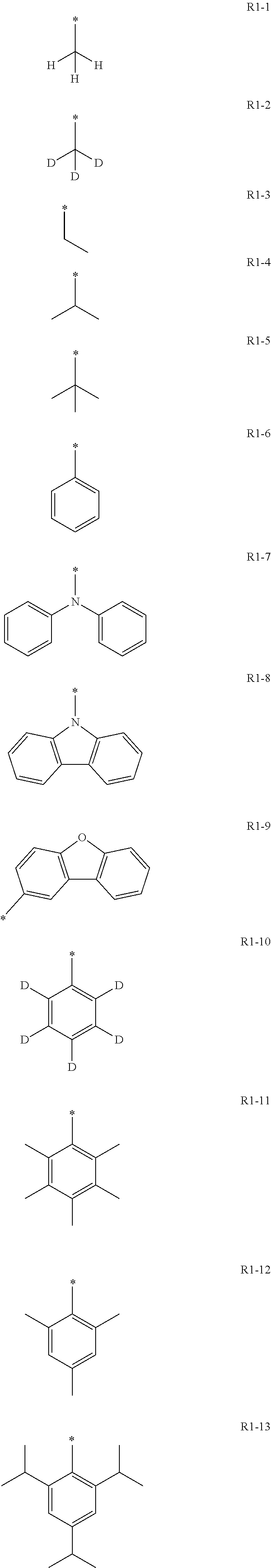
wherein in Formula R1-2 and Formula R1-10,
D is a deuterium atom.

10. The light emitting element of claim 1, wherein
the emission layer comprises a host and a dopant, and
the dopant comprises the first compound.

11. The light emitting element of claim 1, wherein the emission layer comprises the first compound, the second compound, the third compound, and the fourth compound.

12. The light emitting element of claim 1, wherein the first compound comprises at least one compound selected from Compound Group 1: 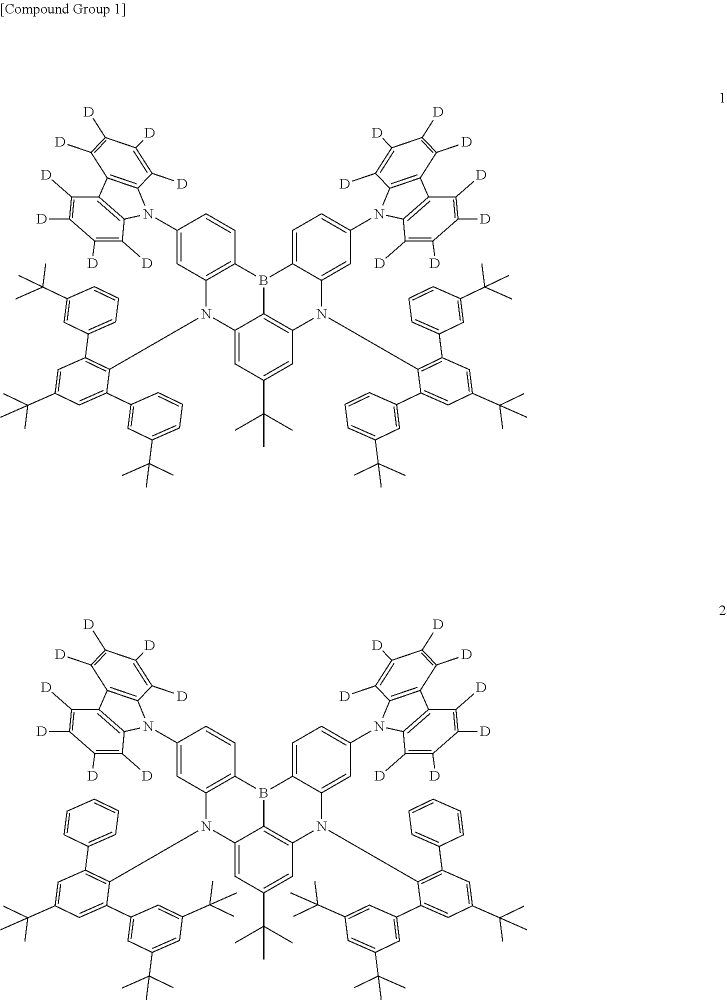 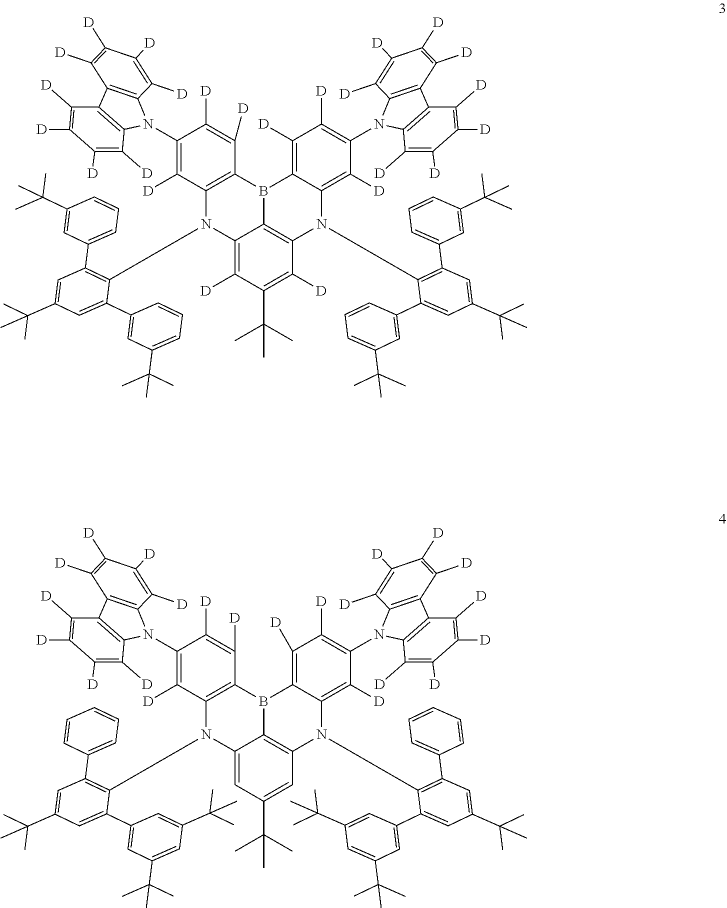 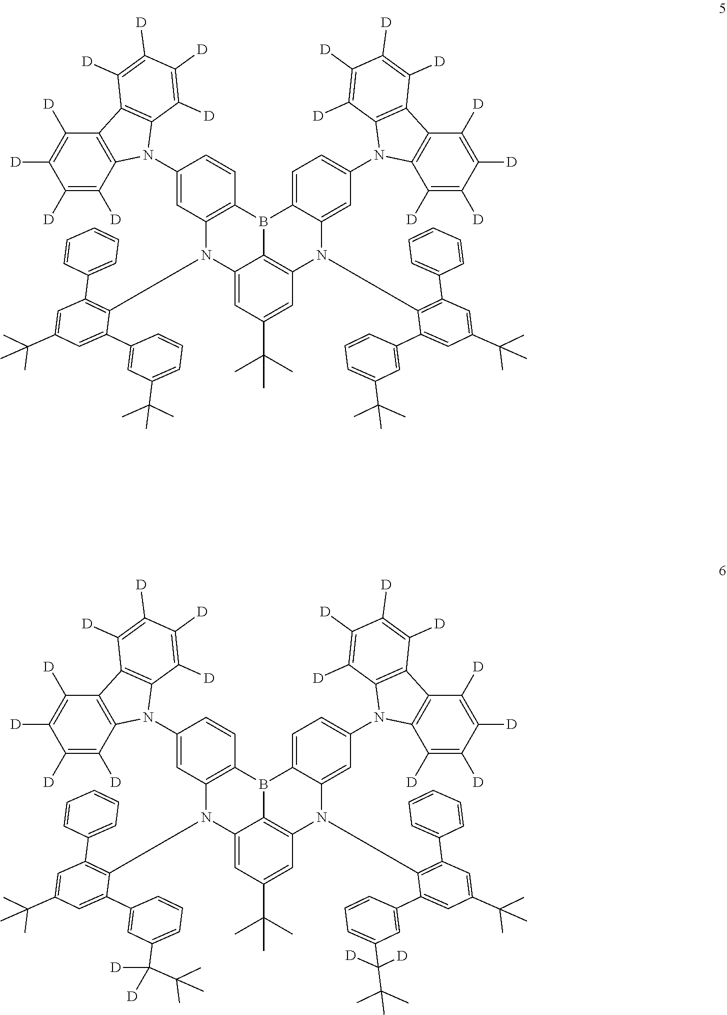 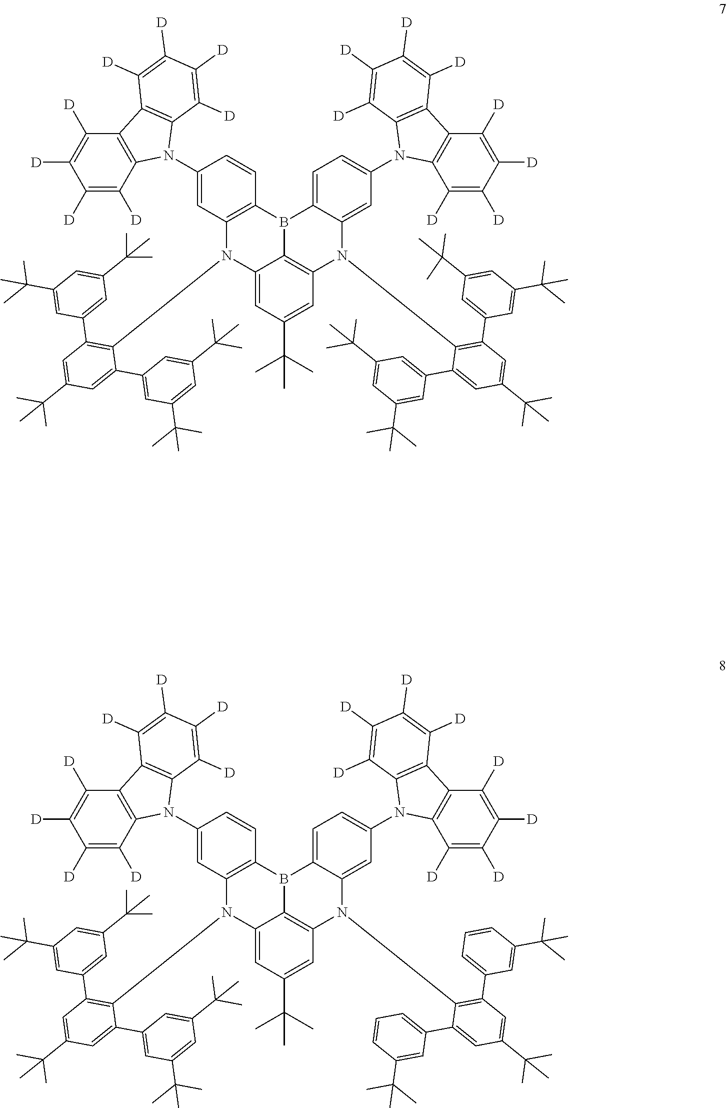 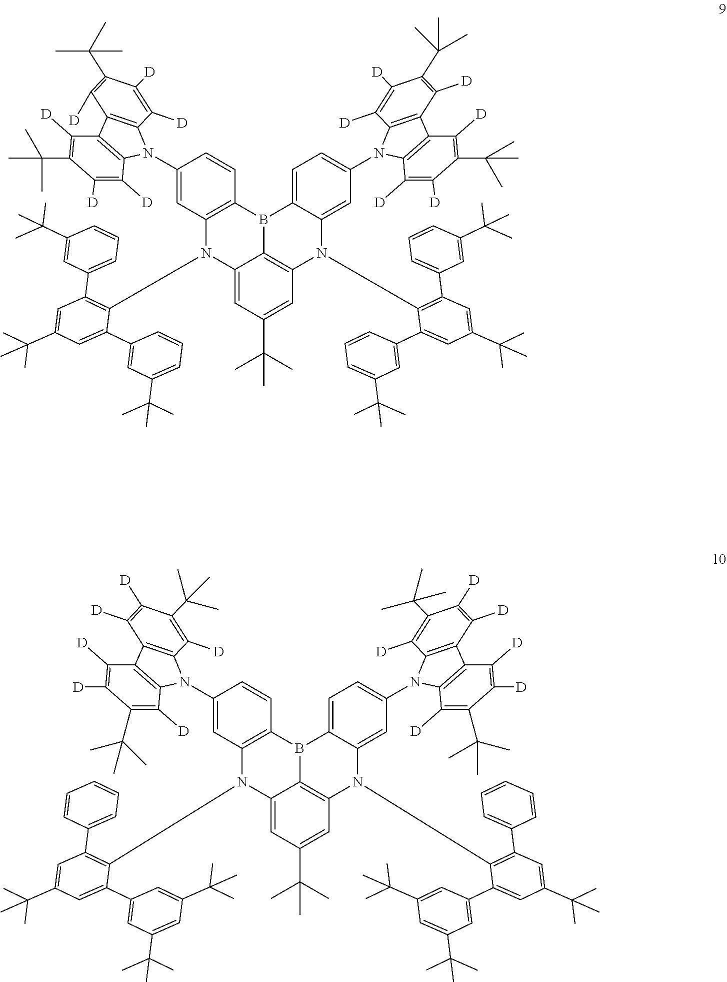 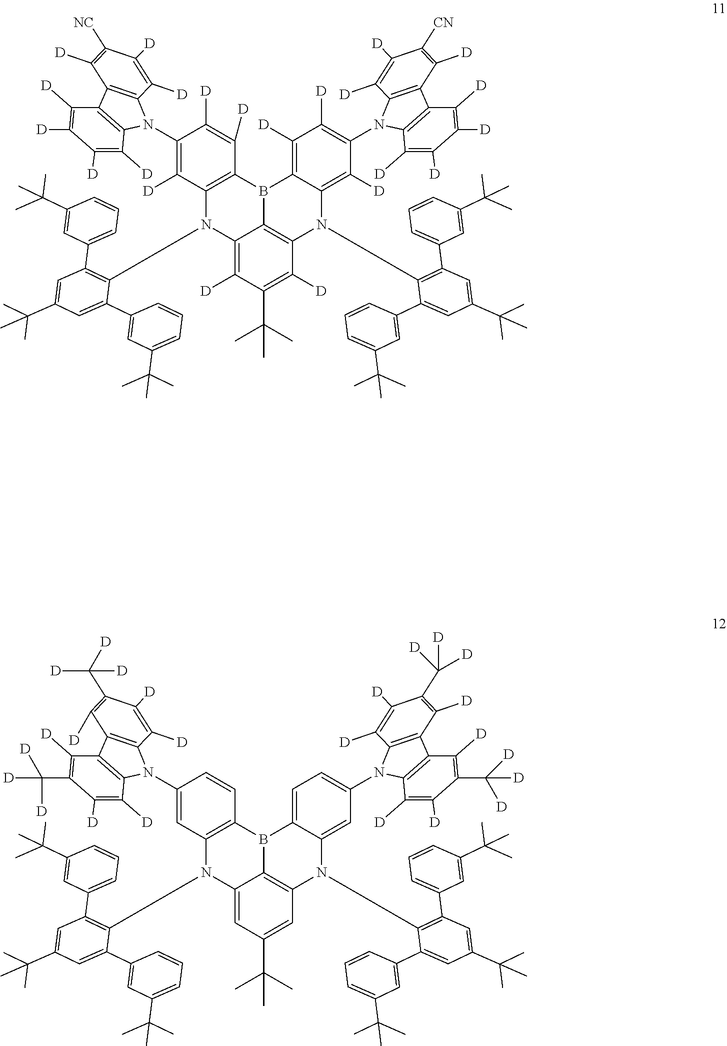 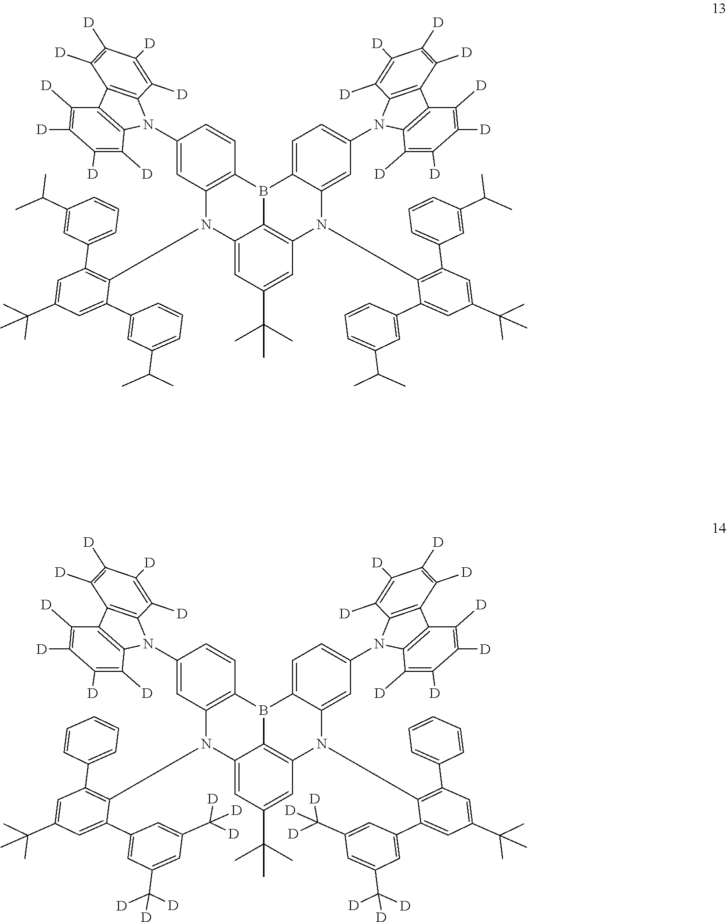 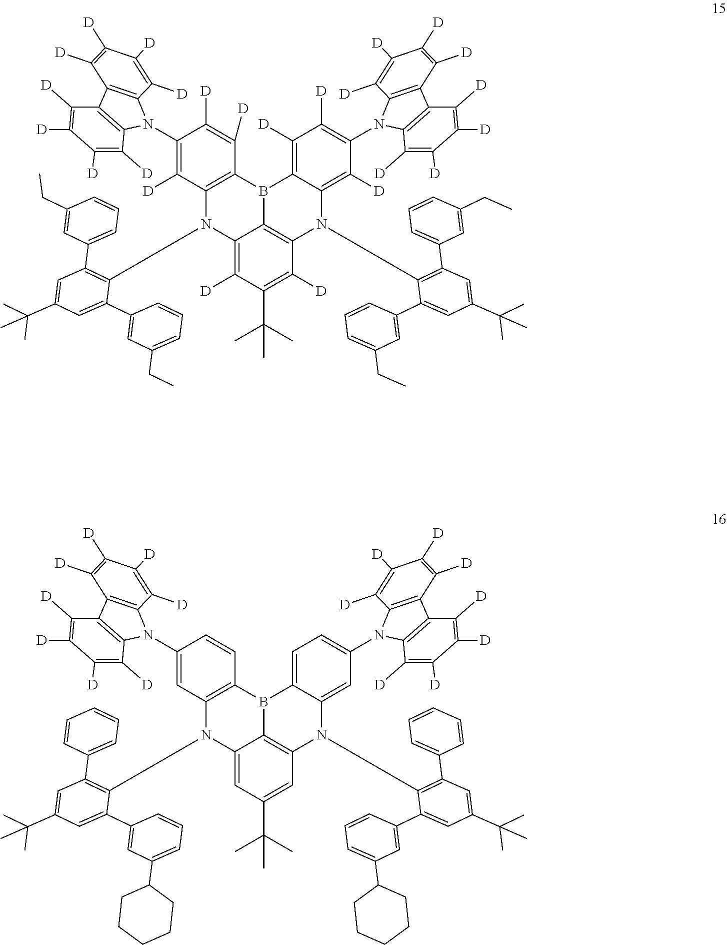 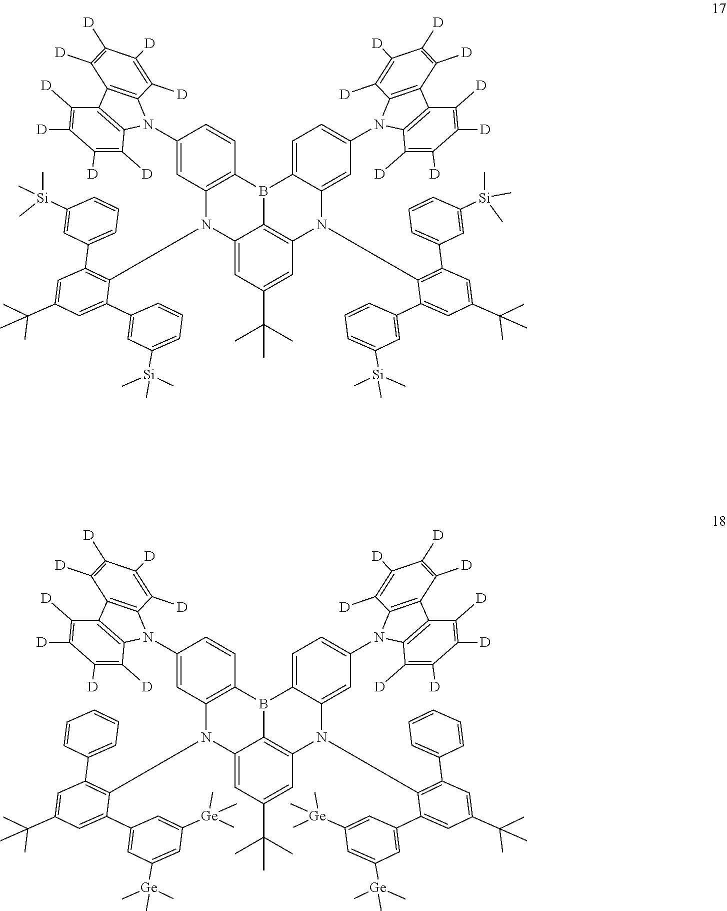 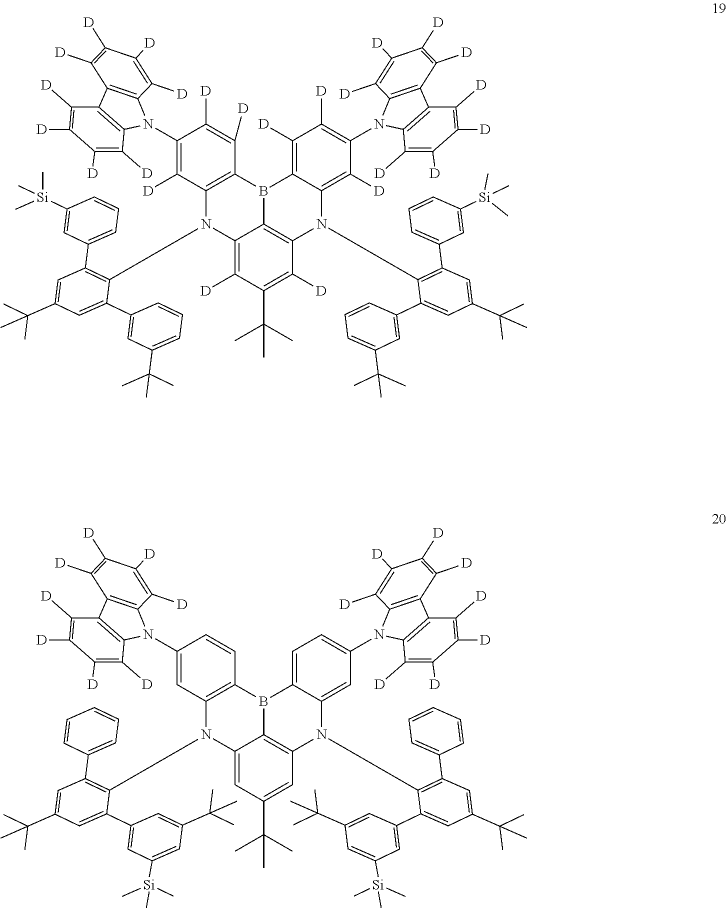 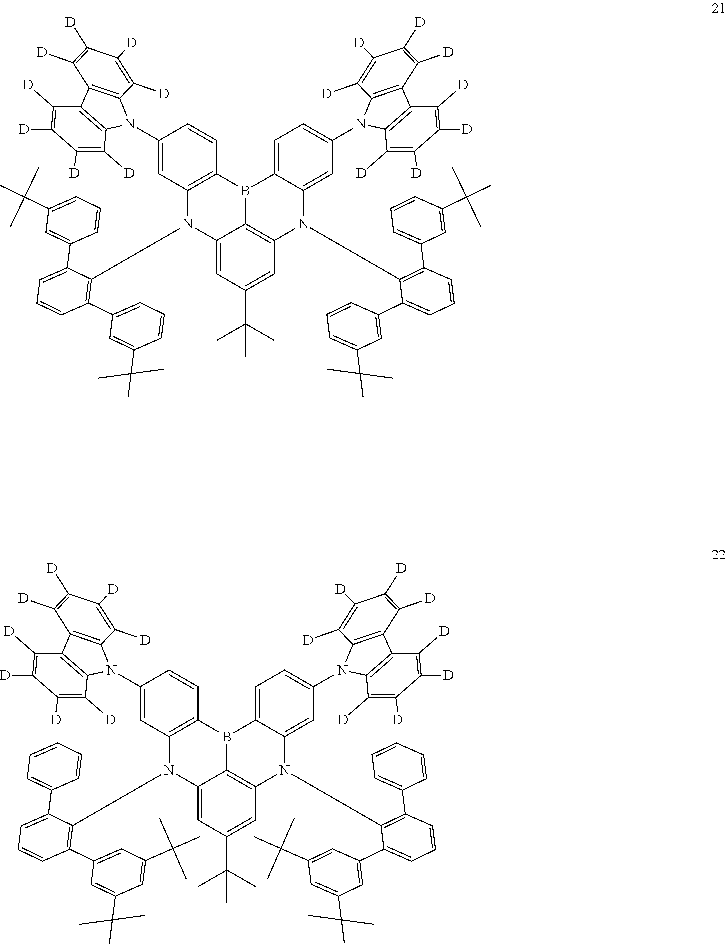 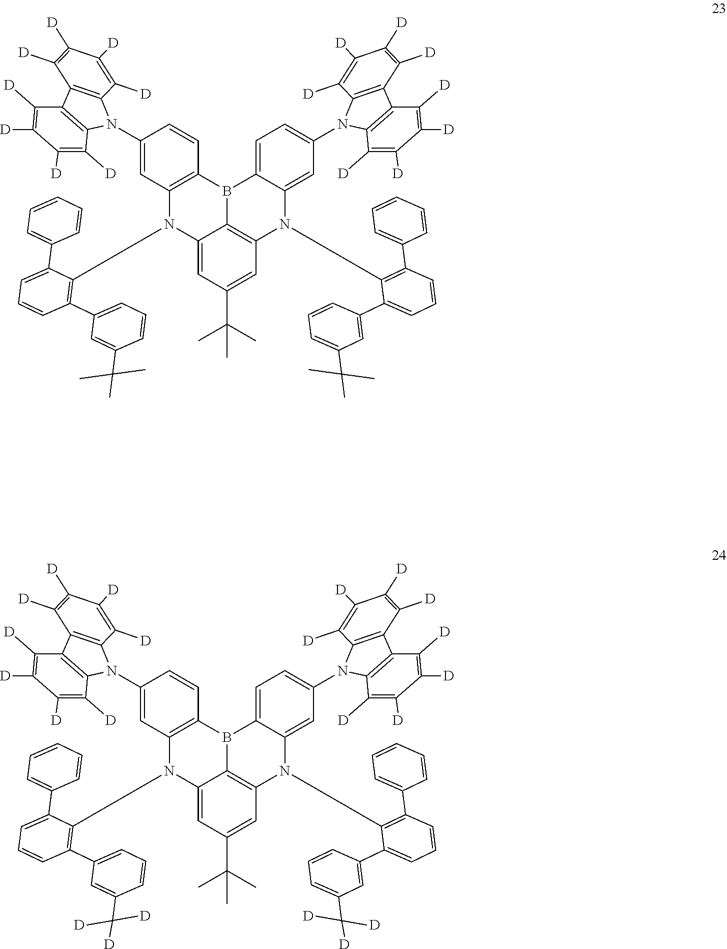 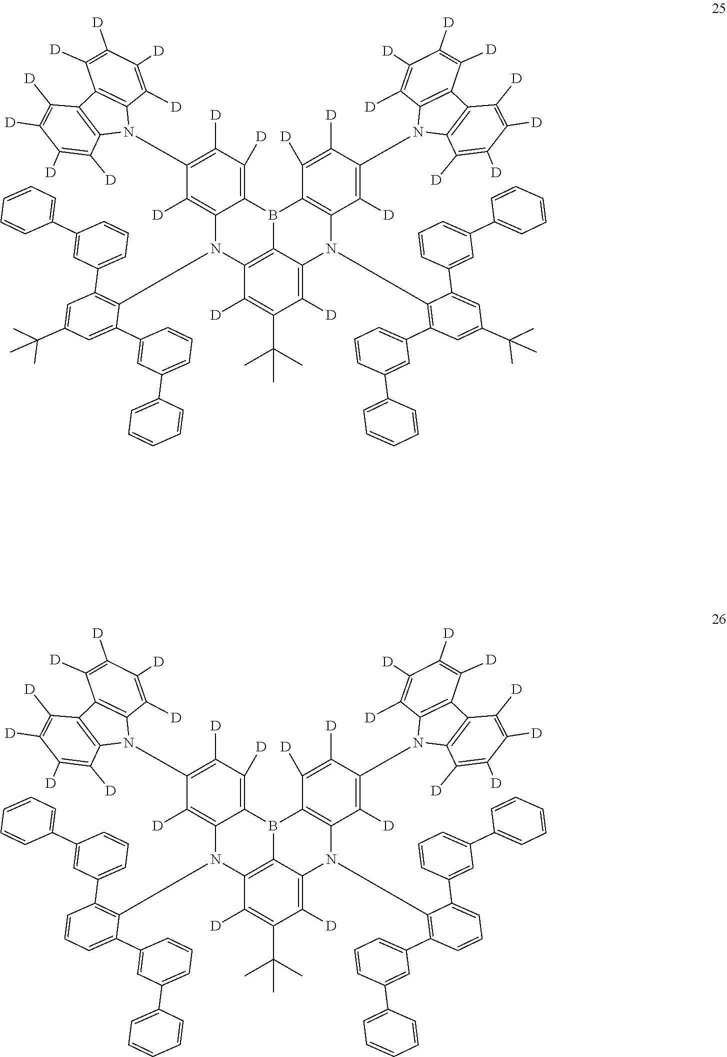 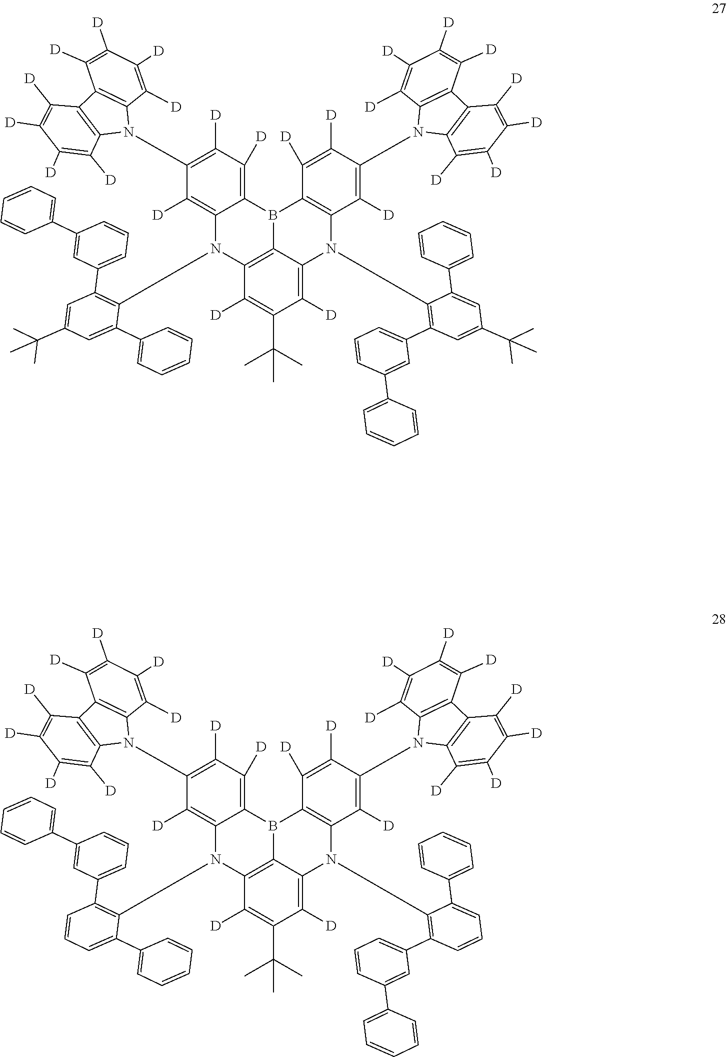 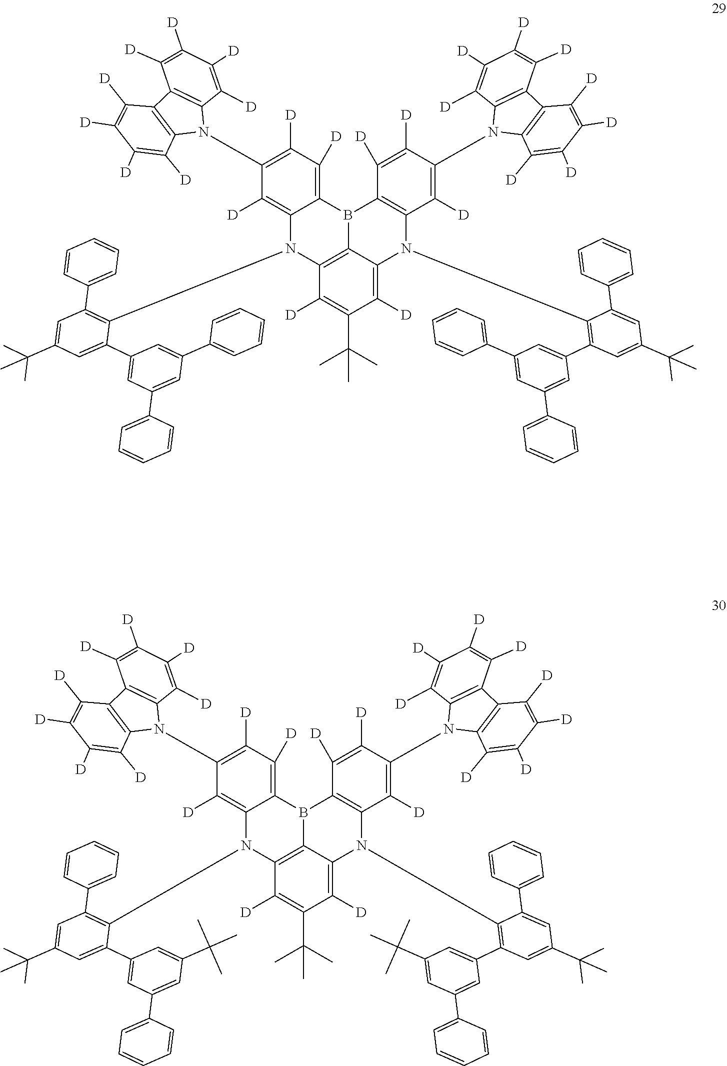 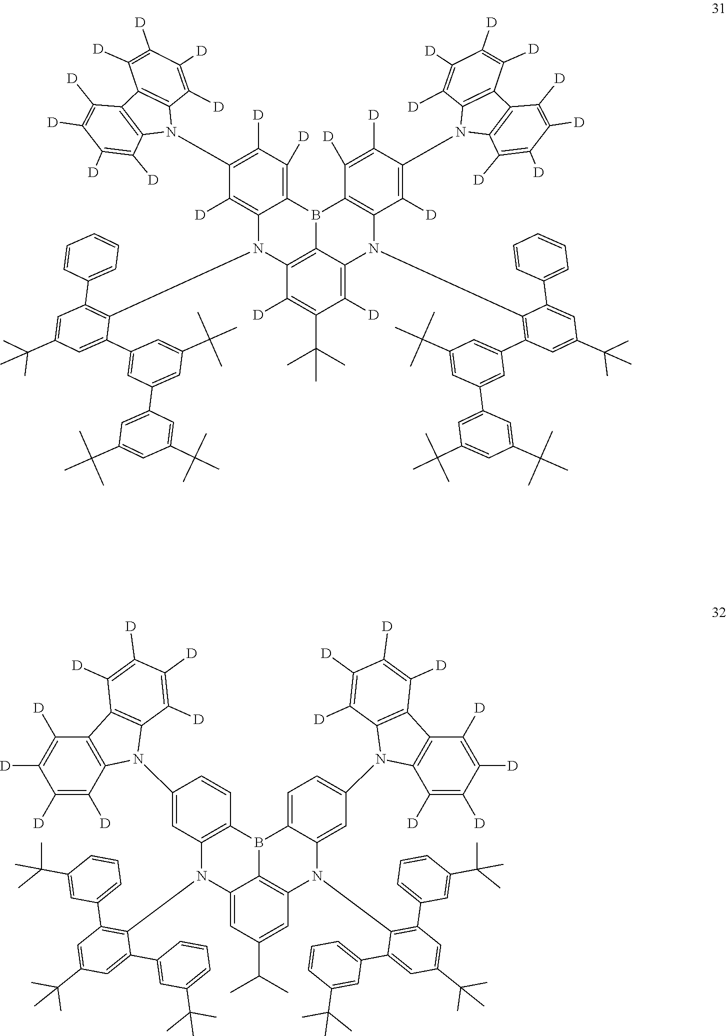 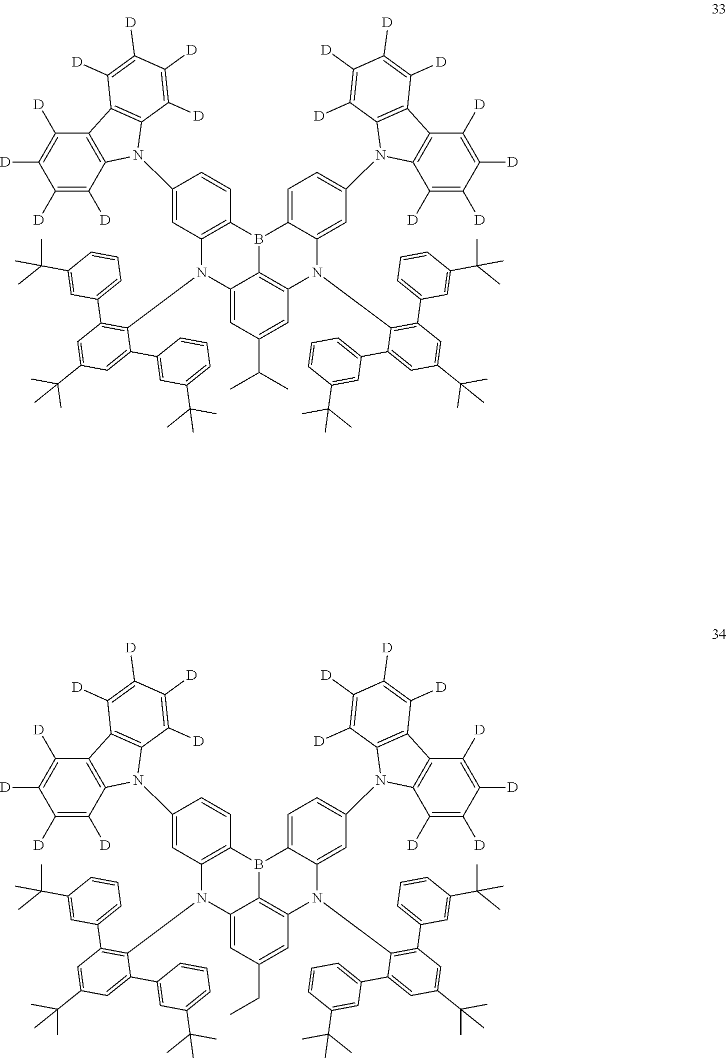 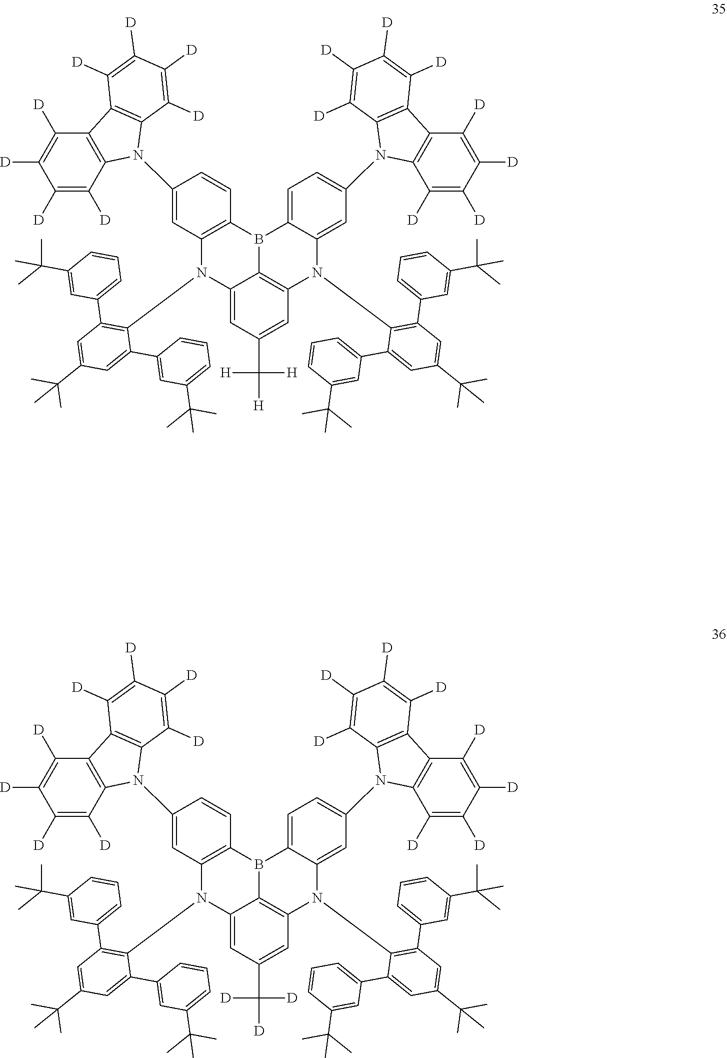 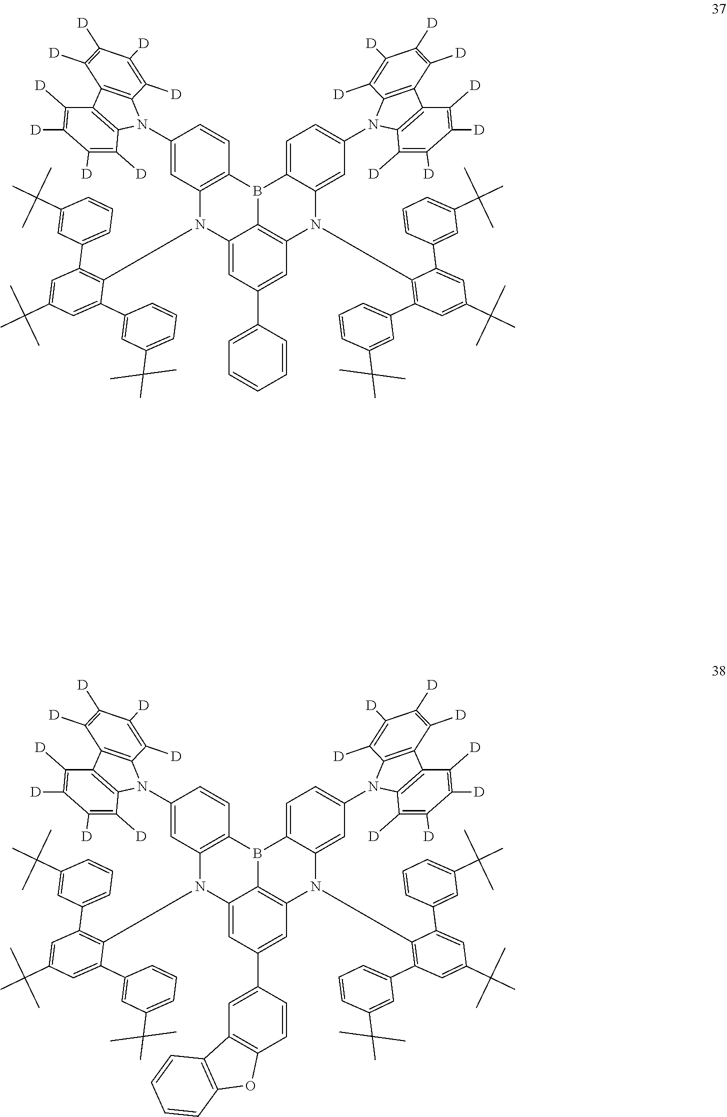 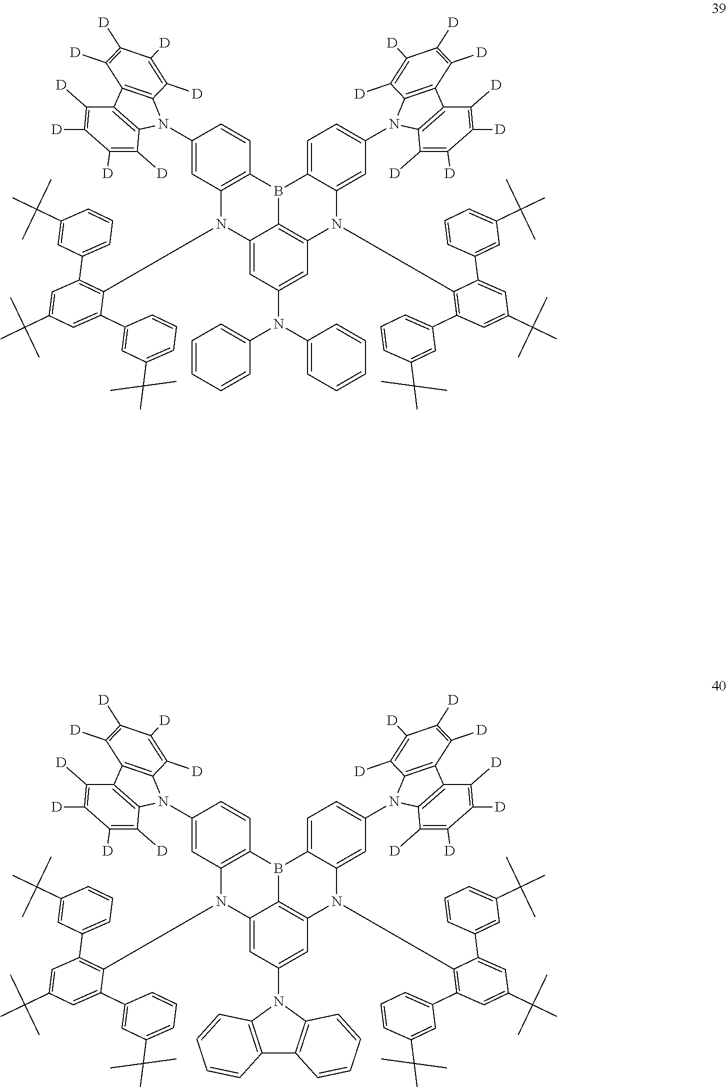 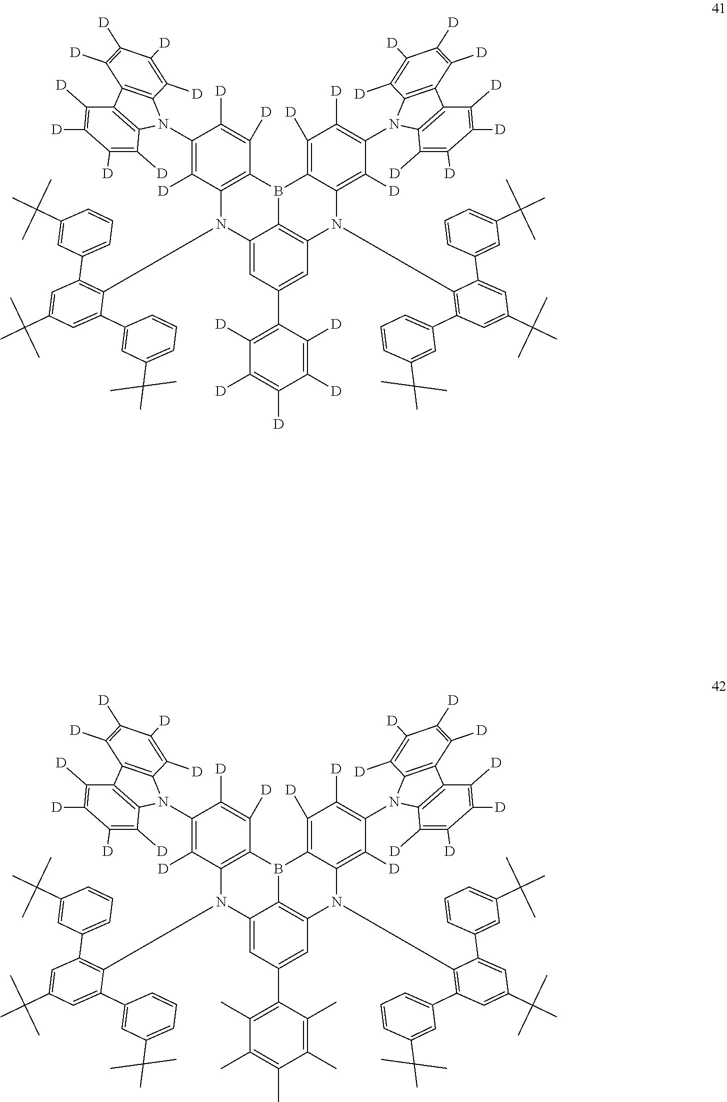 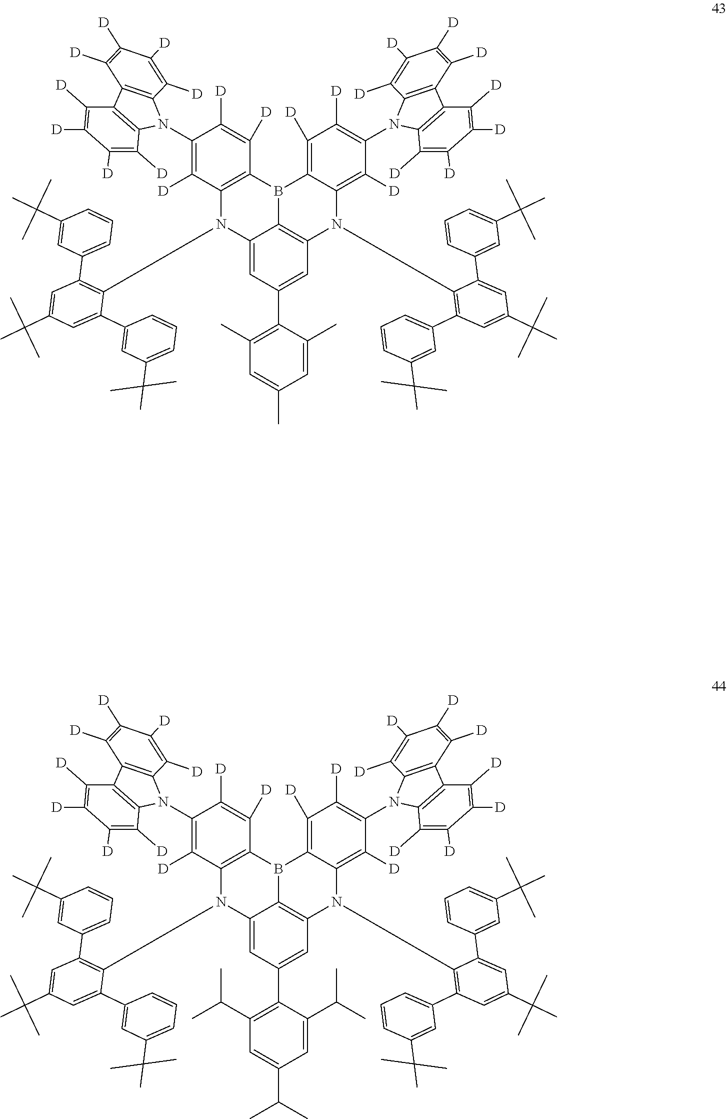 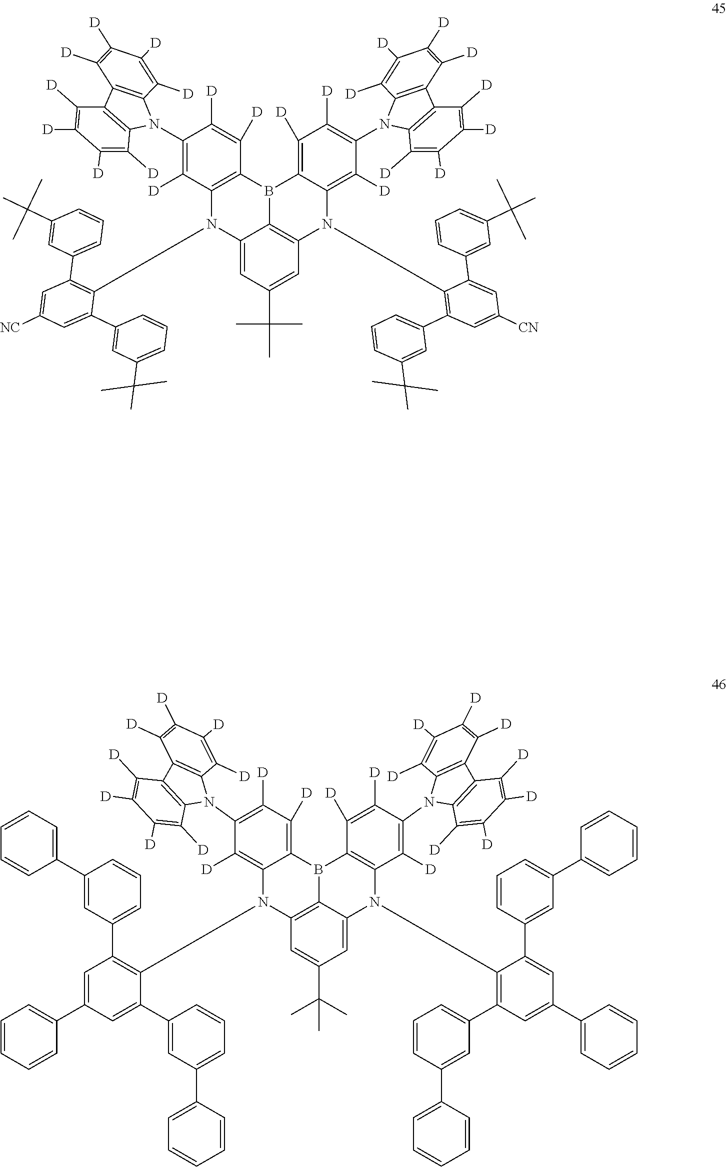 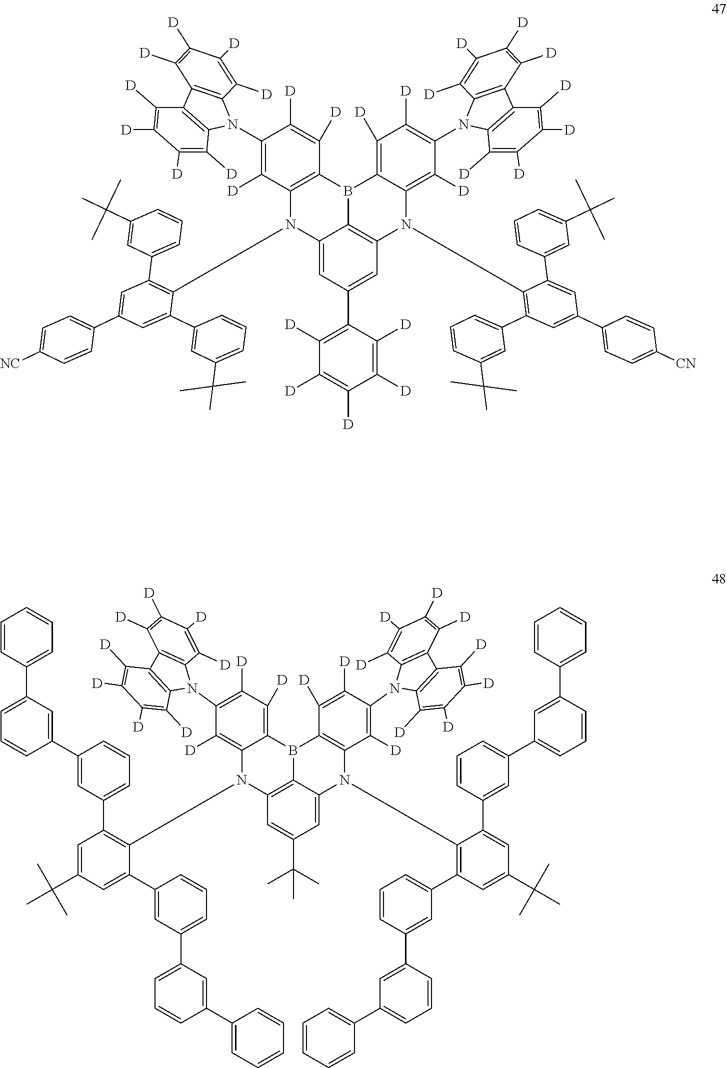 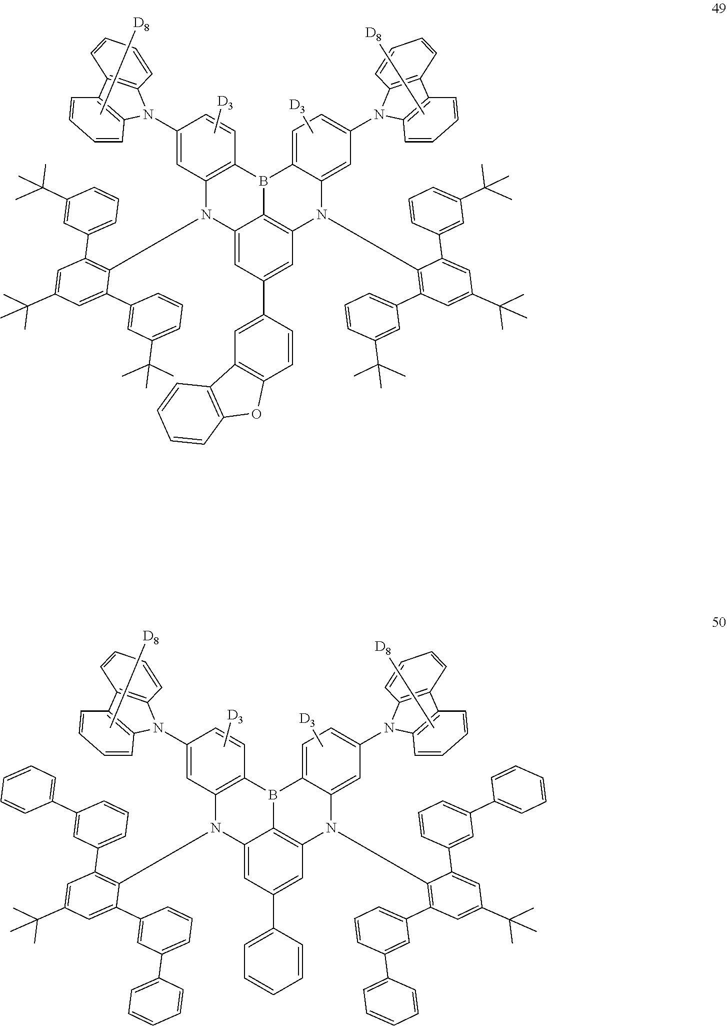
wherein in Compound Group 1,
D is a deuterium atom.

13. A fused polycyclic compound represented by Formula 1: 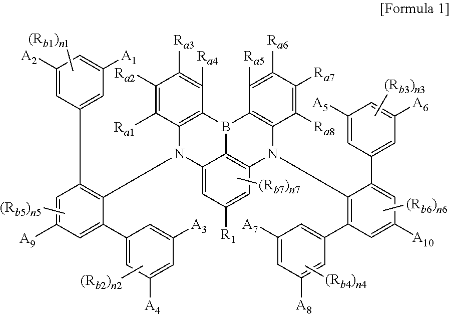
wherein in Formula 1,
at least one of Rₐ₁ to Rₐ₈ is each independently a group represented by Formula 2,
the remainder of Rₐ₁ to Rₐ₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 60 carbon atoms, a substituted or unsubstituted alkenyl group having 2 to 60 carbon atoms, a substituted or unsubstituted aryl group having 6 to 60 ring-forming carbon atoms, or a substituted or unsubstituted heteroaryl group having 2 to 60 ring-forming carbon atoms,
at least one of A₁ to A₈ is each independently a first substituent,
the remainder of A₁ to A₈ are each independently a hydrogen atom or a deuterium atom,
the first substituent is a substituted or unsubstituted germanium group, a substituted or unsubstituted silyl group, a substituted or unsubstituted alkyl group having 1 to 60 carbon atoms, or a substituted or unsubstituted aryl group having 6 to 60 ring-forming carbon atoms,
A₉ and A₁₀ are each independently a hydrogen atom, a deuterium atom, a cyano group, a substituted or unsubstituted alkyl group having 1 to 60 carbon atoms, or a substituted or unsubstituted aryl group having 6 to 60 ring-forming carbon atoms,
R₁ is a hydrogen atom, a deuterium atom, a halogen atom, a cyano group, a nitro group, a hydroxyl group, a substituted or unsubstituted silyl group, a substituted or unsubstituted amine group, a substituted or unsubstituted alkoxy group, a substituted or unsubstituted alklythio group, a substituted or unsubstituted alkyl group having 1 to 60 carbon atoms, a substituted or unsubstituted aryl group having 6 to 60 ring-forming carbon atoms, or a substituted or unsubstituted heteroaryl group having 2 to 60 ring-forming carbon atoms, or is bonded to an adjacent group to form a ring,
n1 to n4 are each independently an integer from 0 to 3,
n5 to n7 are each independently an integer from 0 to 2, and
R_{b1} to R_{b7} are each independently a hydrogen atom or a deuterium atom; 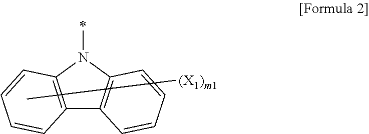
wherein in Formula 2,
m1 is an integer from 0 to 8, and
X₁ is a hydrogen atom, a deuterium atom, a cyano group, or a substituted or unsubstituted alkyl group having 1 to 60 carbon atoms.

14. The fused polycyclic compound of claim 13, wherein Formula 1 is represented by Formula 1-A1 or Formula 1-A2: 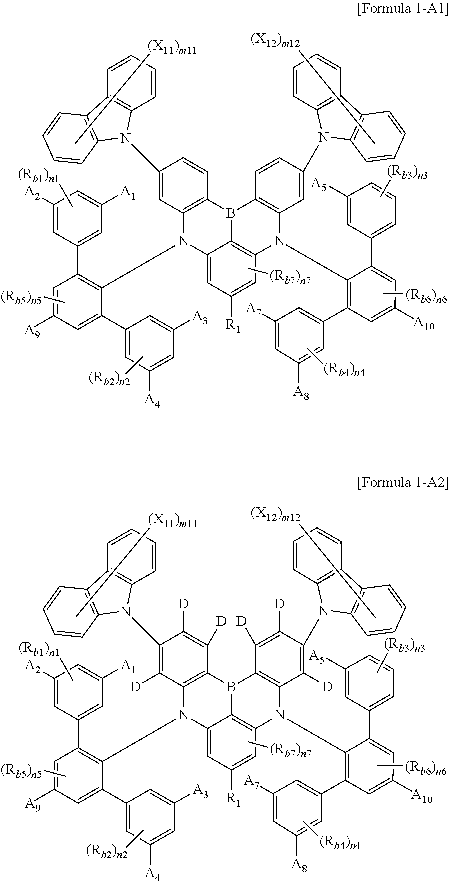
wherein in Formula 1-A1 and Formula 1-A2,
m11 and m12 are each independently an integer from 0 to 8,
X₁₁ and X₁₂ are each independently a hydrogen atom, a deuterium atom, a cyano group, or a substituted or unsubstituted alkyl group having 1 to 60 carbon atoms, and
A₁ to A₁₀, R₁, n1 to n7, and R_{b1} to R_{b7} are the same as defined in Formula 1.

15. The fused polycyclic compound of claim 13, wherein Formula 1 is represented by Formula 1-B: 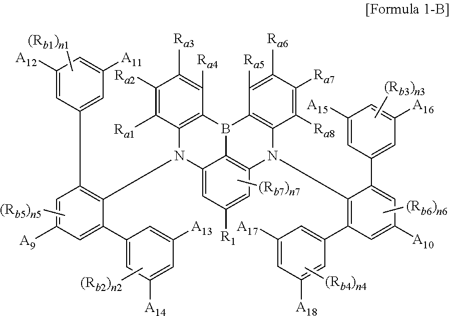
wherein in Formula 1-B,
A₁₄ and A₁₈ are each independently a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms,
A₁₁ to A₁₃ and A₁₈ to A₁₇ are each independently a hydrogen atom, a deuterium atom, a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and
Rₐ₁ to Rₐ₈, A₉, A₁₀, R₁, n1 to n7, and R_{b1} to R_{b7} are the same as defined in Formula 1.

16. The fused polycyclic compound of claim 15, wherein Formula 1-B is represented by one of Formula 1-B1 to Formula 1-B3: 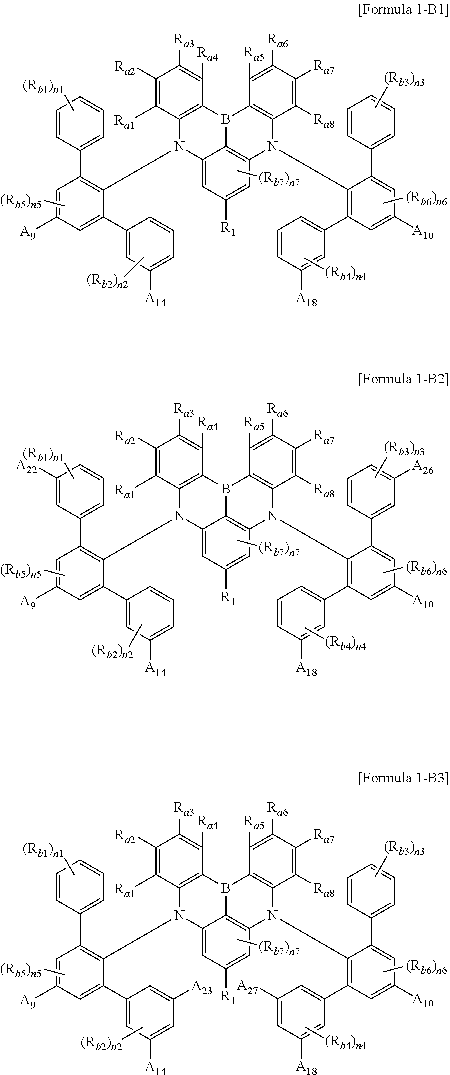
wherein in Formula 1-B2 and Formula 1-B3,
A₂₂, A₂₃, A₂₆, and A₂₇ are each independently a substituted or unsubstituted germanium group, a substituted or unsubstituted silyl group, a substituted or unsubstituted alkyl group having 1 to 10 carbon atoms, or a substituted or unsubstituted aryl group having 6 to 20 ring-forming carbon atoms, and
wherein in Formula 1-B1 to Formula 1-B3,
Rₐ₁ to Rₐ₈, A₉, A₁₀, A₁₄, A₁₈, R₁, n1 to n7, and R_{b1} to R_{b7} are the same as defined in Formula 1-B.

17. The fused polycyclic compound of claim 13, wherein the first substituent is a substituted or unsubstituted trimethylgermanium group, a substituted or unsubstituted trimethylsilyl group, a substituted or unsubstituted ethyl group, a substituted or unsubstituted isopropyl group, a substituted or unsubstituted propyl group, a substituted or unsubstituted t-butyl group, a substituted or unsubstituted cyclohexyl group, or a substituted or unsubstituted phenyl group.

18. The fused polycyclic compound of claim 13, wherein the first substituent is represented by one of Formula F-1 to Formula F-11: 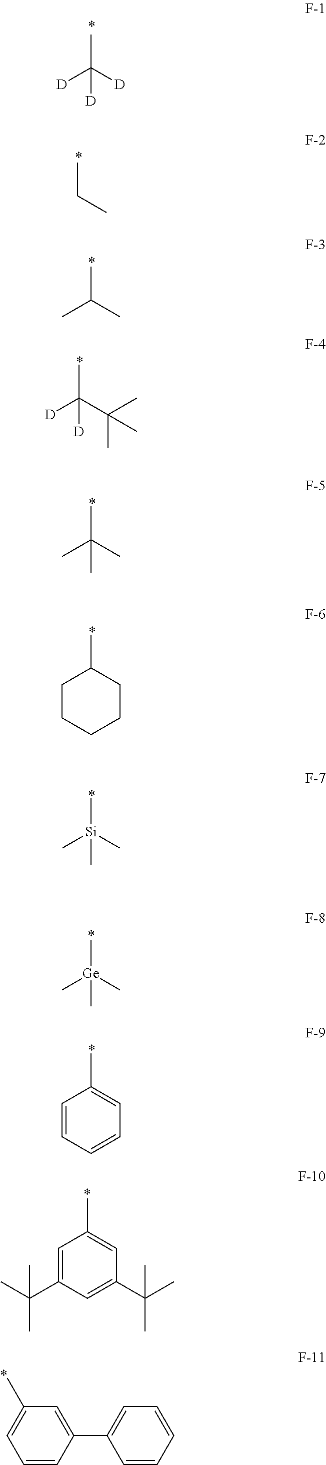
wherein in Formula F-1 and Formula F-4,
D is a deuterium atom.

19. The fused polycyclic compound of claim 13, wherein Formula 1 is represented by Formula 1-C1 or Formula 1-C2: 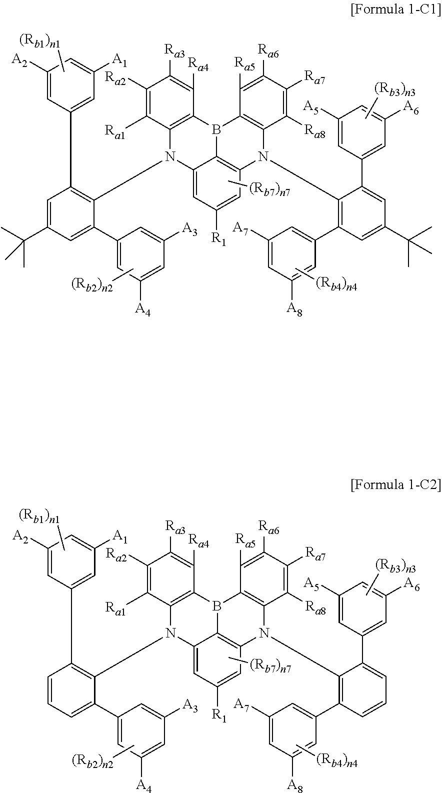
wherein in Formula 1-C1 and Formula 1-C2,
Rₐ₁ to Rₐ₈, A₁ to A₈, R₁, n1 to n4, n7, R_{b1} to R_{b4}, and R_{b7} are the same as defined in Formula 1.

20. The fused polycyclic compound of claim 13, wherein the group represented by Formula 2 is a group represented by Formula 2-1: 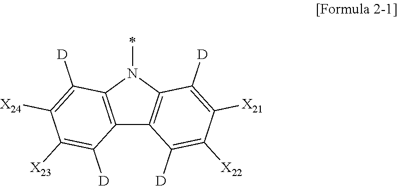
wherein in Formula 2-1,
X₂₁ to X₂₄ are each independently a deuterium atom, a cyano group, a substituted or unsubstituted methyl group, or a substituted or unsubstituted t-butyl group, and
D is a deuterium atom.

21. The fused polycyclic compound of claim 13, wherein in Formula 1, R₁ is represented by one of Formula R1-1 to Formula R1-13: 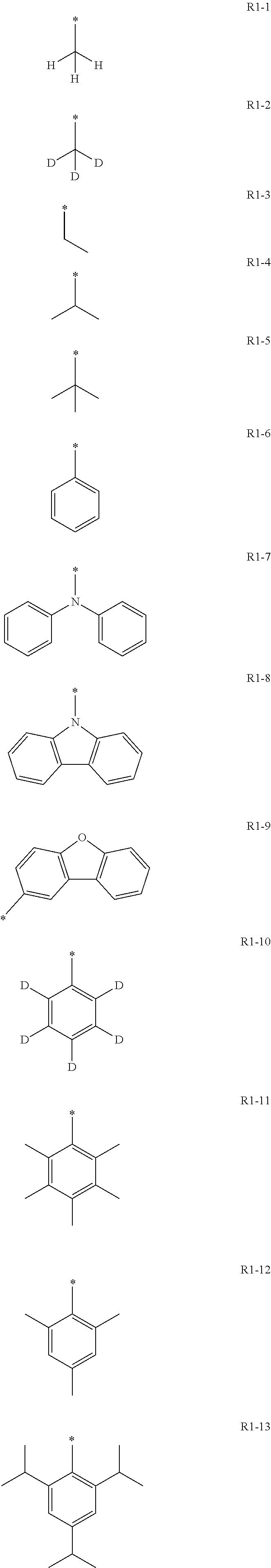
wherein in Formula R1-2 and Formula R1-10,
D is a deuterium atom.

22. The fused polycyclic compound of claim 13, wherein the fused polycyclic compound is selected from Compound Group 1: 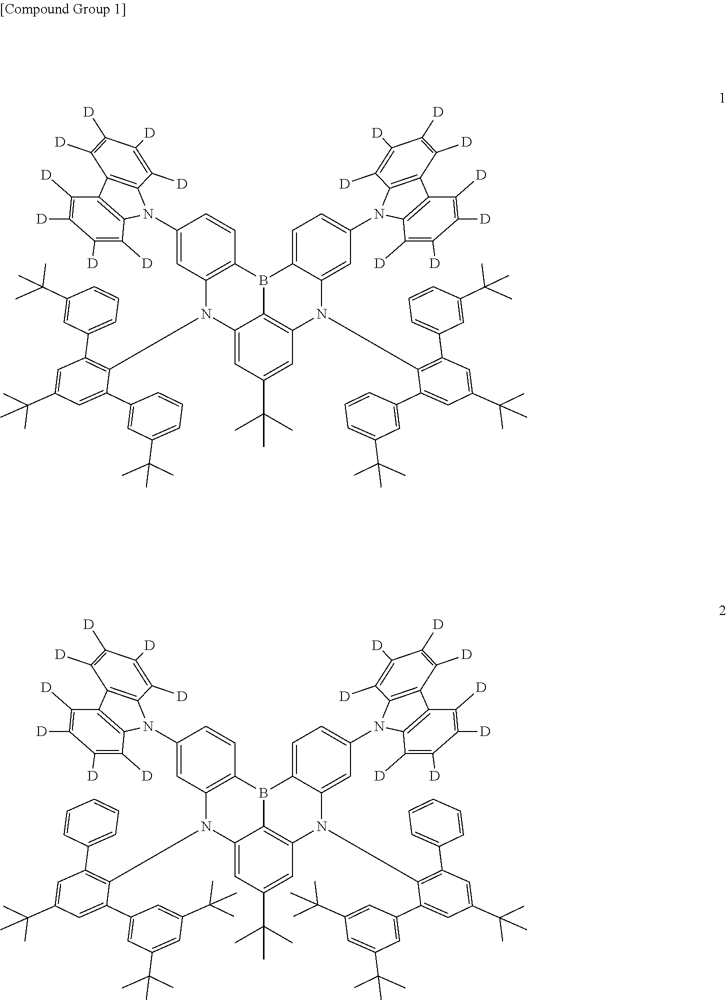 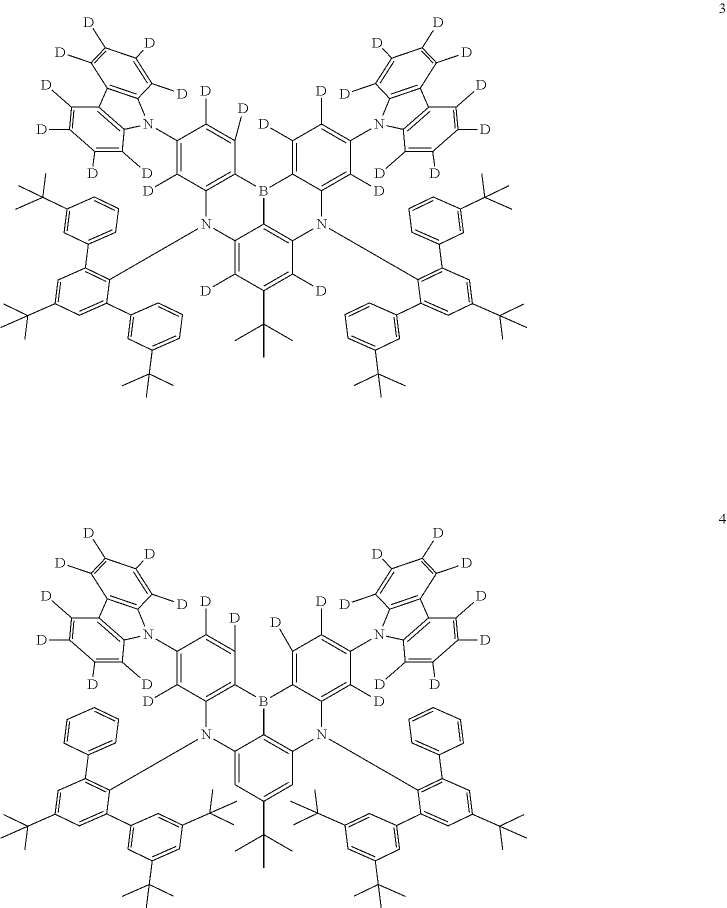 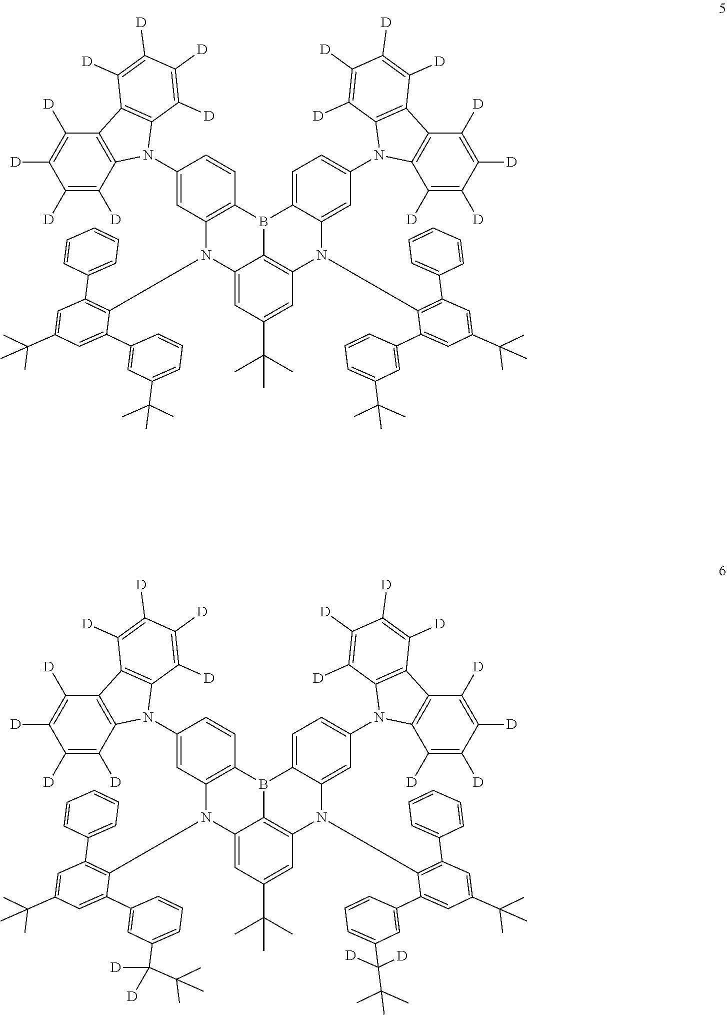 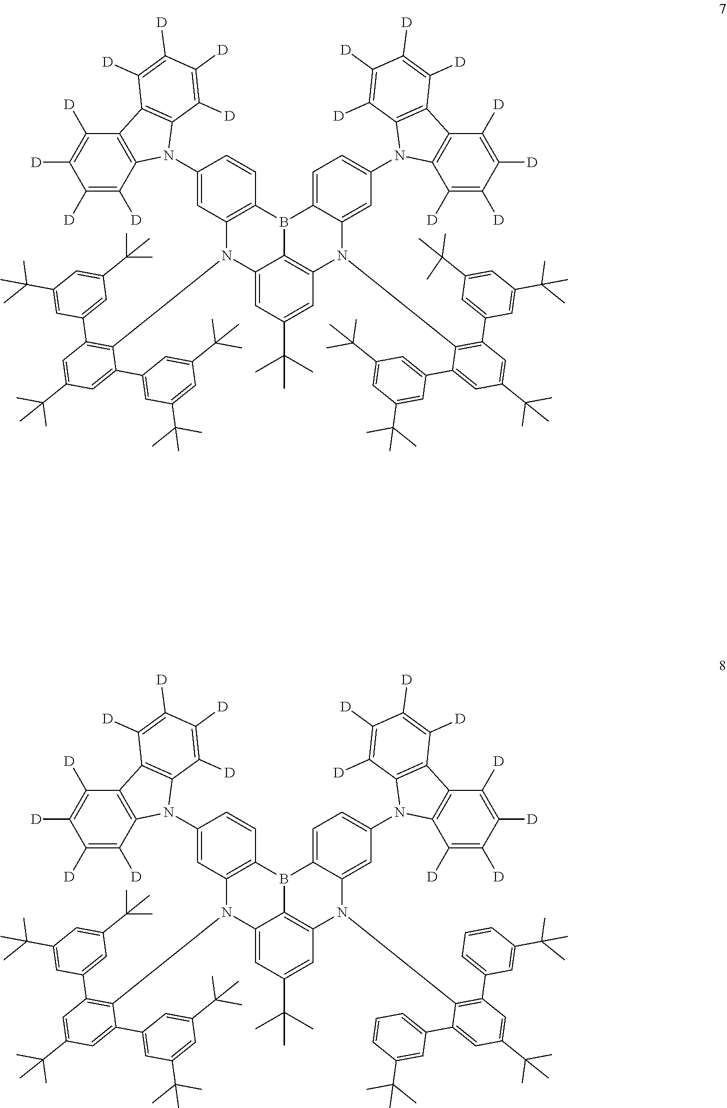 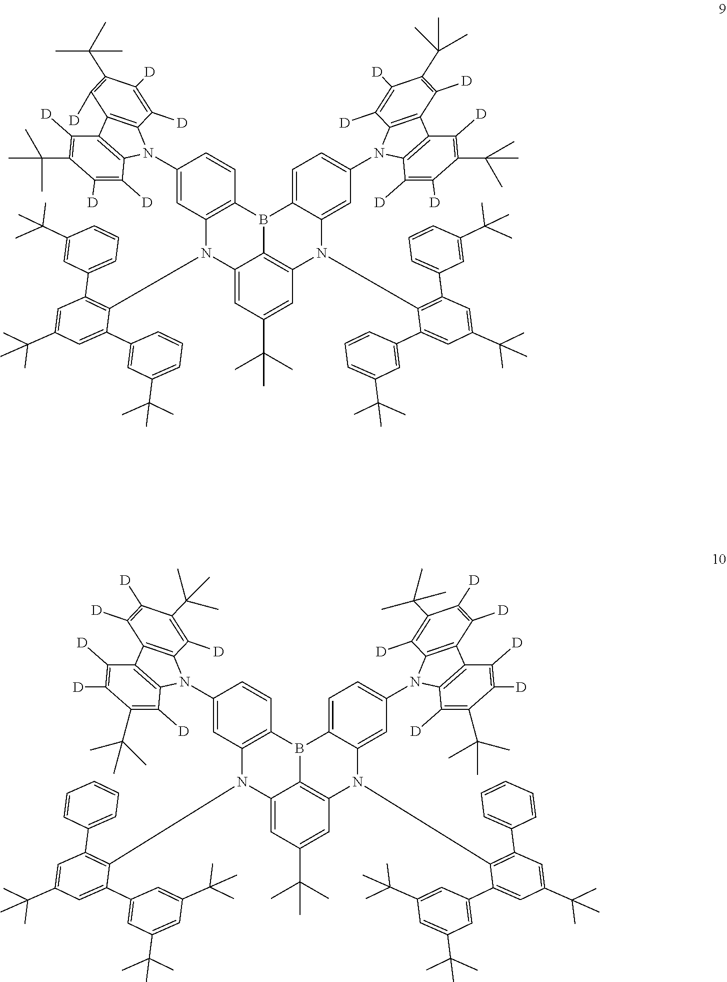 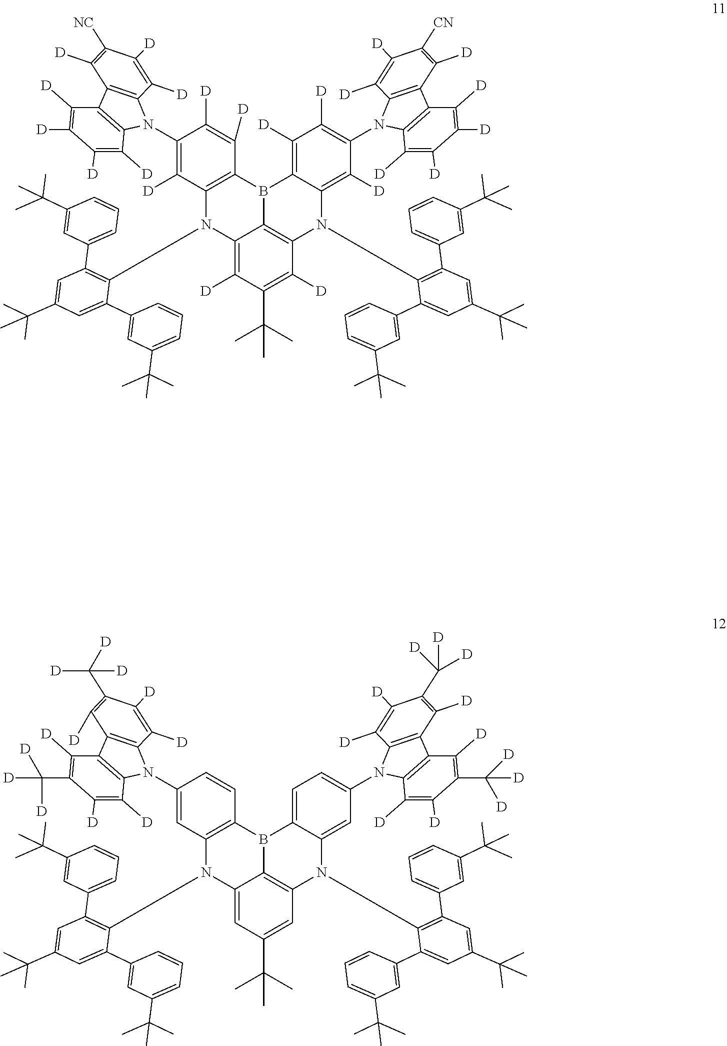 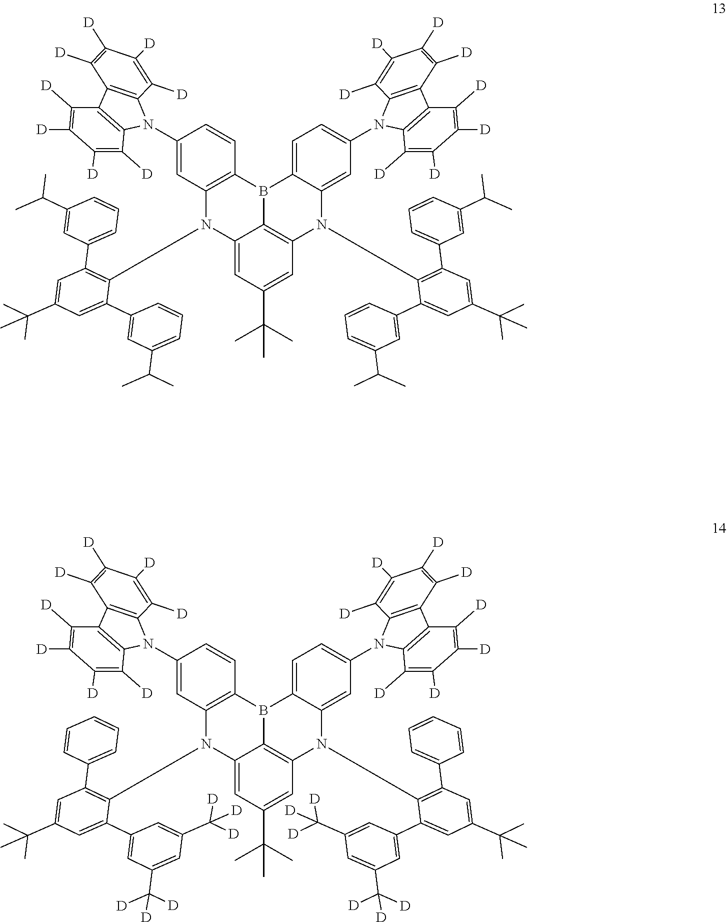 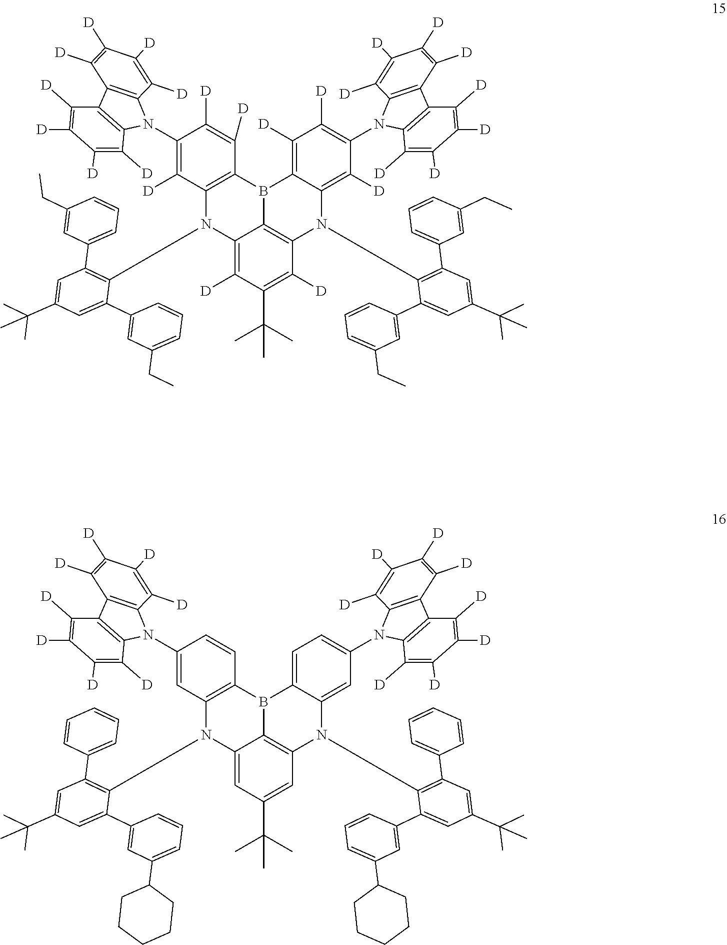 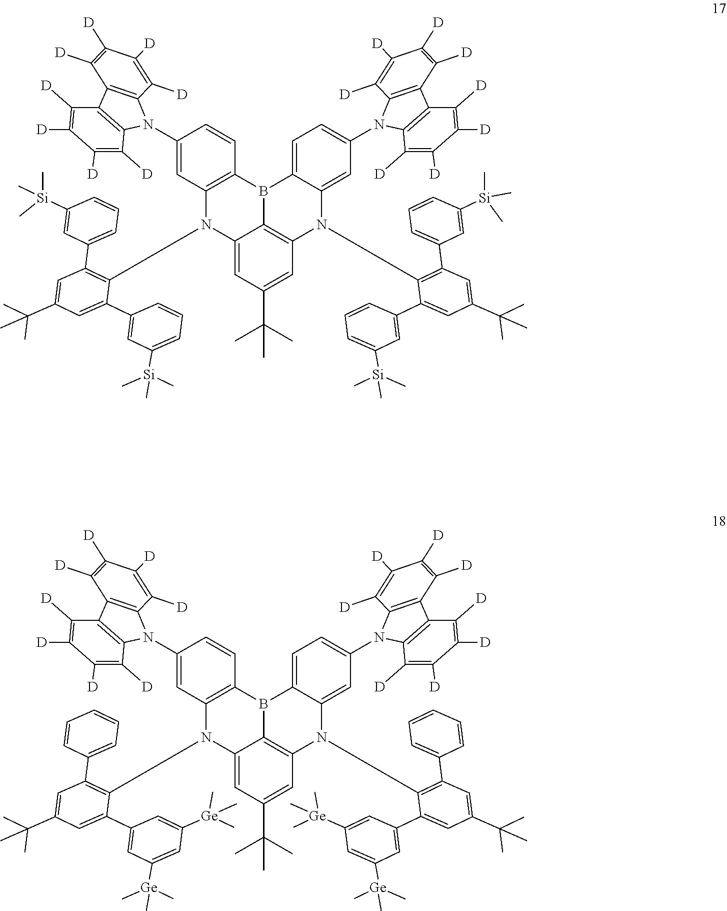 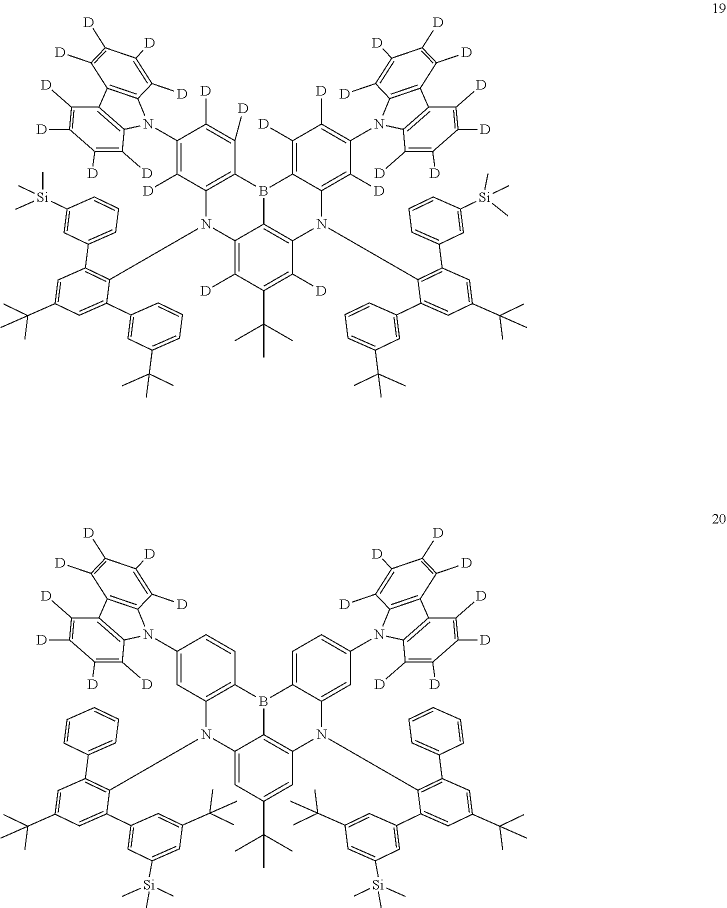 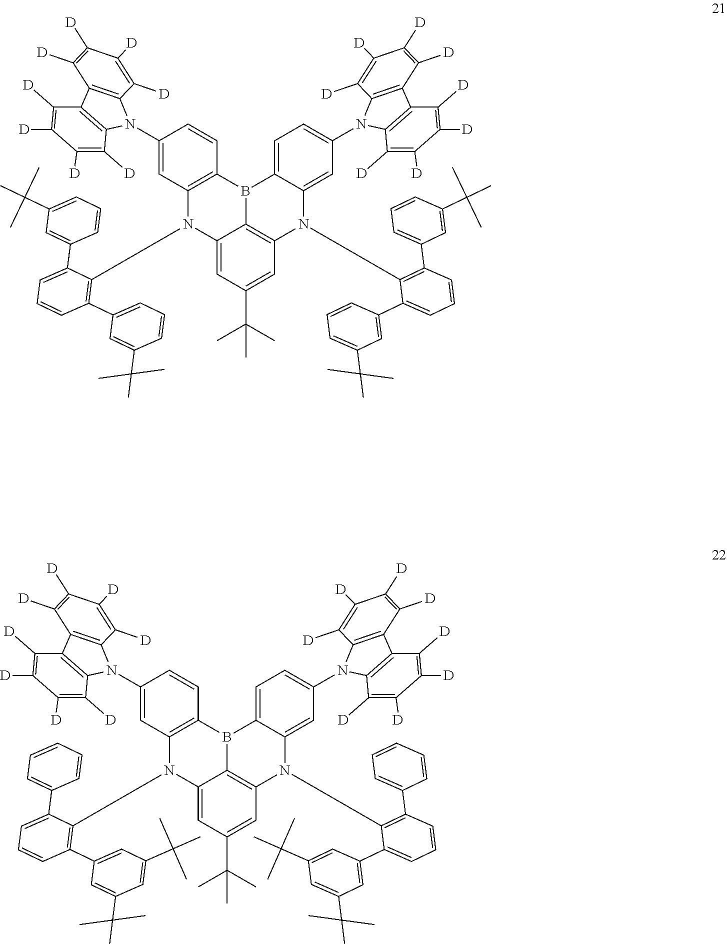 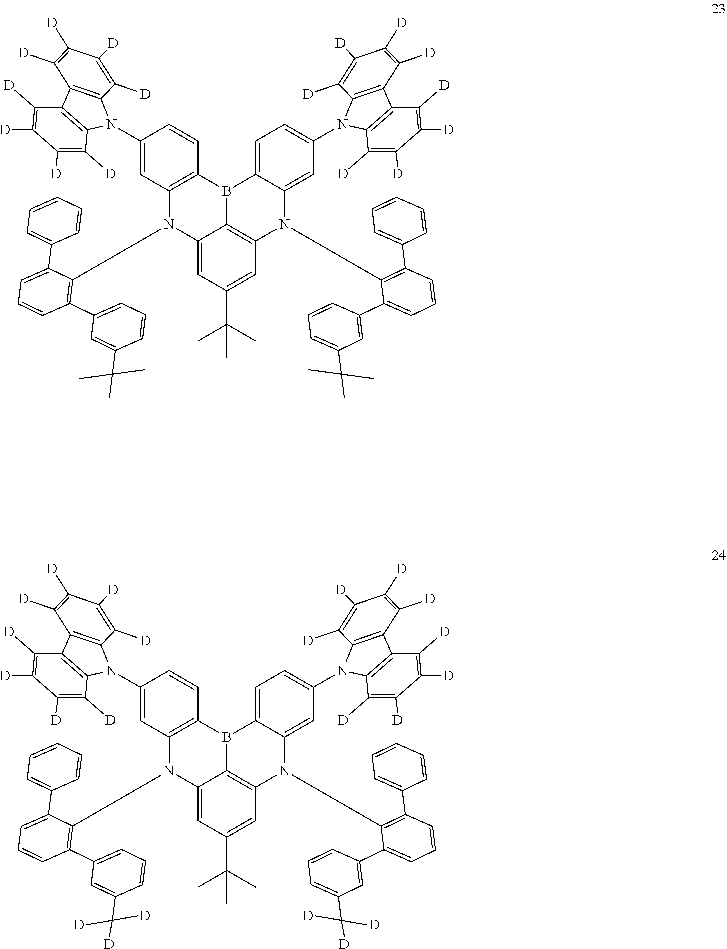 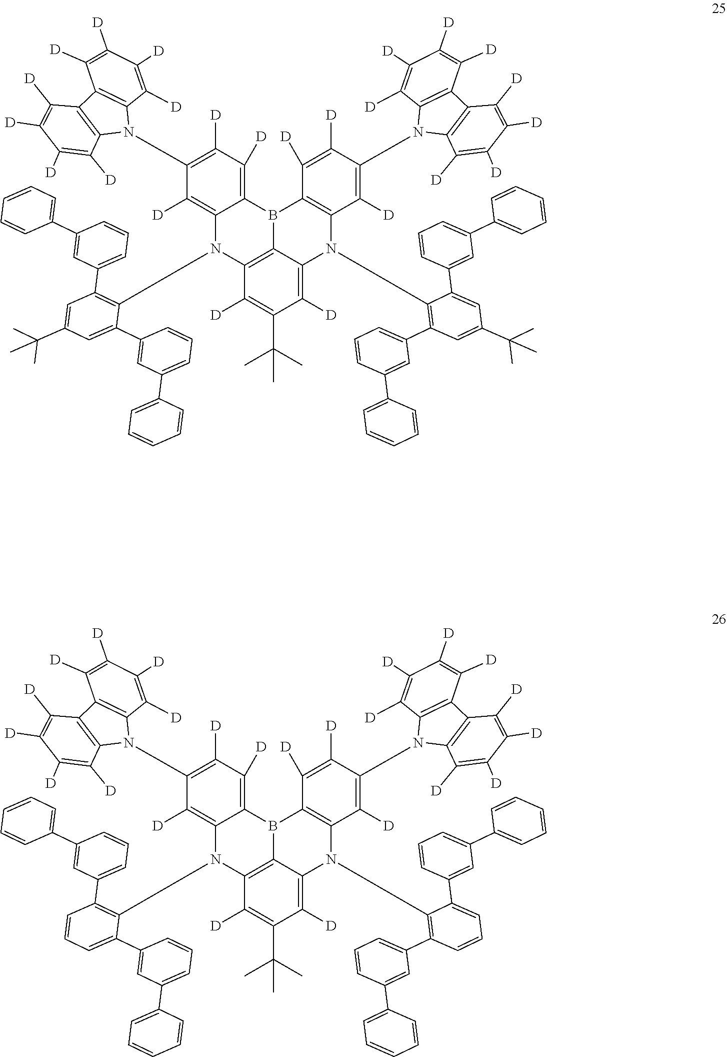 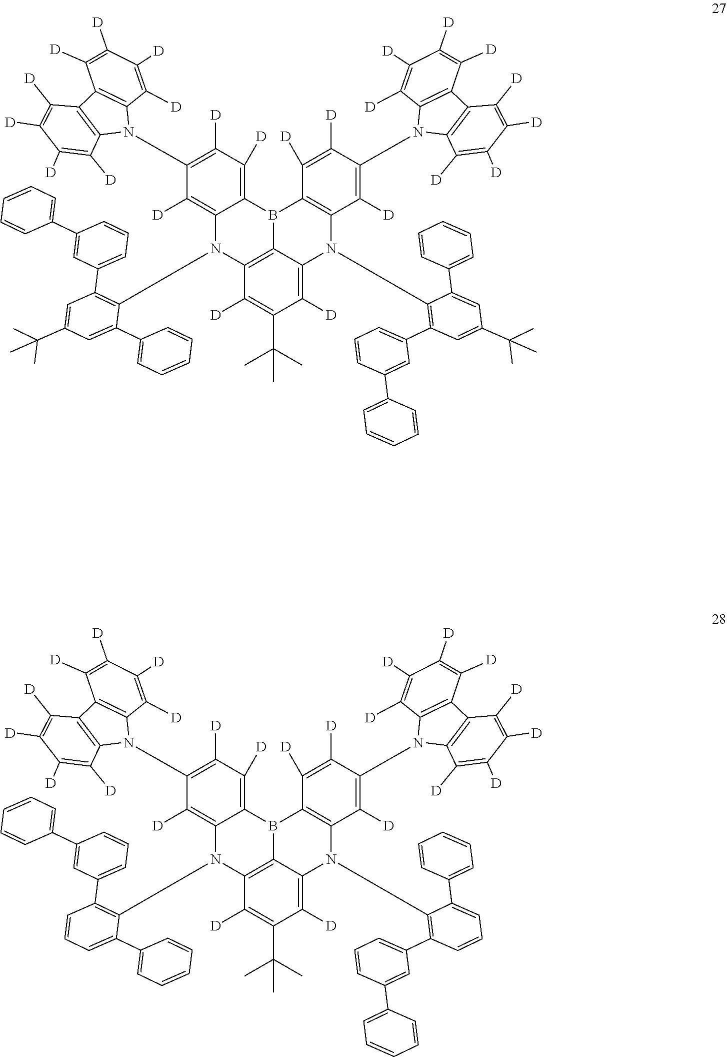 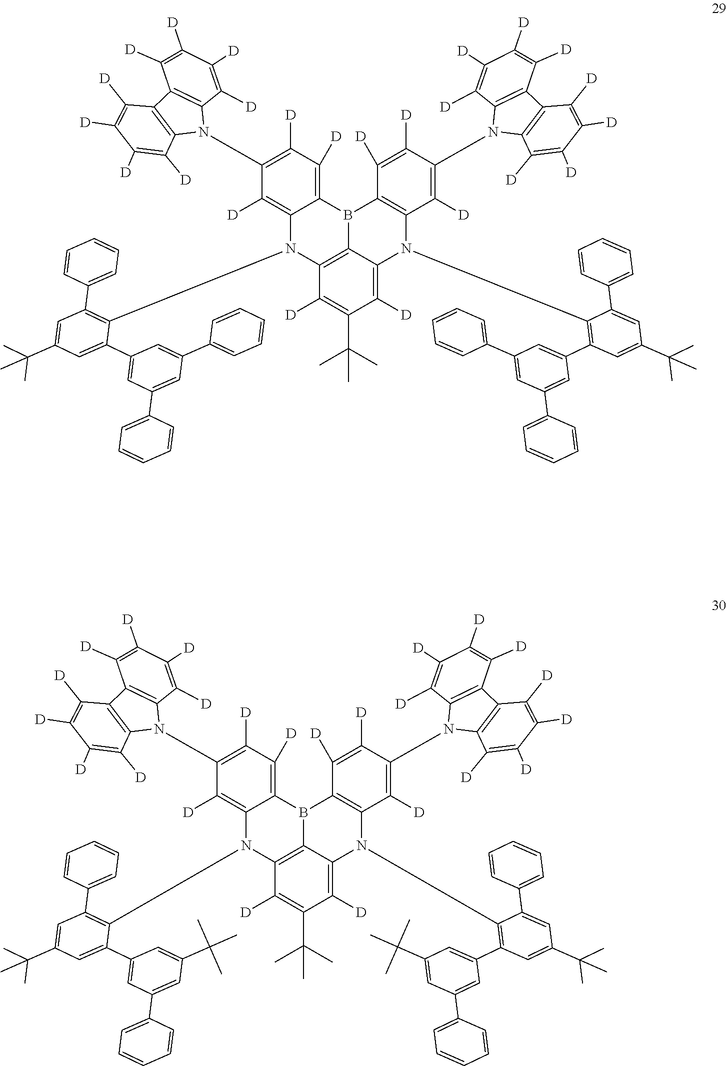 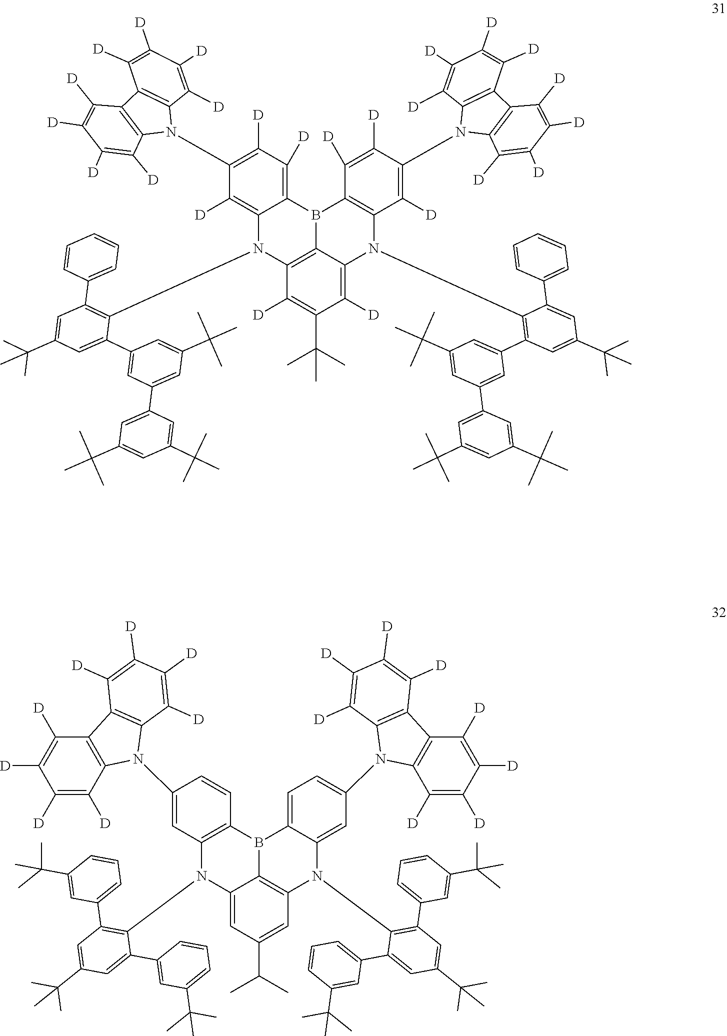 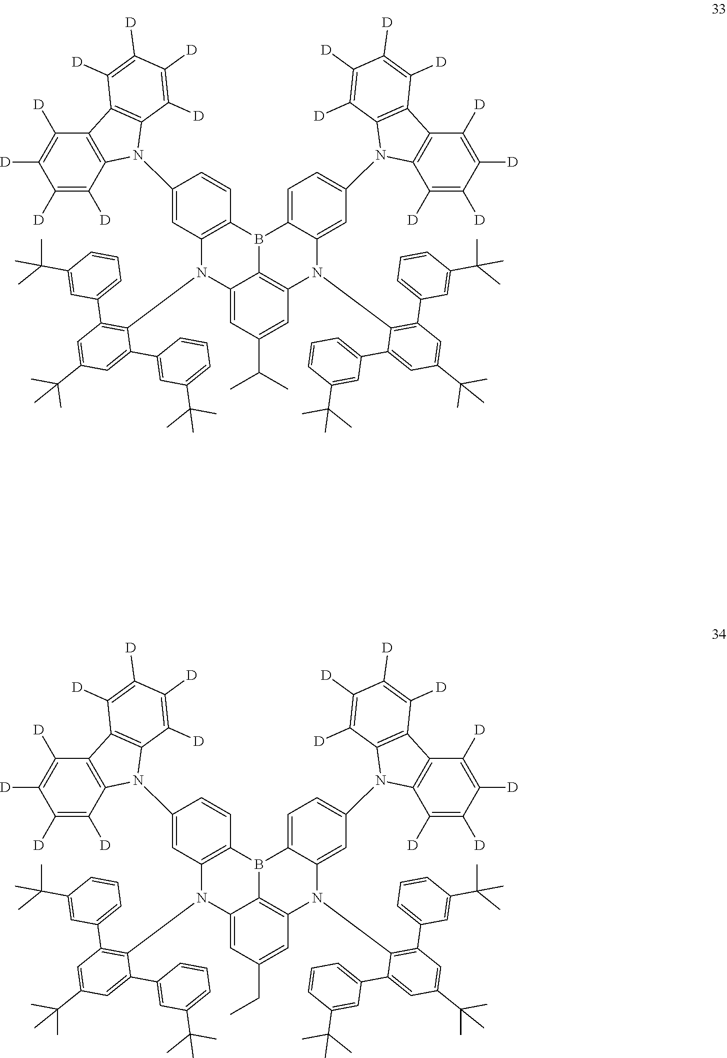 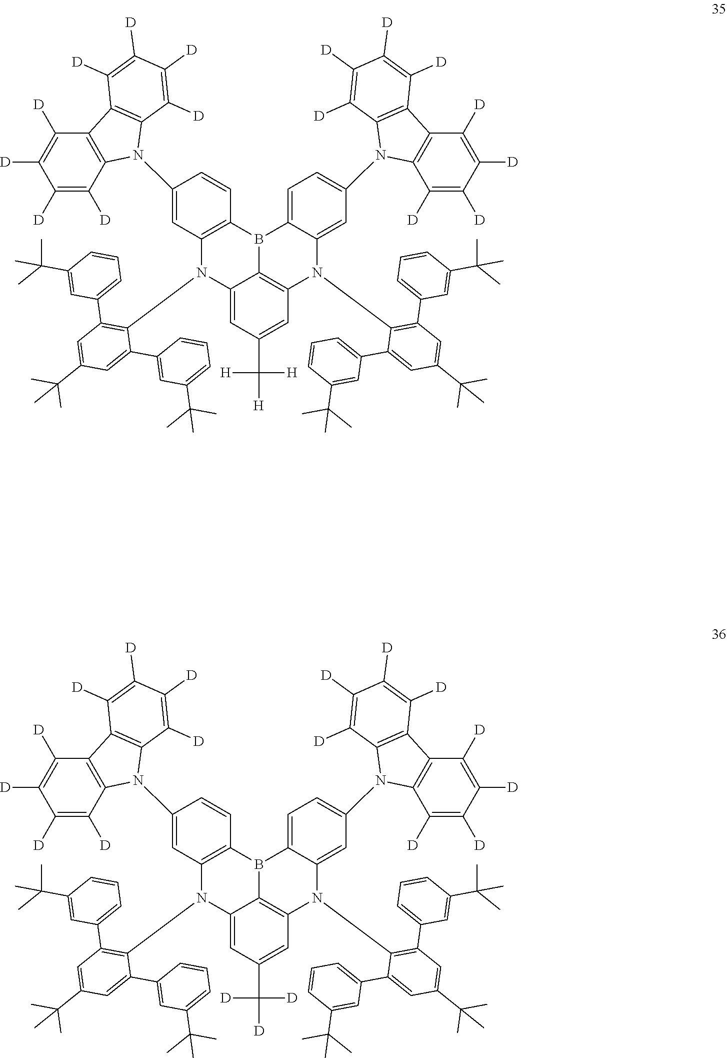 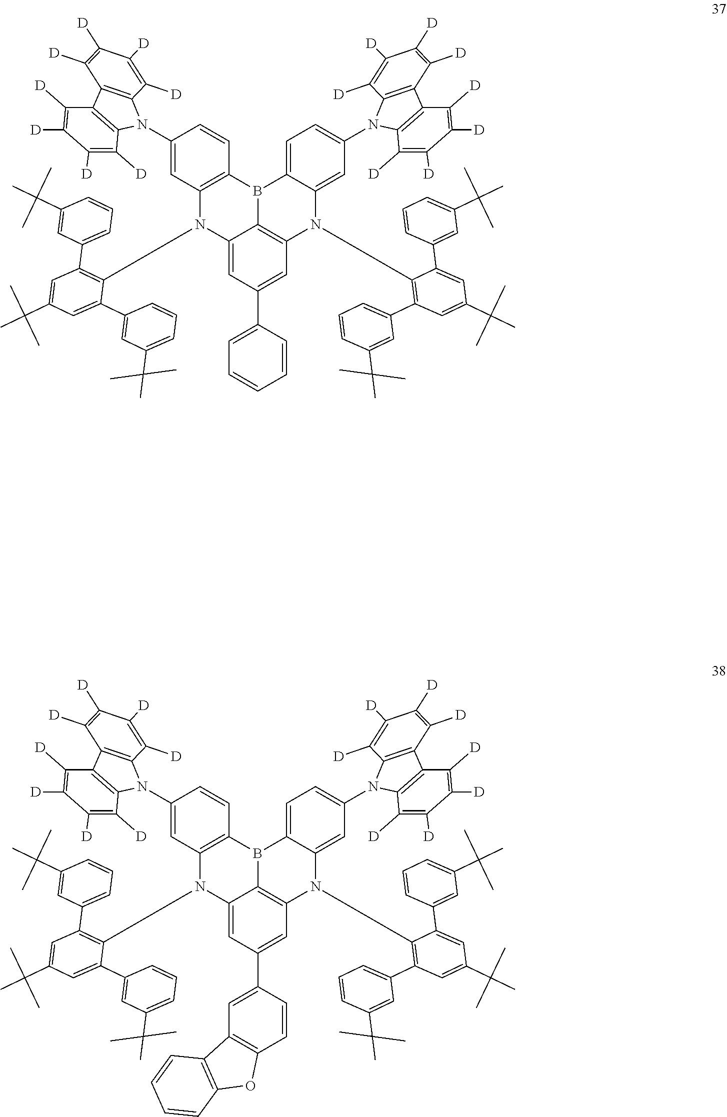 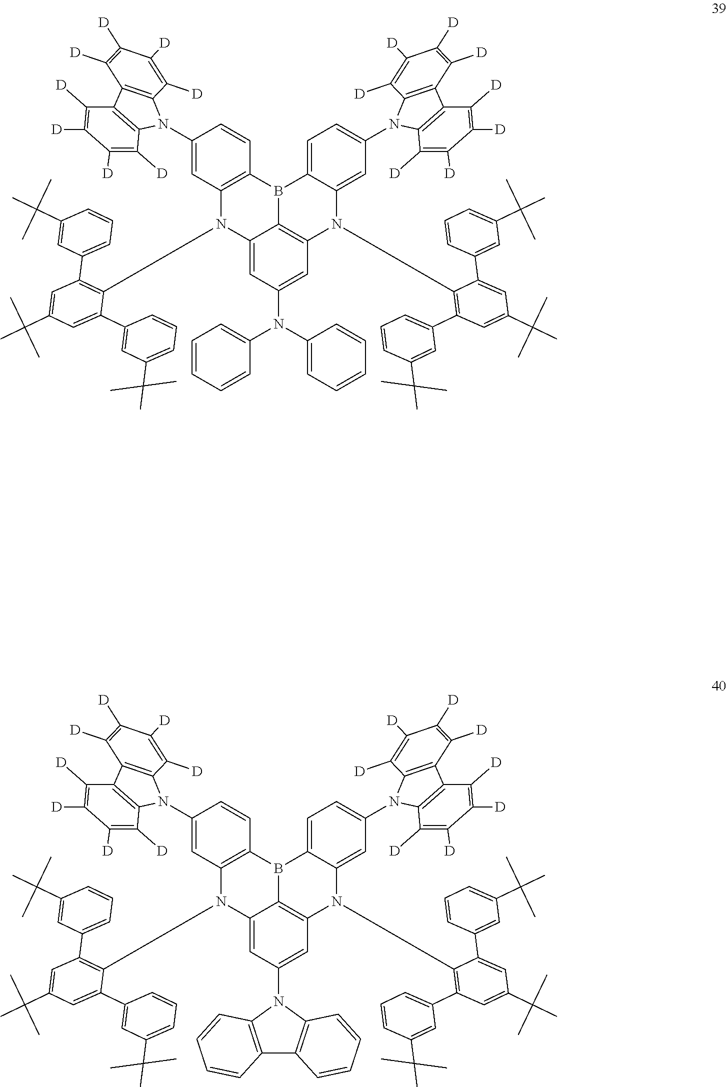 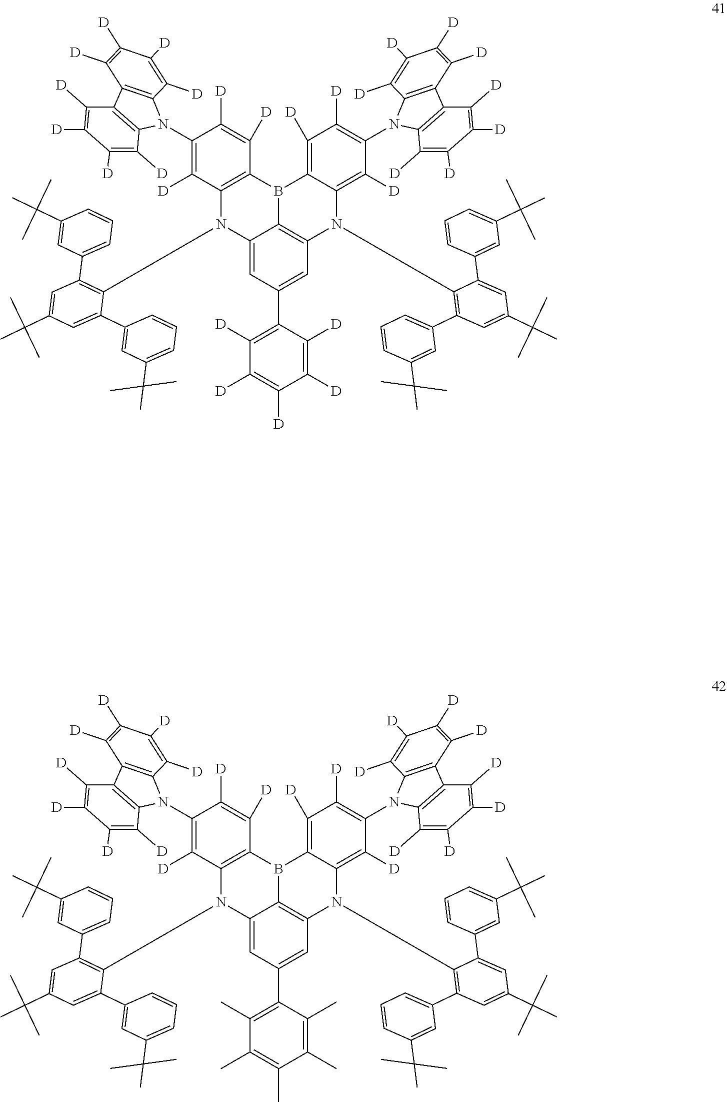 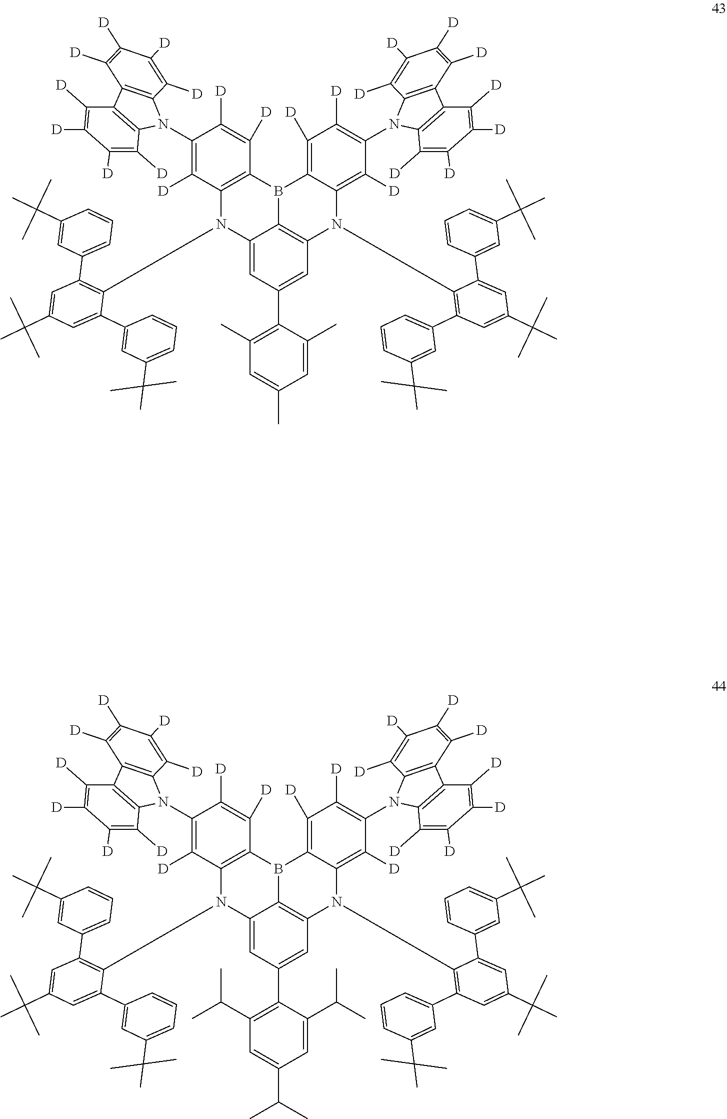 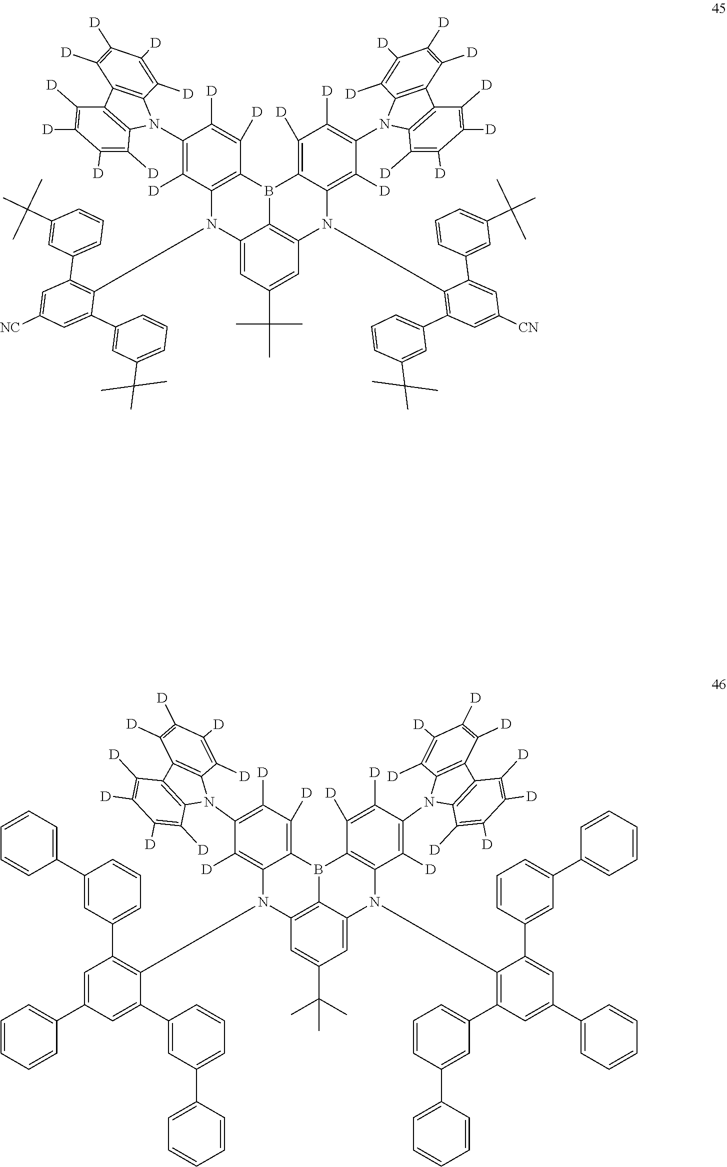 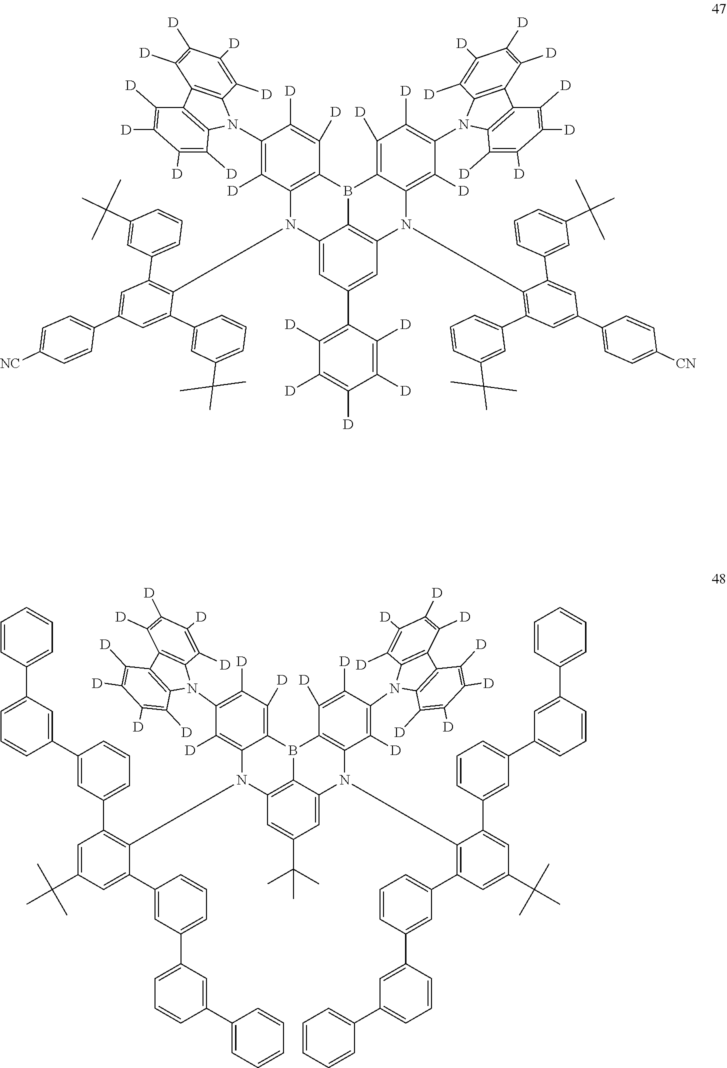 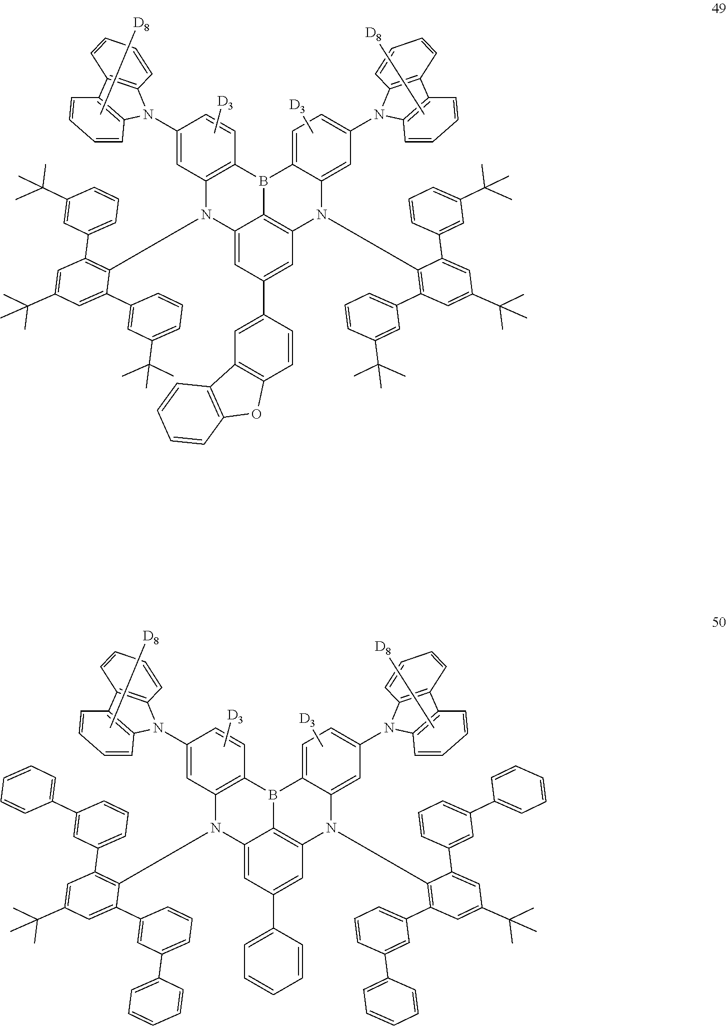
wherein in Compound Group 1,
D is a deuterium atom.
